(19) United States
(12) Patent Application Publication
(10) Pub. No.: US 2017/0059995 A1
(43) Pub. Date: Mar. 2, 2017

(54) PATTERN FORMING METHOD, ACTIVE LIGHT SENSITIVE OR RADIATION SENSITIVE RESIN COMPOSITION, ACTIVE LIGHT SENSITIVE OR RADIATION SENSITIVE FILM, METHOD FOR MANUFACTURING ELECTRONIC DEVICE, AND ELECTRONIC DEVICE

(71) Applicant: FUJIFILM Corporation, Tokyo (JP)

(72) Inventors: Hajime FURUTANI, Haibara-gun (JP); Akiyoshi GOTO, Haibara-gun (JP); Michihiro SHIRAKAWA, Haibara-gun (JP); Masahiro YOSHIDOME, Haibara-gun (JP); Masafumi KOJIMA, Haibara-gun (JP)

(73) Assignee: FUJIFILM Corporation, Tokyo (JP)

(21) Appl. No.: 15/350,913

(22) Filed: Nov. 14, 2016

Related U.S. Application Data
(63) Continuation of application No. PCT/JP2015/061930, filed on Apr. 20, 2015.

(30) Foreign Application Priority Data
Jun. 13, 2014 (JP) 2014-122870
Feb. 23, 2015 (JP) 2015-033281

(51) Int. Cl. G03F 7/32; G03F 7/16; G03F 7/039; G03F 7/004; G03F 7/20; G03F 7/038

(52) U.S. Cl. CPC G03F 7/322; G03F 7/325; G03F 7/2006; G03F 7/038; G03F 7/0397; G03F 7/0045; G03F 7/16

(57) ABSTRACT

A pattern forming method includes a pattern forming method using an actinic ray-sensitive or radiation-sensitive resin composition in which ΔDth represented by the following Formula (1) satisfies 0.8 or more (in the formula, Dth(PTI) represents the threshold deprotection rate of the acid-decomposable group with respect to the film thickness of the actinic ray-sensitive or radiation-sensitive film after development using the alkali developer, and Dth(NTI) represents the threshold deprotection rate of the acid-decomposable group with respect to the film thickness of the actinic ray-sensitive or radiation-sensitive film after development using the developer including an organic solvent).

ΔDth=Dth(PTI)/Dth(NTI) (1)

### CROSS-REFERENCE TO RELATED APPLICATIONS

This application is a Continuation of PCT International Application No. PCT/JP2015/61930, filed on Apr. 20, 2015, which claims priority under 35 U.S.C. §119(a) to Japanese Patent Application No. 2014-122870, filed on Jun. 13, 2014 and Japanese Patent Application No. 2015-33281, filed on Feb. 23, 2015. Each of the above application(s) is hereby expressly incorporated by reference, in its entirety, into the present application.

### BACKGROUND OF THE INVENTION

1. Field of the Invention

The present invention relates to a pattern forming method which is used for a process for manufacturing a semiconductor such as an IC, a process for manufacturing a circuit board for a liquid crystal, a thermal head, or the like, and other lithographic processes for photofabrication; and an actinic ray-sensitive or radiation-sensitive resin composition, an actinic ray-sensitive or radiation-sensitive film, a method for manufacturing an electronic device, and an electronic device, each of which is suitably used in the pattern forming method. The present invention further relates to a pattern forming method which is suitable, in particular, for exposure with an ArF exposure device and an immersion type projection exposure device, using far ultraviolet light at a wavelength of 300 nm or less as a light source; a water-based developer for use in the pattern forming method; a method of manufacturing an electronic device; and an electronic device.

2. Description of the Related Art

Since a resist for a KrF excimer laser (248 nm) was developed, an image forming method called chemical amplification has been used as an image forming method for a resist in order to compensate for desensitization caused by light absorption. By way of an example of an image forming method with positive type chemical amplification, there is a method which is an image forming method in which an acid generator in an exposed area decomposes due to exposure with an excimer laser, electron beams, extreme ultraviolet rays, or the like to produce an acid, the generated acid is used as a reactive catalyst during post-exposure bake to change alkali-insoluble groups to alkali-soluble groups, and the exposed area is removed by an alkali developer. Currently, as the alkali developer, water-based developers with 2.38% by mass of tetramethylammonium hydroxide (TMAH) have been widely used as a standard solution.

In order to make semiconductor elements finer, the wavelength of an exposure light source has been shortened and a projection lens with a high numerical aperture (high NA) has been advanced, and an exposure machine using an ArF excimer laser having a wavelength of 193 nm as a light source is currently being developed. In the case of using an ArF excimer laser as an exposure light source, a compound having an aromatic group essentially exhibits high absorption in a region at 193 nm, and accordingly, a resist for ArF excimer laser, which contains a resin having an alicyclic hydrocarbon structure, has been developed (see, for example, JP1997-73173A (JP-H09-73173A)). In addition, as a technique for further improving resolving power, a method in which a liquid having a high refractive index (hereinafter also referred to as an “immersion liquid”) is filled between a projection lens and a sample (a so-called liquid immersion method) has been proposed. Further, EUV lithography in which exposure is carried out with ultraviolet rays at a shorter wavelength (13.5 nm) has been proposed.

In recent years, a pattern forming method including an organic solvent development process in which development has been carried out using a developer including an organic solvent (which is hereinafter also referred to as an “organic solvent developer”) has also been developed. For example, JP2008-292975A discloses a double development process involving an alkali development process for carrying out development using an alkali developer and an organic solvent development process, as a double patterning technique for further enhancing resolving power. To describe the double development process by alkali development-organic solvent development with reference to FIG. 9, based on the polarity of a resin in a resist composition to be adjusted such that the resin has a high polarity in a region having high light intensity and has a low polarity in a region having low light intensity through exposure, a region 11 with a high exposure dose (exposed area) in the resist film is dissolved in an alkali developer (see FIGS. 9(a) and (b)), and a region 13 with a low exposure dose (unexposed area) is dissolved in an organic solvent developer, and thus, a region 12 with an intermediate exposure dose (intermediate-exposed area) is not dissolved and removed by development, and remains, whereby a line-and-space pattern having a half pitch of a mask for exposure is formed (see FIGS. 9(b) and (c)).

### SUMMARY OF THE INVENTION

In a double development process including an alkali development step and an organic solvent development step, in a case where the dissolution contrast of a region with an intermediate exposure dose (which is hereinafter also referred to as an “intermediate-exposed area”) is insufficient, the residual amount of the pattern is small, and as a result, a problem of generation of bridges in contact hole patterns or disconnections in line-and-space patterns occurs.

It is an object of the present invention to provide a pattern forming method which has good pattern survivability and excellent performance of suppressing generation of bridges in contact holes or performance of suppressing line-and-space disconnections; an actinic ray-sensitive or radiation-sensitive resin composition and an actinic ray-sensitive or radiation-sensitive film, each of which is suitably used in the pattern forming method, with regard to a pattern forming technique including a double development process involving an alkali development step and an organic solvent development step. It is another object of the present invention to provide a method for manufacturing an electronic device, including the pattern forming method, and an electronic device.

In one aspect, the present invention is as follows.

[1] A pattern forming method comprising:

a step of forming an actinic ray-sensitive or radiation-sensitive film, using an actinic ray-sensitive or radiation-sensitive resin composition containing a resin (A) whose polarity increases by the action of an acid by having repeating units (a-1) including acid-decomposable groups capable of decomposing by the action of an acid to generate polar groups;

an exposing step of irradiating the actinic ray-sensitive or radiation-sensitive film with actinic ray or radiation;

a developing step of dissolving a region with a large irradiation dose of actinic ray or radiation in the actinic ray-sensitive or radiation-sensitive film, using an alkali developer; and

a developing step of dissolving a region with a small irradiation dose of actinic ray or radiation in the actinic ray-sensitive or radiation-sensitive film, using a developer including an organic solvent,

in which ΔDth represented by the following Formula (1) of the actinic ray-sensitive or radiation-sensitive resin composition is 0.8 or more.

ΔDth=Dth(PTI)/Dth(NTI) (1)

In the formula,

Dth(PTI) represents the threshold deprotection rate of the acid-decomposable group in the repeating unit (a-1) included in the resin (A) with respect to the film thickness of the actinic ray-sensitive or radiation-sensitive film after development using the alkali developer, and

Dth(NTI) represents the threshold deprotection rate of the acid-decomposable group in the repeating unit (a-1) included in the resin (A) with respect to the film thickness of the actinic ray-sensitive or radiation-sensitive film after development using the developer including an organic solvent.

[2] The pattern forming method as described in [1], in which Dth(PTI) in Formula (1) is 0.3 or more.

[3] The pattern forming method as described in [1], in which Dth(NTI) in Formula (1) is 0.4 or less.

[4] The pattern forming method as described in any one of [1] to [3], in which the weight-average molecular weight of the resin (A) is 10,000 or more.

[5] The pattern forming method as described in any one of [1] to [4], in which the content of the repeating units (a-1) including acid-decomposable groups constituting the resin (A) is 65% by mole or less with respect to all the repeating units in the resin (A).

[6] The pattern forming method as described in any one of [1] to [5], in which the resin (A) contains an adamantane structure.

[7] The pattern forming method as described in any one of [1] to [6], in which the resin (A) further contains repeating units represented by the following General Formula (2).

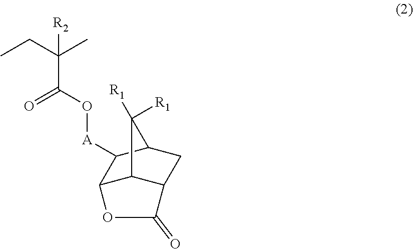

In the formula, A represents a single bond or a linking group, R₁'s each independently represent a hydrogen atom or an alkyl group, and R₂ represents a hydrogen atom or an alkyl group.

[8] An actinic ray-sensitive or radiation-sensitive resin composition used in a pattern forming method including a step of carrying out development using an alkali developer, and a step of carrying out development using a developer including an organic solvent, the actinic ray-sensitive or radiation-sensitive resin composition comprising a resin (A) whose polarity increases by the action of an acid by having repeating units (a-1) including acid-decomposable groups capable of decomposing by the action of an acid to generate polar groups, in which ΔDth represented by the following Formula (1) is 0.8 or more.

ΔDth=Dth(PTI)/Dth(NTI) (1)

In the formula,

Dth(PTI) represents the threshold deprotection rate of the acid-decomposable group in the repeating unit (a-1) included in the resin (A) with respect to the film thickness of the actinic ray-sensitive or radiation-sensitive film after development using the alkali developer, and

Dth(NTI) represents the threshold deprotection rate of the acid-decomposable group in the repeating unit (a-1) included in the resin (A) with respect to the film thickness of the actinic ray-sensitive or radiation-sensitive film after development using the developer including an organic solvent.

[9] The actinic ray-sensitive or radiation-sensitive resin composition as described in [8], in which Dth(PTI) in Formula (1) is 0.3 or more.

[10] The actinic ray-sensitive or radiation-sensitive resin composition as described in [8], in which Dth(NTI) in Formula (1) is 0.4 or less.

[11] The actinic ray-sensitive or radiation-sensitive resin composition as described in any one of [8] to [10], in which the weight-average molecular weight of the resin (A) is 10,000 or more.

[12] The actinic ray-sensitive or radiation-sensitive resin composition as described in any one of [8] to [11], in which the content of the repeating units (a-1) including acid-decomposable groups that occupy the resin (A) is 65% by mole or less with respect to all the repeating units in the resin (A).

[13] The actinic ray-sensitive or radiation-sensitive resin composition as described in any one of [8] to [12], in which the resin (A) contains an adamantane structure.

[14] The actinic ray-sensitive or radiation-sensitive resin composition as described in any one of [8] to [13], in which the resin (A) contains repeating units represented by the following General Formula (2).

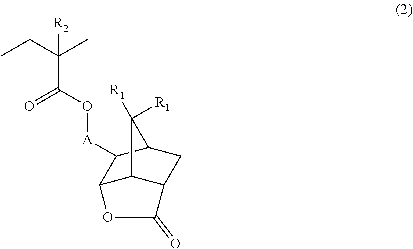

In the formula, A represents a single bond or a linking group, R₁'s each independently represent a hydrogen atom or an alkyl group, and R₂ represents a hydrogen atom or an alkyl group.

[15] An actinic ray-sensitive or radiation-sensitive film formed from the actinic ray-sensitive or radiation-sensitive resin composition as described in any one of [8] to [14].

[16] A method for manufacturing an electronic device, comprising the pattern forming method as described in any one of [1] to [7].

[17] An electronic device manufactured by the method for manufacturing an electronic device as described in [16].

According to the present invention, it is possible to provide a pattern forming method which has good pattern survivability and excellent performance of suppressing generation of bridges in contact holes or performance of suppressing line-and-space disconnections, an actinic ray-sensitive or radiation-sensitive resin composition and an actinic ray-sensitive or radiation-sensitive film, each of which is suitably used in this pattern forming method, with regard to a pattern forming technique including a double development process involving an alkali development process and an organic solvent development process. According to the present invention, it is also possible to provide a method for manufacturing an electronic device, including the pattern forming method, and an electronic device.

### BRIEF DESCRIPTION OF THE DRAWINGS

FIG. 1 is an explanatory view illustrating the relationship between the film thickness after exposure and the exposure dose.

FIG. 2 is an explanatory view illustrating the relationship between the film thickness after alkali development and the exposure dose.

FIG. 3 is an explanatory view illustrating the relationship between the deprotection amount of the acid-decomposable group and the exposure dose.

FIG. 4 is an explanatory view illustrating the relationship between the deprotection rate of the acid-decomposable group and the exposure dose.

FIG. 5 is an explanatory view illustrating the relationship between the film thickness after alkali development and the deprotection rate of the acid-decomposable group.

FIG. 6 is an explanatory view illustrating the relationship between the film thickness after organic solvent development and the exposure dose.

FIG. 7 is an explanatory view illustrating the relationship between the film thickness after organic solvent development and the deprotection rate of the acid-decomposable group.

FIG. 8 is a view illustrating the structure of the contact hole mask used in Examples.

FIG. 9 is a view schematically illustrating a double development process.

### DESCRIPTION OF THE PREFERRED EMBODIMENTS

Hereinafter, embodiments of the present invention will be described in detail.

In citations for group (atomic groups) in the present specification, in a case where a group is denoted without specifying whether it is substituted or unsubstituted, the group includes both a group not having a substituent and a group having a substituent. For example, an “alkyl group” includes not only an alkyl group not having a substituent (unsubstituted alkyl group), but also an alkyl group having a substituent (substituted alkyl group).

Moreover, “actinic ray” or “radiation” herein means, for example, a bright line spectrum of a mercury lamp, far ultraviolet rays represented by an excimer laser, extreme ultraviolet rays (EUV light), X-rays, electron beams (EB), or the like. In addition, in the present invention, light means actinic ray or radiation.

In addition, unless otherwise specified, “exposure” herein includes not only exposure by a mercury lamp, far ultraviolet rays represented by an excimer laser, extreme ultraviolet rays (EUV light), X-rays, or the like, but also writing by particle rays such as electron beams and ion beams.

Hereinafter, the respective steps included in the pattern forming method of the present invention, and the actinic ray-sensitive or radiation-sensitive resin composition which is suitably used in the pattern forming method will be described in detail.

As described above, the pattern forming method of the present invention includes:

a step of forming an actinic ray-sensitive or radiation-sensitive film using the actinic ray-sensitive or radiation-sensitive resin composition (which is hereinafter referred to as a “film-forming step”),

an exposing step of irradiating the actinic ray-sensitive or radiation-sensitive film with actinic ray or radiation,

a developing step of dissolving a region with a large irradiation dose of actinic ray or radiation in the actinic ray-sensitive or radiation-sensitive film after exposure, using an alkali developer (which is hereinafter referred to as an “alkali development step”), and

a developing step of dissolving a region with a small irradiation dose of actinic ray or radiation in the actinic ray-sensitive or radiation-sensitive film after exposure, using a developer including an organic solvent (which is hereinafter referred to as an “organic solvent development step”).

Here, the “region with a large irradiation dose of actinic ray or radiation in the actinic ray-sensitive or radiation-sensitive film” in the alkali development step means an exposed area in the actinic ray-sensitive or radiation-sensitive film, and the “region with a small irradiation dose of actinic ray or radiation in the actinic ray-sensitive or radiation-sensitive film” in the organic solvent development step means an unexposed area in the actinic ray-sensitive or radiation-sensitive film. Further, the order of the alkali development step and the organic solvent development step is not particularly limited, but it is preferable to develop the alkali development step and the organic solvent development step in this order from the viewpoint of pattern survivability.

The pattern forming method of the present invention includes a double development process involving the alkali development step and the organic solvent development step, as described above, and in a first aspect, it uses an actinic ray-sensitive or radiation-sensitive resin composition which contains a resin (which is hereinafter referred to as an “acid-decomposable resin” or a “resin (A)”) whose polarity increases by the action of an acid by having repeating units (a-1) including acid-decomposable groups capable of decomposing by the action of an acid to generate polar groups (which is hereinafter referred to as a “repeating unit (a-1)” or an “acid-decomposable repeating unit”), and having ΔDth represented by the following Formula (1) of 0.8 or more.

ΔDth=Dth(PTI)/Dth(NTI) (1)

In the formula,

Dth(PTI) represents the threshold deprotection rate of the acid-decomposable group in the repeating unit (a-1) included in the resin (A) with respect to the film thickness of the actinic ray-sensitive or radiation-sensitive film after development using the alkali developer, and

Dth(NTI) represents the threshold deprotection rate of the acid-decomposable group in the repeating unit (a-1) included in the resin (A) with respect to the film thickness of the actinic ray-sensitive or radiation-sensitive film after development using the developer including an organic solvent.

As described above, in the double development process, an exposed area in the actinic ray-sensitive or radiation-sensitive film, that is, a high deprotection region of the acid-decomposable group is dissolved by alkali development; an unexposed area, that is, a low deprotection region of the acid-decomposable group is dissolved by organic solvent development; and an intermediate-exposed area which is not dissolved by any of the development, that is, an intermediate deprotected region becomes a pattern. In the case of using a resist composition having a narrow intermediate deprotection region that thus becomes the pattern, the pattern after double development becomes fine, and accordingly, bridges in contact hole patterns or disconnections of line-and-space patterns occur.

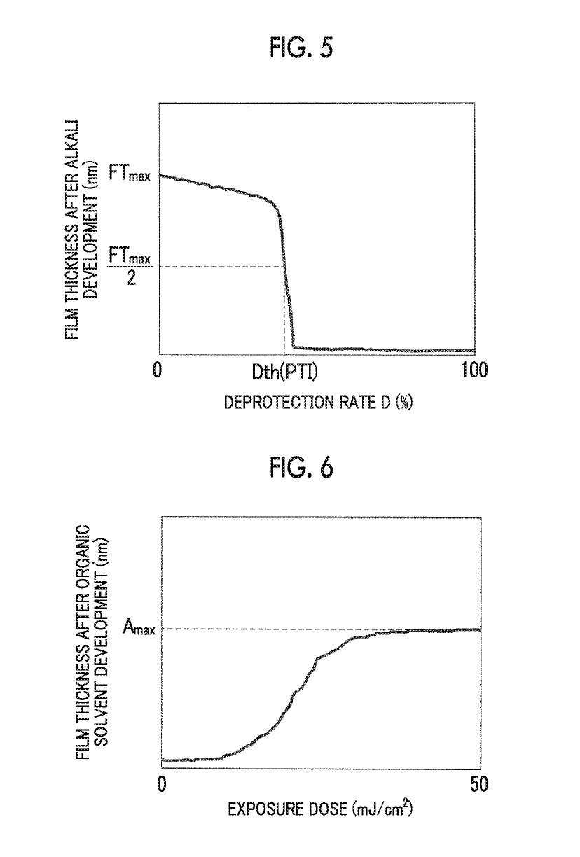

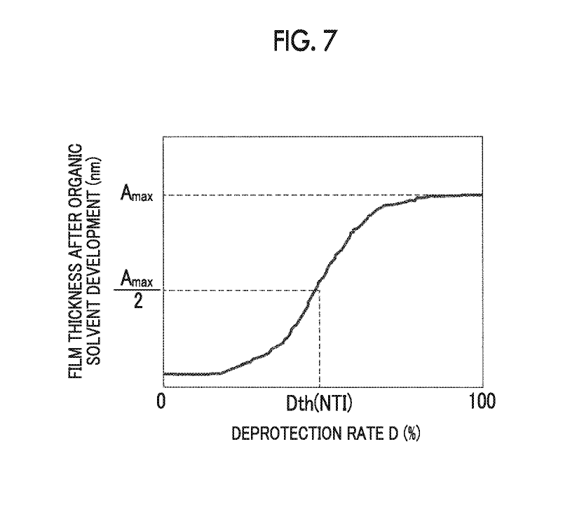

The present inventors have conducted extensive studies and as a result, they have found a deprotection rate which becomes a threshold (which is hereinafter referred to as a “threshold deprotection rate”) (Dth(PTI), Dth(NTI)) (see FIGS. 5 and 7) with respect to the film thickness of the pattern after development in the relationship between the deprotection rate of the acid-decomposable group in the acid-decomposable resin by exposure and the film thickness of the pattern after development, as described in detail below. Further, they have also found that it is preferable that the threshold deprotection rate (Dth(PTI)) of the acid-decomposable group in the alkali development is high, whereas the threshold deprotection rate (Dth(NTI)) of the acid-decomposable group in the organic solvent development is low, from the viewpoint of pattern survivability. In addition, as a result of their additional extensive studies, it was found that setting Dth(PTI) and Dth(NTI) to meet the relationship represented by General Formula (1) in a pattern forming method including a double development process makes patterns after double development thick to solve problems such as bridges in contact hole patterns and disconnections of line-and-space patterns.

Dth(PTI) and Dth(NTI) will be described in detail below.

[Threshold Deprotection Rate Dth(PTI) in Alkali Development]

The threshold deprotection rate of the acid-decomposable group in alkali development, represented by Dth(PTI),

determines an exposure dose at which the film thickness becomes a half value of the film thickness upon unexposure in a case where the actinic ray-sensitive or radiation-sensitive film is exposed and developed using an alkali developer, and

represents a deprotection rate determined from the ratio of the dissolved acid-decomposable groups in the repeating units (a-1) included in the resin (A) when the actinic ray-sensitive or radiation-sensitive film is exposed at the exposure dose.

Dth(PTI) is determined by, for example, the following method.

<Method for Determining Threshold Deprotection Rate Dth(PTI) in Alkali Development>

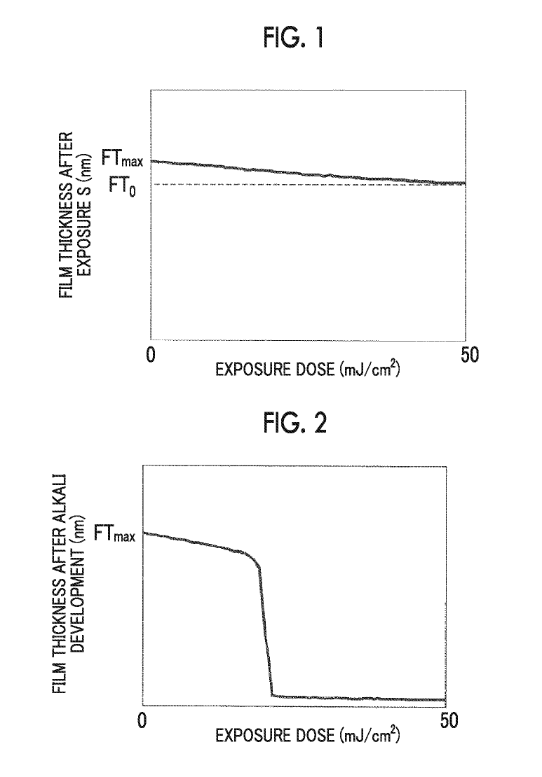

The composition of the present invention is applied onto a substrate and baked (Prebake: PB) to form an actinic ray-sensitive or radiation-sensitive film (film thickness: FTₘₐₓ/nm). The obtained actinic ray-sensitive or radiation-sensitive film was fractionated and exposed at an exposure dose which is changed per section. For example, surface exposure is carried out using an ArF excimer laser scanner by changing the exposure dose by 0.5 mJ/cm² within the range of 0 to 50 mJ/cm² per section. Here, the exposure dose of 50 mJ/cm² in ArF exposure is an over dose to an extent where the film thickness/dissolution contrast is not changed. After exposure, bake (Post Exposure Bake: PEB) is further carried out, and the film thickness is measured at each exposure dose per section. From these measurement results, a graph (film shrinkage curve) illustrating the relationship between the film thickness after exposure and the exposure dose shown in FIG. 1 is obtained.

The sample whose film thickness after exposure has been measured is subsequently developed for a predetermined period of time, using a 2.38%-by-mass aqueous tetramethylammonium solution (alkali developer), and the film thickness is measured again per section. From these measurement results, a sensitivity curve illustrating the relationship between the film thickness after alkali development and the exposure dose shown in FIG. 2 is obtained.

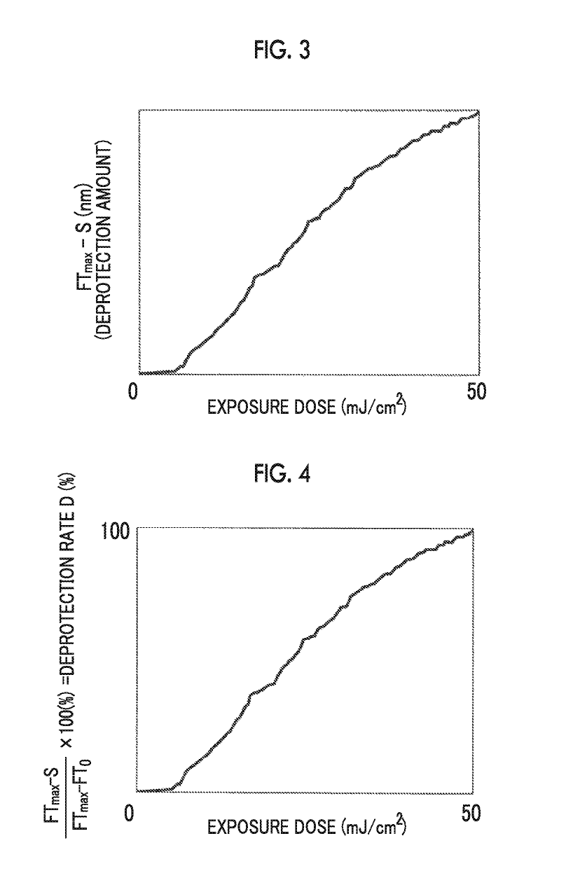

In the curve of film shrinkages after exposure shown in FIG. 1, the film thickness at an exposure dose of 0 (unexposure) is defined as FTₘₐₓ, the film thickness at an exposure dose of 50 mJ/cm² (Over Dose) is defined as FT₀, and the film thickness after exposure at a predetermined exposure dose is defined as S. Since the film shrinkage amount after exposure can be replaced with FTₘₐₓ−S, FTₘₐₓ−S at each exposure dose is calculated per section to obtain a graph illustrating the relationship between the film shrinkage amount after exposure and the exposure dose shown in FIG. 3.

Furthermore, a graph illustrating the relationship between the film shrinkage rate after exposure and the exposure dose shown in FIG. 4 is obtained by calculating a film shrinkage rate obtained by dividing the film shrinkage amount at each exposure dose: FTₘₐₓ−S by FTₘₐₓ, −FT₀: {FTₘₐₓ−S/FTₘₐₓ−FT₀}×100(%). Here, the film shrinkage rate at an exposure dose of 50 mJ/cm² (Over Dose) becomes 100%.

The film shrinkage amount after exposure corresponds to the volatilization amount of the protective group deprotected by the decomposition of the acid-decomposable group by the action of an acid, and therefore, in the present invention, the film shrinkage amount after exposure: FTₘₐₓ−S is defined as the deprotection amount of the acid-decomposable group, and the film shrinkage rate: {FTₘₐₓ−S/FTₘₐₓ−FT₀}×100(%) is defined as the deprotection rate of the acid-decomposable group (D). Accordingly, the graph shown in FIG. 3 illustrates the relationship between the deprotection amount of the acid-decomposable group and the exposure dose, and the graph shown in FIG. 4 illustrates the relationship between the deprotection rate of the acid-decomposable group and the exposure dose.

Moreover, a graph illustrating the relationship between the film thickness after alkali development and the deprotection rate (D) shown in FIG. 5 is obtained by changing the exposure dose in the sensitivity curve illustrating the relationship between the film thickness after alkali development and the exposure dose in FIG. 2 to the deprotection rate (D) in the graph illustrating the relationship between the deprotection rate (D) and the exposure dose in FIG. 4. In addition, the deprotection rate (D) at a time when the film thickness after alkali development becomes a half film thickness (FTₘₐₓ/2) with respect to the film thickness FTₘₐₓ at a deprotection rate of 0% is defined as a threshold deprotection rate Dth(PTI) in alkali development in the graph shown in FIG. 5.

[Threshold Deprotection Rate Dth(NTI) in Organic Solvent Development]

The threshold deprotection rate of the acid-decomposable group in organic solvent development, represented by Dth(NTI),

determines an exposure dose at which the film thickness becomes a half value of the film thickness during exposure at an excessive exposure dose (intended to be an Over Dose to an extent where the film thickness/dissolution contrast is not changed) in a case where the actinic ray-sensitive or radiation-sensitive film is exposed and developed using a developer including an organic solvent, and

represents a deprotection rate determined from the ratio of the dissolved acid-decomposable groups in the repeating units (a-1) included in the resin (A) when the actinic ray-sensitive or radiation-sensitive film is exposed at the exposure dose.

Dth(NTI) is determined by, for example, the following method.

<Method for Determining Threshold Deprotection Rate Dth(NTI) in Organic Solvent Development>

The composition of the present invention is applied onto a substrate and baked (Prebake: PB) to form an actinic ray-sensitive or radiation-sensitive film (film thickness: FTₘₐₓ/nm). The obtained actinic ray-sensitive or radiation-sensitive film was fractionated and exposed at an exposure dose which is changed per section. For example, surface exposure is carried out using an ArF excimer laser scanner, by changing the exposure dose by 0.5 mJ/cm² within the range of 0 to 50 mJ/cm² per section. Here, the exposure dose of 50 mJ/cm² in ArF exposure is an over dose to an extent where the film thickness/dissolution contrast is not changed. After exposure, bake (Post Exposure Bake: PEB) is further carried out, and the film thickness is measured at each exposure dose per section. From these measurement results, a graph (film shrinkage curve) illustrating the relationship between the film thickness after exposure and the exposure dose shown in FIG. 1 is obtained.

The sample whose film thickness after exposure has been measured is subsequently developed for a predetermined period of time, using an organic solvent developer, and the film thickness is measured again per section. From these measurement results, a sensitivity curve illustrating the relationship between the film thickness after organic solvent development and the exposure dose shown in FIG. 6 is obtained.

In the sensitivity curve shown in FIG. 6, the film thickness after organic solvent development at an exposure dose of 50 mJ/cm² (Over Dose) is defined as Aₘₐₓ.

In the curve of film shrinkages after exposure shown in FIG. 1, the film thickness at an exposure dose of 0 (unexposure) is defined as FTₘₐₓ, the film thickness at an exposure dose of 50 mJ/cm² (Over Dose) is defined as FT₀, and the film thickness after exposure at a predetermined exposure dose is defined as S. Since the film shrinkage amount after exposure can be replaced with FTₘₐₓ−S, FTₘₐₓ−S at each exposure dose is calculated per section to obtain a graph illustrating the relationship between the film shrinkage amount after exposure and the exposure dose shown in FIG. 3.

Furthermore, a graph illustrating the relationship between the film shrinkage rate after exposure and the exposure dose shown in FIG. 4 is obtained by calculating a film shrinkage rate obtained by dividing the film shrinkage amount at each exposure dose: FTₘₐₓ−S by FTₘₐₓ−FT₀: {FTₘₐₓ−S/FTₘₐₓ−FT₀}×100(%). Here, the film shrinkage rate at an exposure dose of 50 mJ/cm² (Over Dose) becomes 100%.

The film shrinkage amount after exposure corresponds to the volatilization amount of the protective group deprotected by the decomposition of the acid-decomposable group by the action of an acid, and therefore, in the present invention, the film shrinkage amount after exposure: FTₘₐₓ−S is defined as the deprotection amount of the acid-decomposable group, and the film shrinkage rate: {FTₘₐₓ−S/FTₘₐₓ−FT₀}×100(%) is defined as the deprotection rate of the acid-decomposable group (D). Accordingly, the graph shown in FIG. 3 illustrates the relationship between the deprotection amount of the acid-decomposable group and the exposure dose, and the graph shown in FIG. 4 illustrates the relationship between the deprotection rate of the acid-decomposable group and the exposure dose.

Moreover, a graph illustrating the relationship between the film thickness after organic solvent development and the deprotection rate (D) shown in FIG. 7 is obtained by changing the exposure dose in the sensitivity curve illustrating the relationship between the film thickness after organic solvent development and the exposure dose in FIG. 6 to the deprotection rate (D) in the graph illustrating the relationship between the deprotection rate (D) and the exposure dose in FIG. 4. In addition, the deprotection rate (D) at a time when the film thickness after organic solvent development becomes a half film thickness (Aₘₐₓ/2) with respect to the film thickness Aₘₐₓ at a deprotection rate of 100% is defined as a threshold deprotection rate Dth(NTI) in organic solvent development in the graph shown in FIG. 7.

As described above, the actinic ray-sensitive or radiation-sensitive resin composition used in the pattern forming method of the present invention has ΔDth represented by Formula (1) of 0.8 or more.

ΔDth=Dth(PTI)/Dth(NTI) (1)

In one aspect of the present invention, the threshold deprotection rate Dth(PTI) of the acid-decomposable group in alkali development is preferably 0.3 or more, more preferably 0.5 or more, and particularly preferably 0.6 or more. From the viewpoint of sensitivity, the upper limit is still more preferably 0.9 or less.

Furthermore, in one aspect of the present invention, the threshold deprotection rate Dth(NTI) of the acid-decomposable group in organic solvent development is preferably 0.4 or less, more preferably 0.3 or less, and particularly preferably 0.2 or less. From the viewpoint of scum, the lower limit is still more preferably 0.05 or more.

The ratio ΔDth of Dth(NTI) to Dth(PTI) is 0.8 or more, preferably 1 or more, and more preferably 1.2 or more. In order to suppress the disconnections of line-and-space patterns or suppress generation of non-apertures and bridges of the contact hole, the upper limit is still more preferably 2.5 or less.

Hereinafter, the actinic ray-sensitive or radiation-sensitive resin composition which is suitably used in the pattern forming method of the present invention will be described in detail, and then the respective steps included in the pattern forming method of the present invention will be described in detail.

<Actinic Ray-Sensitive or Radiation-Sensitive Resin Composition>

[Acid-Decomposable Resin]

The actinic ray-sensitive or radiation-sensitive resin composition of the present invention contains an acid-decomposable resin (resin (A)) whose polarity increases by the action of an acid by having repeating units (a-1) including acid-decomposable groups capable of decomposing by the action of an acid to generate polar groups. This acid-decomposable resin can be used in both aspects of formation of a positive tone pattern using an alkali developer and formation of a negative tone pattern using an organic solvent developer.

(1) Repeating Units (a-1) Including Acid-Decomposable Group

The acid-decomposable group has a structure in which a polar group is protected with a group capable of decomposing by the action of an acid to leave.

Preferred examples of the polar group include a carboxyl group, a fluorinated alcohol group (preferably hexafluoroisopropanol), and a sulfonic acid group.

As the acid-decomposable group, groups obtained by substituting hydrogen atoms of these alkali-soluble groups with groups capable of leaving by the action of an acid are preferable.

Examples of the group capable of leaving by the action of an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, or the like, and more preferably a tertiary alkyl ester group.

As a repeating unit (a-1) having the acid-decomposable group which the resin (A) can contain, a repeating unit represented by the following General Formula (AI) is preferable.

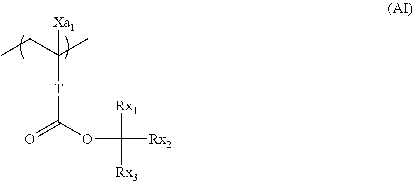

In General Formula (AI),

Xa₁ represents a hydrogen atom, a methyl group which may have a substituent, or a group represented by —CH₂—R₉. R₉ represents a hydroxyl group or a monovalent organic group. Examples of the monovalent organic group include an alkyl group having 5 or less carbon atoms, and an acyl group, and the monovalent organic group is preferably an alkyl group having 3 or less carbon atoms, and still more preferably a methyl group. Xa₁ is preferably a hydrogen atom, a methyl group, a trifluoromethyl group, or a hydroxymethyl group.

T represents a single bond or a divalent linking group.

Rx₁ to Rx₃ each independently represent an (linear or branched) alkyl group or a (monocyclic or polycyclic) cycloalkyl group.

At least two of Rx₁, . . . , or Rx₃ may be bonded to each other to form a (monocyclic or polycyclic) cycloalkyl group.

Examples of the divalent linking group of T include an alkylene group, a —COO-Rt- group, and an —O-Rt- group. In the formulae, Rt represents an alkylene group or a cycloalkylene group.

T is preferably a single bond or a —COO-Rt- group. Rt is preferably an alkylene group having 1 to 5 carbon atoms, and more preferably a —CH₂— group or a —(CH₂)₃— group.

As the alkyl group of Rx₁ to Rx₃, a linear or branched alkyl group having 1 to 4 carbon atoms is preferable.

As the cycloalkyl group of Rxₜ to Rx₃, a monocyclic cycloalkyl group having 3 to 8 carbon atoms and a polycyclic cycloalkyl group having 7 to 20 carbon atoms are preferable.

As the cycloalkyl group formed by the mutual bonding of at least two of Rx₁, . . . , or Rx₃, a monocyclic cycloalkyl group having 3 to 8 carbon atoms and a polycyclic cycloalkyl group having 7 to 20 carbon atoms are preferable, and a monocyclic cycloalkyl group having 5 or 6 carbon atoms is particularly preferable.

An aspect in which Rx₁ is a methyl group or an ethyl group, and Rx₂ and Rx₃ are bonded to form the above-described cycloalkyl group is preferable.

In one aspect, in General Formula (AI), it is preferable that T is a single bond, and Rx₁, Rx₂, and Rx₃ are alkyl groups, the sum of the numbers of carbon atoms of the alkyl groups represented by Rx₁, Rx₂, and Rx₃ is more preferably 4 or more, still more preferably 5 or more, and particularly preferably 6 or more.

From the viewpoint of the effects of the present invention, the content of the repeating units (a-1) having an acid-decomposable group is preferably 65% by mole or less with respect to all the repeating units in the resin (A). In the case where the proportion of the acid-decomposable groups in the acid-decomposable resin is low, the amount of the polar groups generated is reduced. Therefore, in the case where the repeating units (a-1) do not have a high deprotection rate, they are not dissolved in an alkali developer, and as a result, the value of Dth(PTI) increases and accordingly, the value of ΔDth increases. In order to achieve such effects, the content of the repeating units (a-1) having an acid-decomposable group in the acid-decomposable resin is more preferably 55% by mole or less, and particularly preferably 45% by mole or less. In addition, from the viewpoint of the exposure latitude (EL) performance, the content of the repeating units (a-1) is still more preferably 30% by mole or more.

Specific examples of the preferred repeating unit (a-1) having an acid-decomposable group are shown below, but the present invention is not limited thereto. Further, in the formulae, Xa₁ represents any one of H, CH₃, CF₃, and CH₂OH, and Rxa and Rxb each represent a linear or branched alkyl group having 1 to 4 carbon atoms.

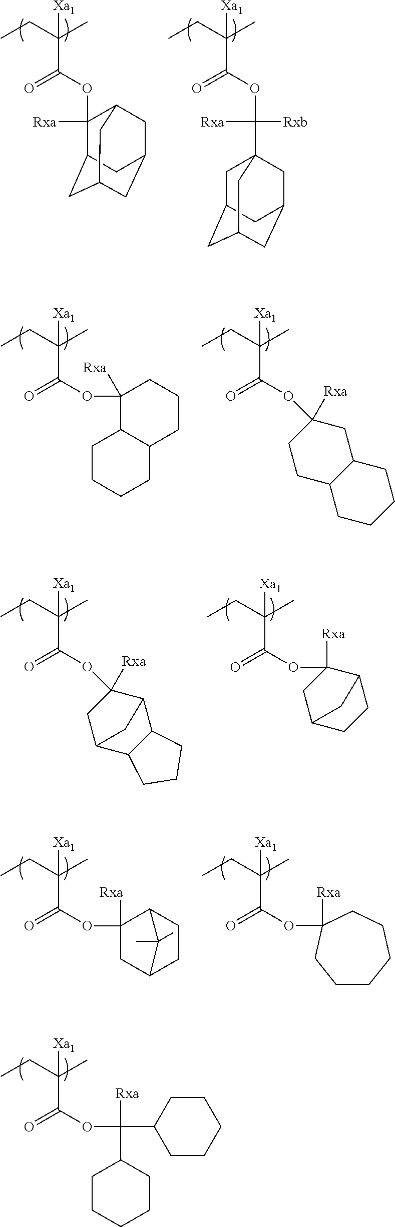

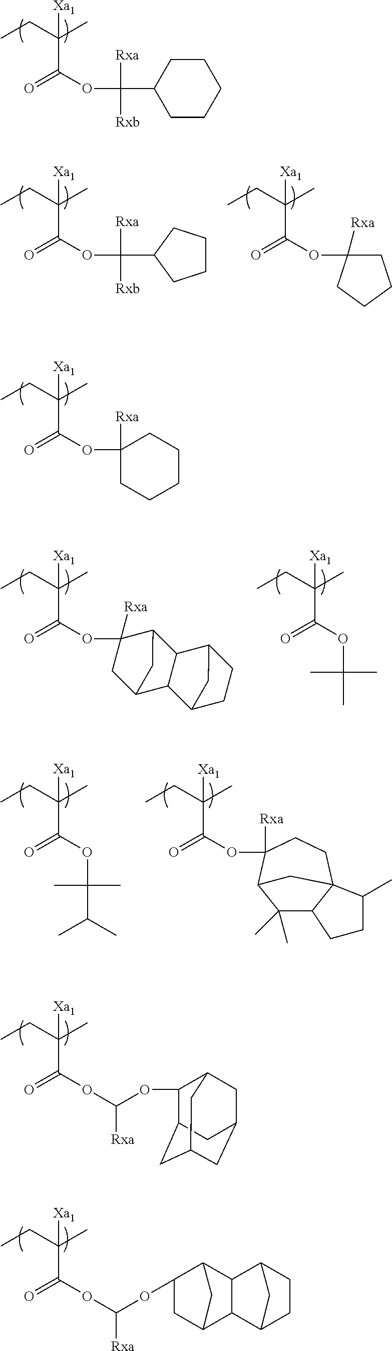

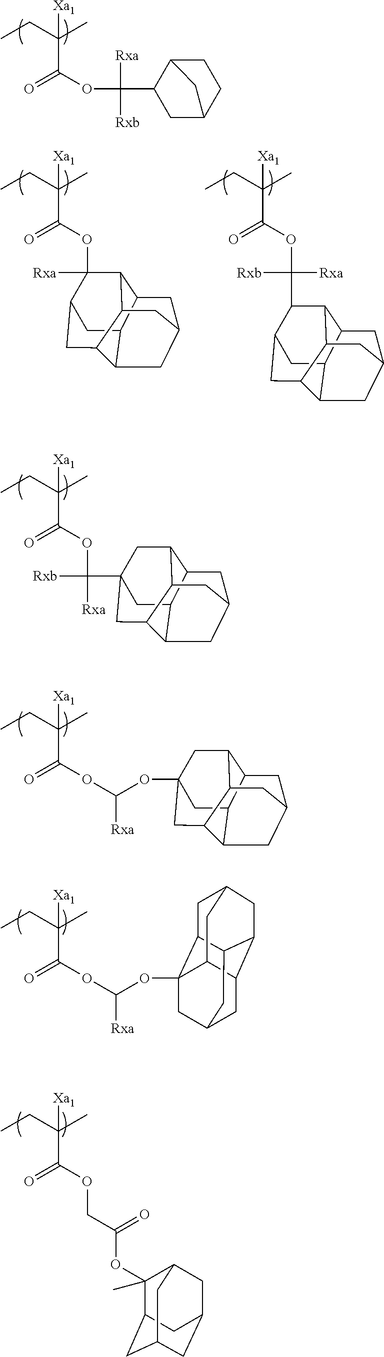

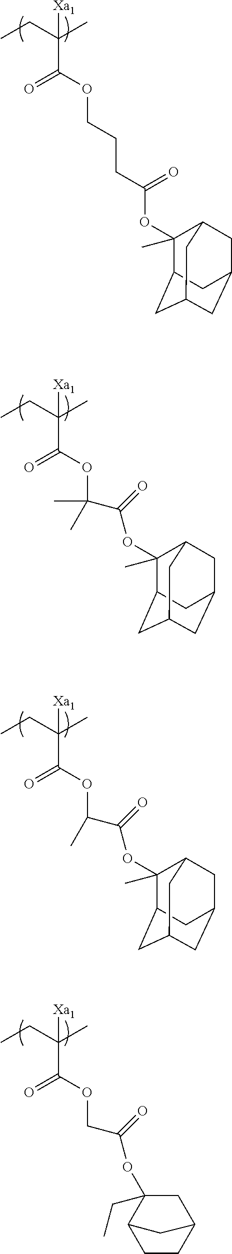

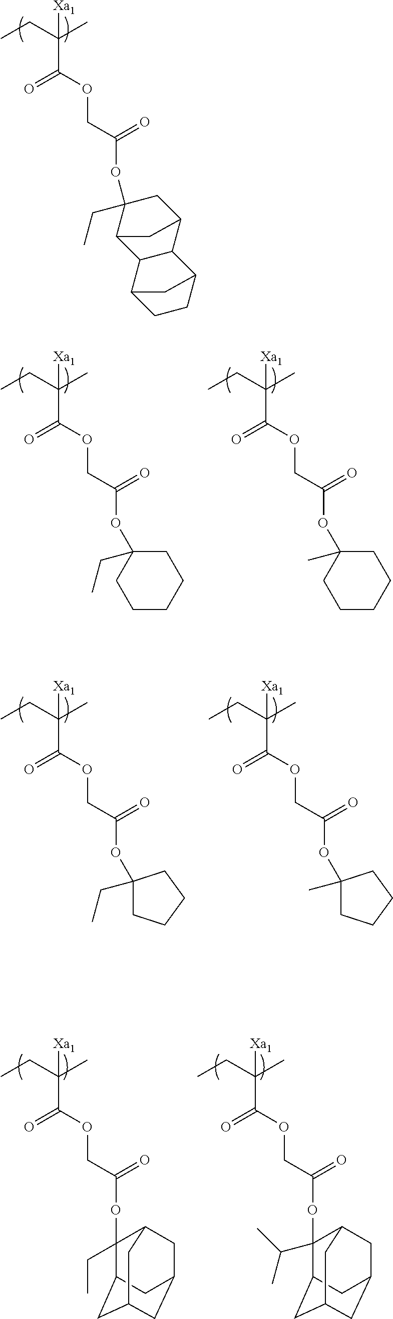

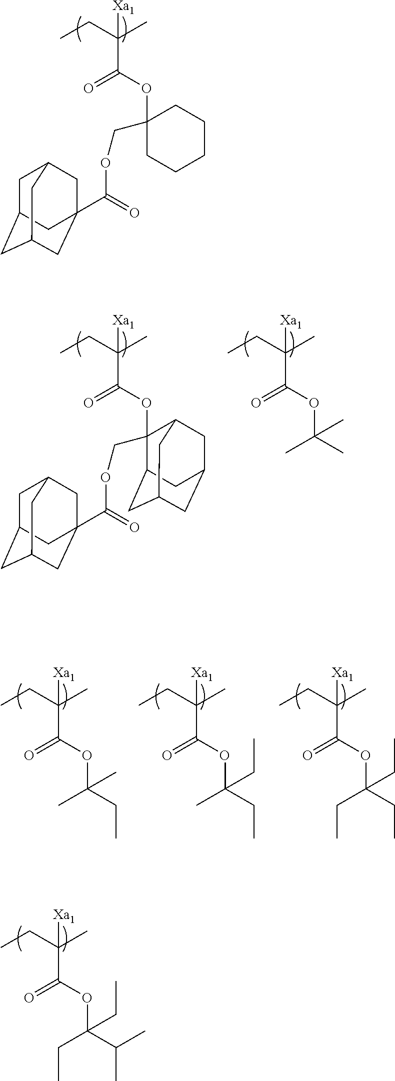

The resin (A) is more preferably a resin which contains a repeating unit represented by the following General Formula (I) as the repeating unit represented by General Formula (AI).

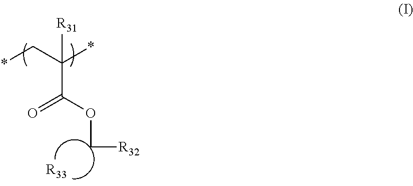

In General Formula (I),

R₃₁ represents a hydrogen atom, an alkyl group, or a fluorinated alkyl group,

R₃₂ represents an alkyl group, and

R₃₃ represents an atomic group required for forming a monocyclic alicyclic hydrocarbon structure together with carbon atoms to which R₃₂ is bonded.

In the alicyclic hydrocarbon structure, some of carbon atoms constituting a ring may be substituted with a hetero atom, or a group having a hetero atom.

The alkyl group of R₃₁ may have a substituent and examples of the substituent include a fluorine atom and a hydroxyl group.

R₃₁ preferably represents a hydrogen atom, a methyl group, a trifluoromethyl group, or a hydroxymethyl group.

R₃₂ is preferably an alkyl group having 3 to 10 carbon atoms, and more preferably an alkyl group having 4 to 7 carbon atoms.

R₃₂ is, for example, a methyl group, an ethyl group, an isopropyl group, or a t-butyl group, preferably an isopropyl group or a t-butyl group, and more preferably a t-butyl group.

The monocyclic alicyclic hydrocarbon structure formed by R₃₃ together with carbon atoms is preferably a 3- to 8-membered ring, and more preferably a 5- or 6-membered ring.

In the monocyclic alicyclic hydrocarbon structure formed by R₃₃ together with carbon atoms, examples of the hetero atom which can substitute some of ring-constituting hydrogen atoms include an oxygen atom and a sulfur atom, and examples of the group having a hetero atom include a carbonyl group. However, it is preferable that the group having a hetero atom is not an ester group (ester bond).

The monocyclic alicyclic hydrocarbon structure formed by R₃₃ together with carbon atoms is preferably formed with only carbon atoms and hydrogen atoms.

The repeating unit represented by General Formula (I) is preferably a repeating unit represented by the following General Formula (I′).

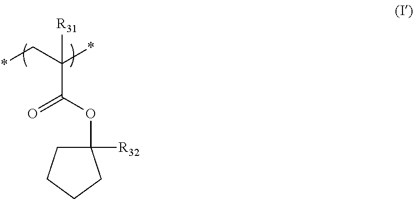

In General Formula (I′), R₃₁ and R₃₂ have the same definitions as those in General Formula (I), respectively.

Specific examples of the repeating unit having the structure represented by General Formula (I) are shown below, but are not limited thereto.

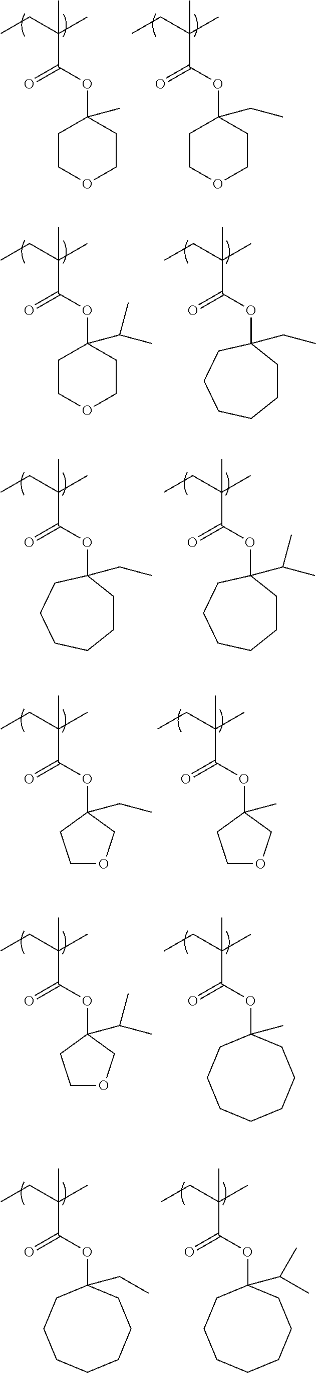

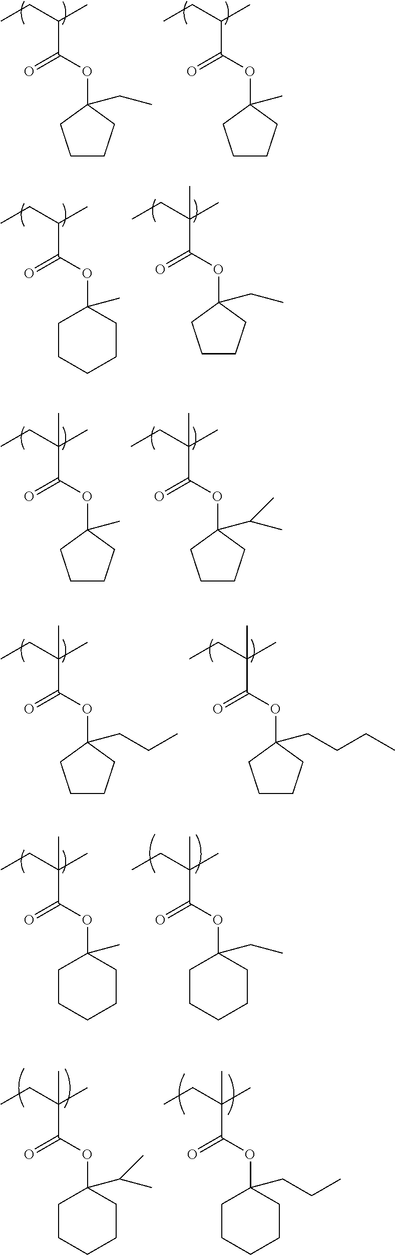

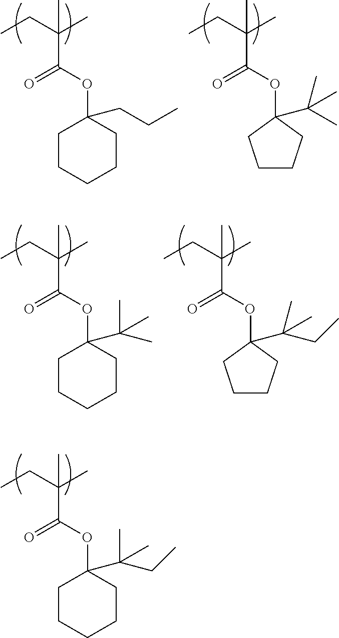

The repeating unit having an acid-decomposable group included in the resin (A) may be used alone or in combination of two or more kinds thereof.

The resin (A) is more preferably a resin which has at least one of the repeating unit represented by General Formula (II) or the repeating unit represented by General Formula (III), for example, as the repeating unit represented by General Formula (AI).

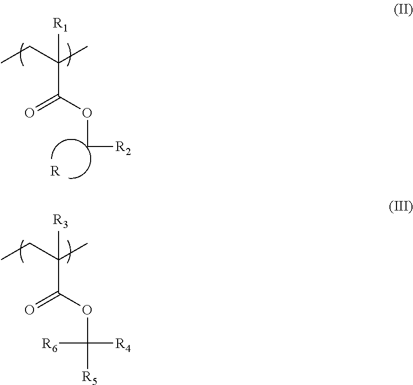

In Formulae (II) and (III),

R₁ and R₃ each independently represent a hydrogen atom, a methyl group which may have a substituent, or a group represented by —CH₂—R₁₁. R₁₁ represents a monovalent organic group.

R₂, R₄, R₅, and R₆ each independently represent an alkyl group or a cycloalkyl group.

R represents an atomic group required for forming an alicyclic structure together with a carbon atom to which R₂ is bonded.

R₁ and R₃ preferably represent a hydrogen atom, a methyl group, a trifluoromethyl group, or a hydroxymethyl group. Specific examples and preferred examples of the monovalent organic group in R₁₁ are the same as those, respectively, as described for Xa₁ in General Formula (AI).

The alkyl group in R₂ may be linear or branched, and may have a substituent.

The cycloalkyl group in R₂ monocyclic or polycyclic, and may have a substituent.

R₂ is preferably an alkyl group, more preferably an alkyl group having 1 to 10 carbon atoms, and still more preferably an alkyl group having 1 to 5 carbon atoms, and examples thereof include a methyl group, an ethyl group, a n-propyl group, an i-propyl group, and a t-butyl group. As the alkyl group in R₂, a methyl group, an ethyl group, an i-propyl group, and a t-butyl group are preferable.

R represents an atomic group required to form an alicyclic structure together with a carbon atom. The alicyclic structure formed by R together with the carbon atom is preferably a monocyclic alicyclic structure. R preferably has 3 to 7 carbon atoms, and more preferably 5 or 6 carbon atoms.

R₃ is preferably a hydrogen atom or a methyl group, and more preferably a methyl group.

The alkyl group in R₄, R₅, or R₆ may be linear or branched, and may have a substituent. Examples of the alkyl group include alkyl groups having 1 to 4 carbon atoms, such as a methyl group, an ethyl group, a n-propyl group, an isopropyl group, a n-butyl group, an isobutyl group, and a t-butyl group.

The cycloalkyl group in R₄, R₅, or R₆ may be monocyclic or polycyclic, and may have a substituent. Preferred examples of the cycloalkyl group include monocyclic cycloalkyl groups such as a cyclopentyl group and a cyclohexyl group, and polycyclic cycloalkyl group such as a norbornyl group, a tetracyclodecanyl group, a tetracyclododecanyl group, and an adamantyl group.

Examples of the substituent which each of the groups may have include the same groups as those described as the substituent which each of the groups in General Formula (AI) may have.

In General Formula (III), R₄, R₅, and R₆ are preferably an alkyl group, and the sum of the numbers of carbon atoms of R₄, R₅, and R₆ is preferably 5 or more, more preferably 6 or more, and still more preferably 7 or more.

The resin (A) is more preferably a resin which contains the repeating unit represented by General Formula (II) and the repeating unit represented by General Formula (III), as the repeating unit represented by General Formula (AI).

Moreover, in another aspect, a resin which contains at least two kinds of the repeating unit represented by General Formula (II) as the repeating unit represented by General Formula (AI) is more preferable. In a case where the resin contains at least two kinds of the repeating unit represented by General Formula (II), it is preferable that the resin contains both of a repeating unit in which an alicyclic structure formed by R together with a carbon atom is a monocyclic alicyclic structure and a repeating unit in which an alicyclic structure formed by R together with a carbon atom is a polycyclic alicyclic structure. The monocyclic alicyclic structure preferably has 5 to 8 carbon atoms, more preferably has 5 or 6 carbon atoms, and particularly preferably has 5 carbon atoms. As the polycyclic alicyclic structure, a norbornyl group, a tetracyclodecanyl group, a tetracyclododecanyl group, and an adamantyl group are preferable.

(2) Repeating Unit Having at Least One Group Selected from Lactone Group, Hydroxyl Group, Cyano Group, or Alkali-Soluble Group

The resin (A) preferably has a repeating unit having at least one group selected from a lactone group, a sultone group, a hydroxyl group, a cyano group, and an alkali-soluble group.

The repeating unit having a lactone group or a sultone group, which the resin (A) may contain, will be described.

As the lactone group or the sultone group, any group may be used as long as it has a lactone structure or a sultone structure, but the structure is preferably a 5- to 7-membered ring lactone structure or sultone structure, and more preferably a 5- to 7-membered ring lactone structure or sultone structure to which another ring structure is fused in the form capable of forming a bicyclo structure or a spiro structure. The resin (A) still more preferably has a repeating unit having a lactone structure represented by any one of the following General Formulae (LC1-1) to (LC1-17), or a sultone structure represented by the following General Formula (SL1-1) or (SL1-2). Further, the lactone structure or the sultone structure may be bonded directly to the main chain. Preferred examples of the lactone structures include (LC1-1), (LC1-4), (LC1-5), (LC1-6), (LC1-13), (LC1-14), and (LC1-17). By using such a specific lactone structure or sultone structure, development defects are relieved.

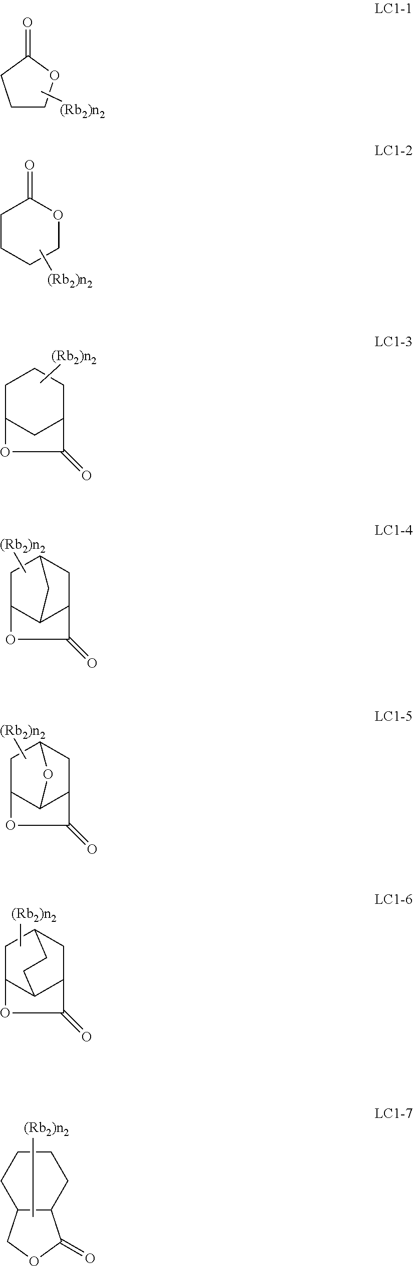

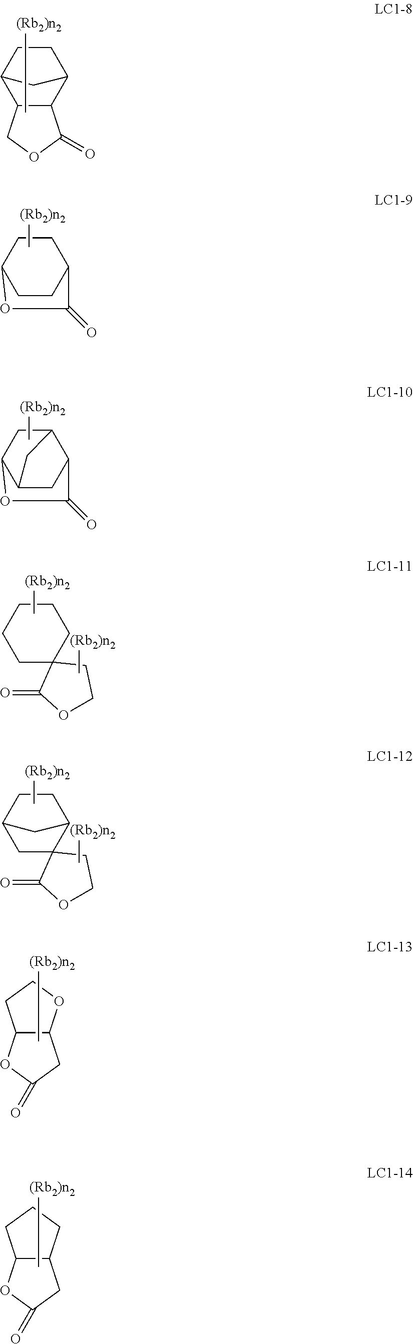

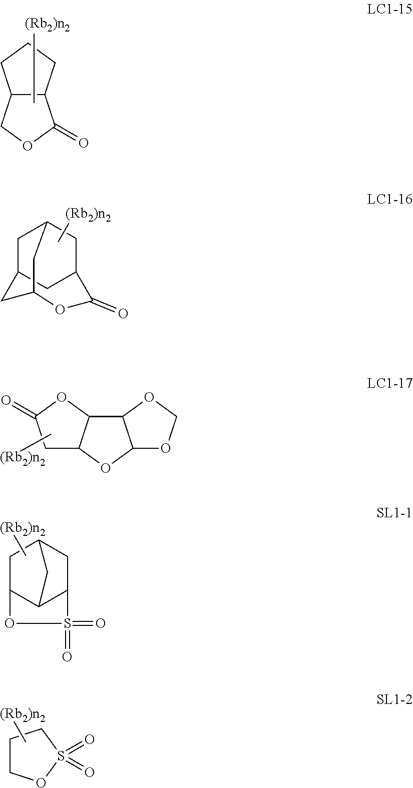

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferable. n₂ represents an integer of 0 to 4. When n₂ is 2 or more, the substituents (Rb₂) which are present in plural numbers may be the same as or different from each other, and further, the substituents (Rb₂) which are present in plural numbers may be bonded to each other to form a ring.

Examples of the repeating unit having a lactone structure represented by any one of the General Formulae (LC1-1) to (LC1-17), and a sultone structure represented by General Formula (SL1-1) or (SL1-2) include repeating units represented by the following General Formula (AII).

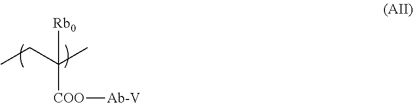

In General Formula (AII),

Rb₀ represents a hydrogen atom, a halogen atom, or an alkyl group having 1 to 4 carbon atoms, which may have a substituent. Preferred examples of the substituents which the alkyl group of Rb₀ may have include a hydroxyl group and a halogen atom. Examples of the halogen atoms of Rb₀ include a fluorine atom, a chlorine atom, a bromine atom, and an iodine atom. Rb₀ is preferably a hydrogen atom, a methyl group, a hydroxymethyl group, or a trifluoromethyl group, and particularly preferably a hydrogen atom or a methyl group.

Ab represents a single bond, an alkylene group, a divalent linking group having a monocyclic or polycyclic alicyclic hydrocarbon structure, an ether bond, an ester bond, a carbonyl group, or a divalent linking group obtained by combining these groups. Ab is preferably a single bond or a divalent linking group represented by -Ab₁-CO₂—.

Ab₁ is a linear or branched alkylene group, or a monocyclic or polycyclic cycloalkylene group, and preferably a methylene group, an ethylene group, a cyclohexylene group, an adamantylene group, or a norbornylene group.

V represents a group having the structure represented by any one of General Formulae (LC1-1) to (LC1-17), and General Formulae (SL1-1) and (SL1-2).

The repeating unit having a lactone group or a sultone group usually has an optical isomer, and any optical isomer may be used. Further, one kind of optical isomer may be used alone or a plurality of optical isomers may be mixed and used. In the case of mainly using one kind of optical isomer, the optical purity (ee) thereof is preferably 90 or more, and more preferably 95 or more.

The content of the repeating units having a lactone structure or a sultone structure is preferably 15% to 60% by mole, more preferably 20% to 50% by mole, and still more preferably 30% to 50% by mole, with respect to all the repeating units in the resin (A).

Furthermore, from the viewpoint of the effects of the present invention, it is preferable that the acid-decomposable resin contains repeating units represented by the following General Formula (2). The repeating unit represented by the following General Formula (2) has low solubility in an alkali developer, and in the case where the acid-decomposable resin contains the repeating unit represented by General Formula (2), the solubility in an alkali developer is lowered and thus, is not dissolved in the alkali developer, and the value of Dth(PTI) increases, and thus, the value of Dth increases. In order to obtain such an effect, the content of the repeating units represented by General Formula (2) in the acid-decomposable resin is preferably 20% by mole or more, more preferably 30% by mole or more, and still more preferably 40% by mole or more, with respect to all the repeating units in the acid-decomposable resin. From the viewpoint of EL performance, the content is preferably 70% by mole or less.

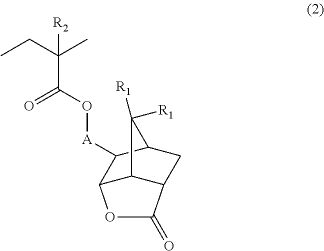

In the formula,

A represents a single bond or a linking group, R₁'s each independently represent a hydrogen atom or an alkyl group, and R₂ represents a hydrogen atom or an alkyl group.

Examples of the linking group represented by A include an alkylene group, a divalent linking group having a monocyclic or polycyclic alicyclic hydrocarbon structure, an ether bond, an ester bond, a carbonyl group, or a divalent linking group obtained by combining these groups. In one aspect of the present invention, A is preferably a single bond.

Examples of the alkyl group represented by R₁ include an alkyl group having 1 or 2 carbon atoms. This alkyl group may have a substituent. R₁ is preferably, for example, a hydrogen atom or a methyl group.

Examples of the alkyl group represented by R₂ include an alkyl group having 1 to 4 carbon atoms. This alkyl group may have a substituent. R₂ is preferably, for example, a methyl group, a trifluoromethyl group, or a hydroxymethyl group.

Examples of the repeating unit having a lactone group or a sultone group include the following repeating units. By choosing an optimal lactone group, pattern profiles and density dependence are improved.

(In the formulae, Rx represents H, CH₃, CH₂OH, or CF₃.)

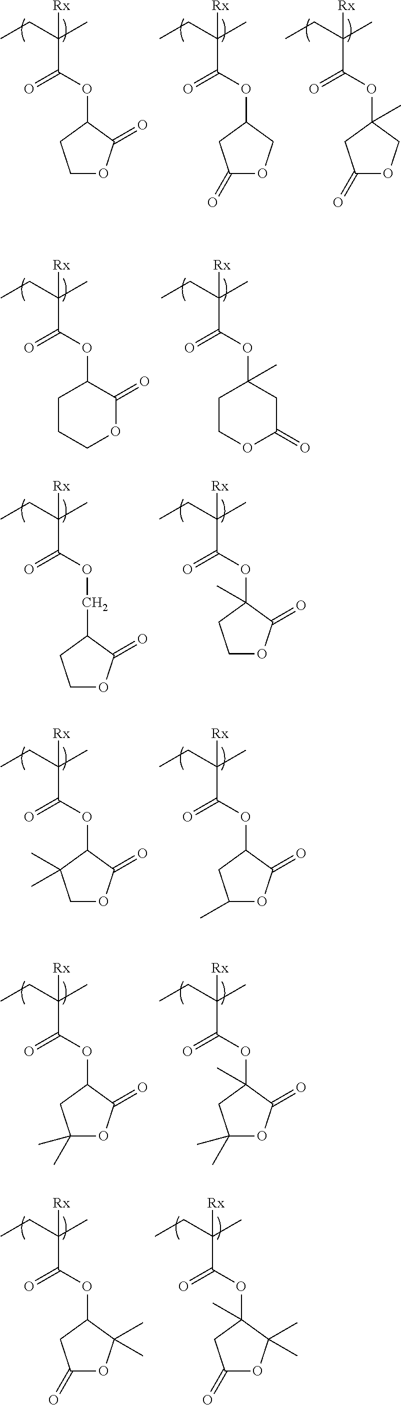

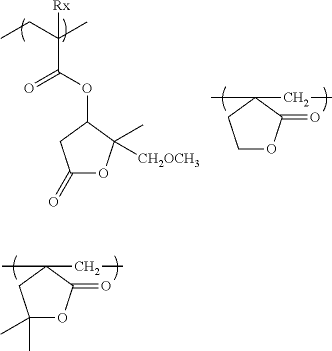

(In the formulae, Rx represents H, CH₃, CH₂OH, or CF₃.)

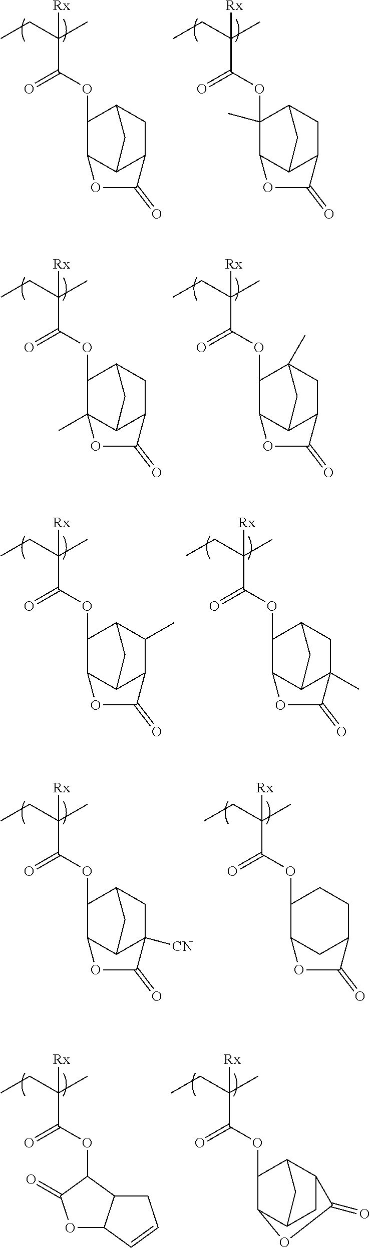

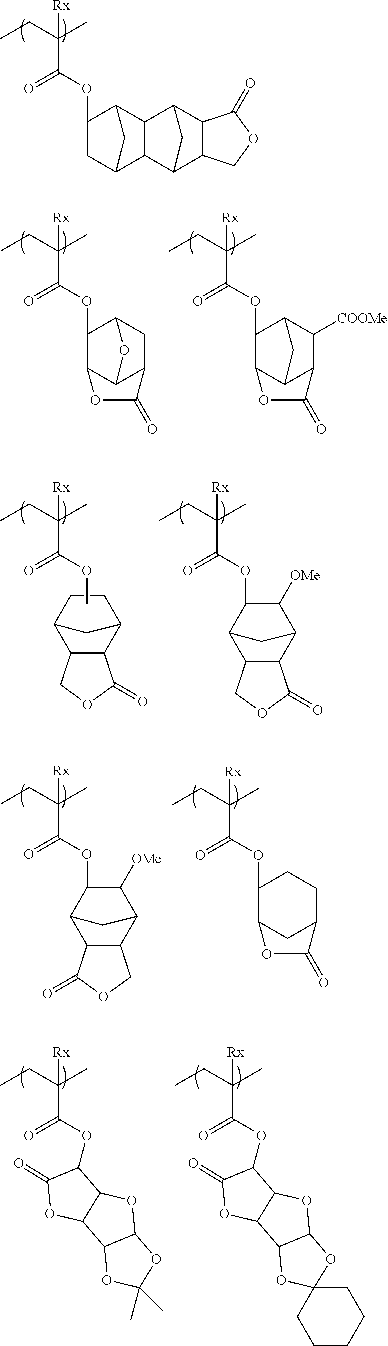

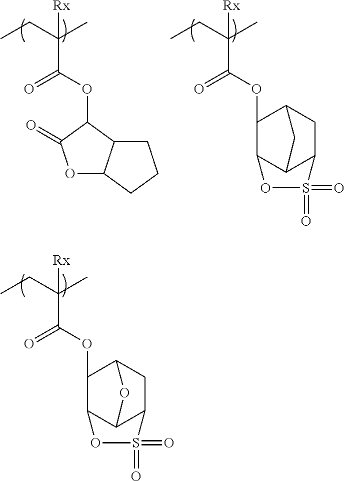

(In the formulae, Rx represents H, CH₃, CH₂OH, or CF₃.)

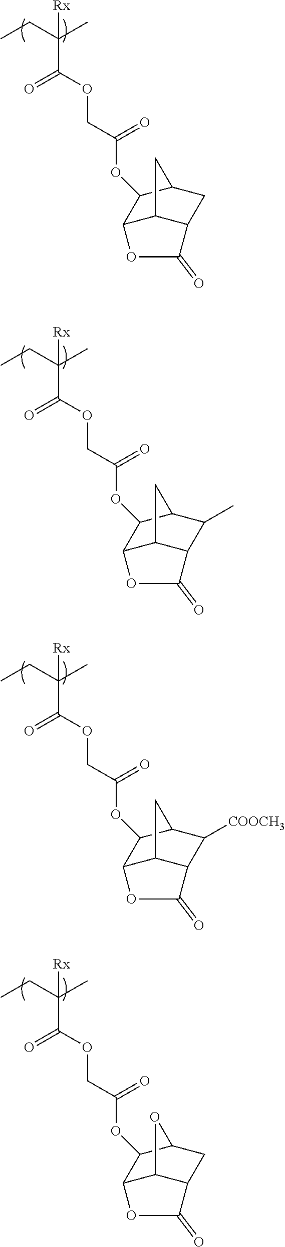

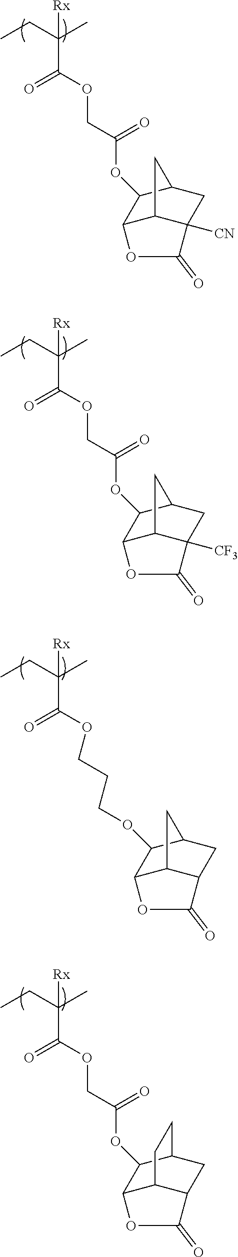

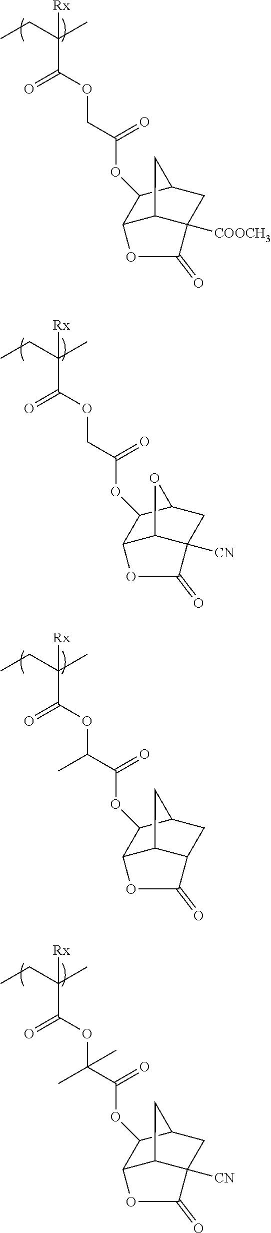

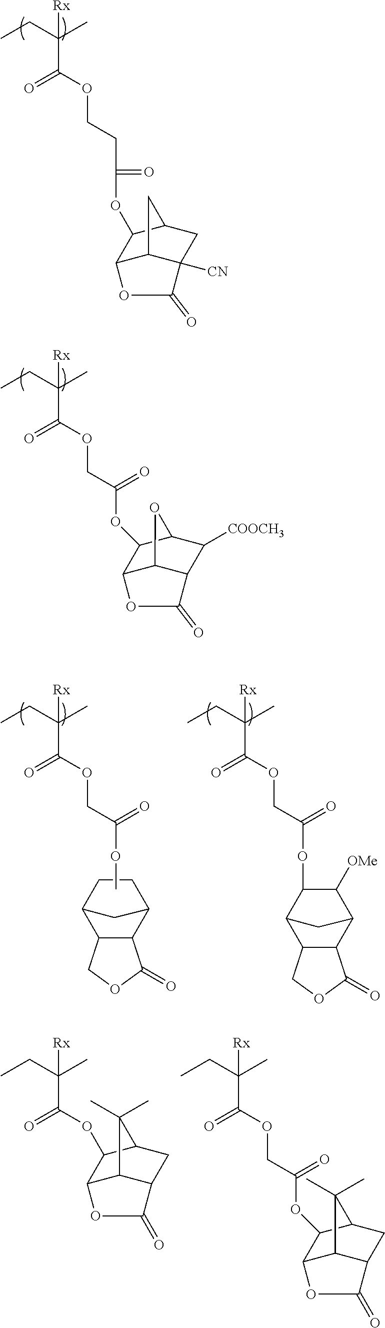

It is also possible to use a combination of two or more kinds of the repeating unit having a lactone structure or a sultone structure.

It is preferable that the resin (A) has repeating units having a hydroxyl group or a cyano group, in addition to General Formulae (AI) and (All). With the repeating units, the adhesiveness to a substrate and the developer affinity are enhanced. The repeating unit having a hydroxyl group or a cyano group is preferably a repeating unit having an alicyclic hydrocarbon structure substituted with a hydroxyl group or a cyano group, and preferably has no acid-decomposable group. Examples of the repeating units having the structures include repeating units represented by the following General Formulae (AIIa) to (AIId).

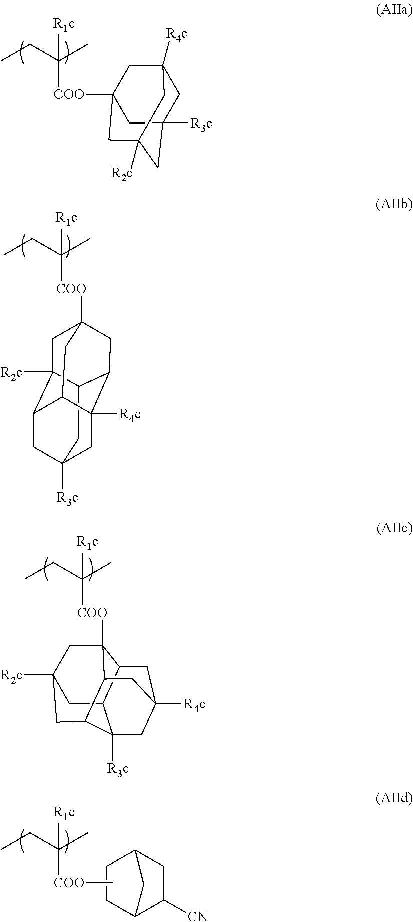

In General Formulae (AIIa) to (AIId),

R₁c represents a hydrogen atom, a methyl group, a trifluoromethyl group, or a hydroxymethyl group.

R₂c to R₄c each independently represent a hydrogen atom, a hydroxyl group, or a cyano group, but at least one of R₂c, . . . , or R₄c represents a hydroxyl group or a cyano group. It is preferable that one or two members out of R₂c to R₄c are hydroxyl groups and the remainders are hydrogen atoms, and it is more preferable that two members out of R₂c to R₄c are hydroxyl groups and the remainders are hydrogen atoms.

The content of the repeating units having a hydroxyl group or a cyano group is preferably 5% to 40% by mole, more preferably 5% to 30% by mole, and still more preferably 10% to 25% by mole, with respect to all the repeating units in the resin (A).

Specific examples of the repeating unit having a hydroxyl group or a cyano group are shown below, but the present invention is not limited thereto.

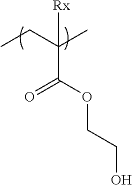

(In the formulae, Rx represents H, CH₃, CH₂OH, or CF₃.)

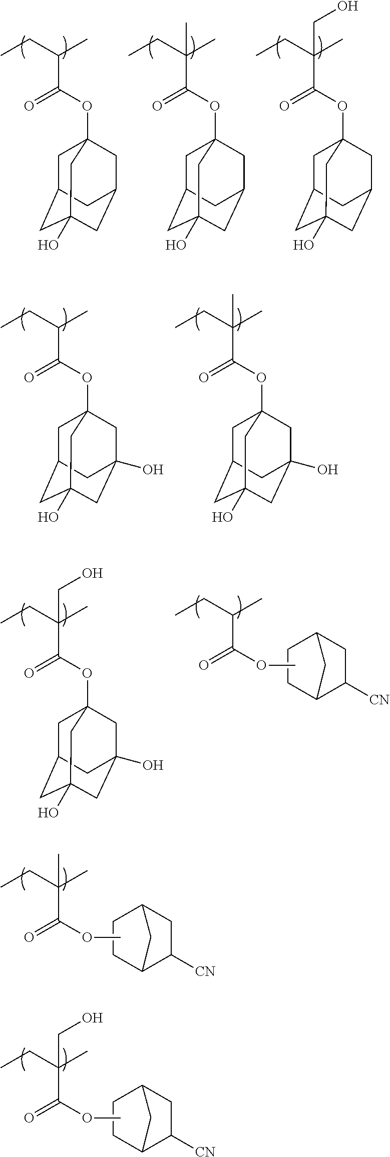

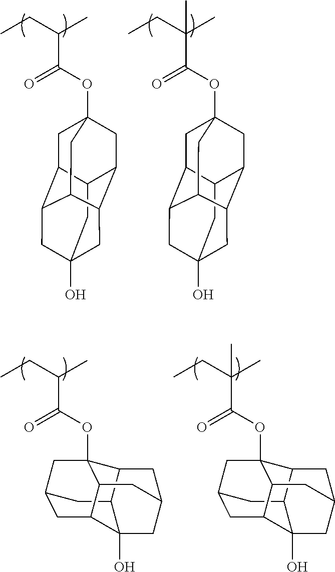

It is preferable that the resin (A) has a repeating unit having an acid group. Examples of the acid group include a carboxyl group, a sulfonamido group, a sulfonylimido group, a disulfonylimido group, and an aliphatic alcohol group with the α-position being substituted with an electron-withdrawing group (for example, a hexafluoroisopropanol group), and it is more preferable that the resin (A) has a repeating unit having a carboxyl group. By virtue of containing a repeating unit having an acid group, the resolution increases in the applications of contact holes. As the repeating unit having an acid group, all of a repeating unit in which an acid group is directly bonded to the main chain of the resin, such as a repeating unit by an acrylic acid or a methacrylic acid, a repeating unit in which an acid group is bonded to the main chain of the resin through a linking group, and a repeating unit in which an acid group is introduced into the polymer chain terminal by using a polymerization initiator having an acid group, or a chain transfer agent at the polymerization, are preferable. The linking group may have a monocyclic or polycyclic hydrocarbon structure. A repeating unit by an acrylic acid or a methacrylic acid is particularly preferable.

The content of the repeating units having an acid group is preferably 0% to 20% by mole, more preferably 3% to 15% by mole, and still more preferably 5% to 10% by mole, with respect to all the repeating units in the resin (A).

Specific examples of the repeating unit having an acid group are shown below, but the present invention is not limited thereto. In the specific examples, Rx represents H, CH₃, CH₂OH, or CF₃.

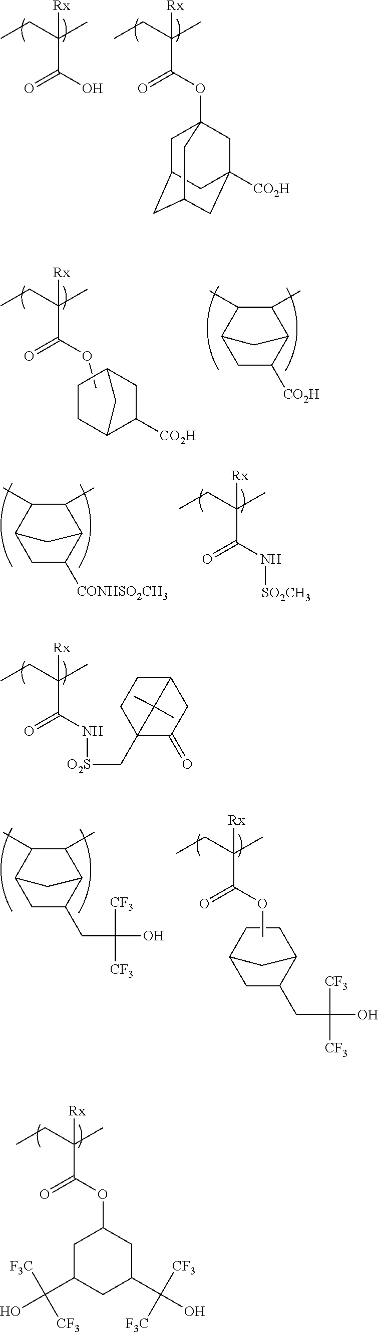

(3) Repeating Unit Having Alicyclic Hydrocarbon Structure and not Exhibiting Acid-Decomposability

The resin (A) may further have a repeating unit having an alicyclic hydrocarbon structure and not exhibiting acid-decomposability. Thus, it is possible to reduce elution of the low-molecular-weight components from the resist film to the immersion liquid during liquid immersion exposure. Examples of such a repeating unit include repeating units formed from 1-adamantyl (meth)acrylate, diamantyl (meth)acrylate, tricyclodecanyl (meth)acrylate, cyclohexyl (meth)acrylate, and the like.

(4) Repeating Unit not Having any One of Hydroxyl Group and Cyano Group

It is preferable that the resin (A) of the present invention contains a repeating unit not having any one of a hydroxyl group and a cyano group, and is represented by General Formula (IV).

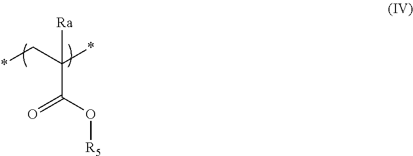

In General Formula (IV), R₅ represents a hydrocarbon group having at least one cyclic structure and not having any one of a hydroxyl group and a cyano group.

Ra represents a hydrogen atom, an alkyl group, or a —CH₂—O—Ra₂ group. In the formula, Ra₂ represents a hydrogen atom, an alkyl group, or an acyl group.

The cyclic structure contained in R₅ includes a monocyclic hydrocarbon group and a polycyclic hydrocarbon group. Examples of the monocyclic hydrocarbon group include a cycloalkyl group having 3 to 12 carbon atoms (more preferably having 3 to 7 carbon atoms), and a cycloalkenyl group having 3 to 12 carbon atoms.

Examples of the polycyclic hydrocarbon group include a ring-assembly hydrocarbon group and a crosslinked cyclic hydrocarbon group. Examples of the crosslinked cyclic hydrocarbon ring include a bicyclic hydrocarbon ring, a tricyclic hydrocarbon ring, and a tetracyclic hydrocarbon ring. Further, other examples of the crosslinked cyclic hydrocarbon ring include fused rings formed by fusing a plurality of 5- to 8-membered cycloalkane rings.

Preferred examples of the crosslinked cyclic hydrocarbon ring include a norbornyl group, an adamantyl group, a bicyclooctanyl group, and a tricyclo[5.2.1.0^{2,6}]decanyl group. More preferred examples of the crosslinked cyclic hydrocarbon rings include a norbornyl group and an adamantyl group.

These alicyclic hydrocarbon groups may have a substituent, and preferred examples of the substituent include a halogen atom, an alkyl group, a hydroxyl group protected with a protective group, and an amino group protected with a protective group.

The content of the repeating units not having any one of a hydroxyl group and a cyano group, represented by General Formula (IV), is preferably 0% to 40% by mole, and more preferably 0% to 20% by mole, with respect to all the repeating units in the resin (A).

Specific examples of the repeating unit represented by General Formula (IV) are shown below, but the present invention is not limited thereto. In the formulae, Ra represents H, CH₃, CH₂OH, or CF₃.

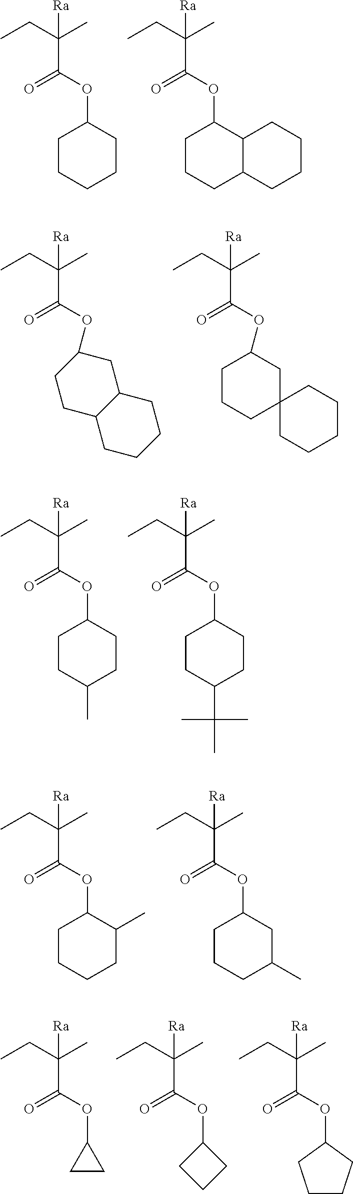

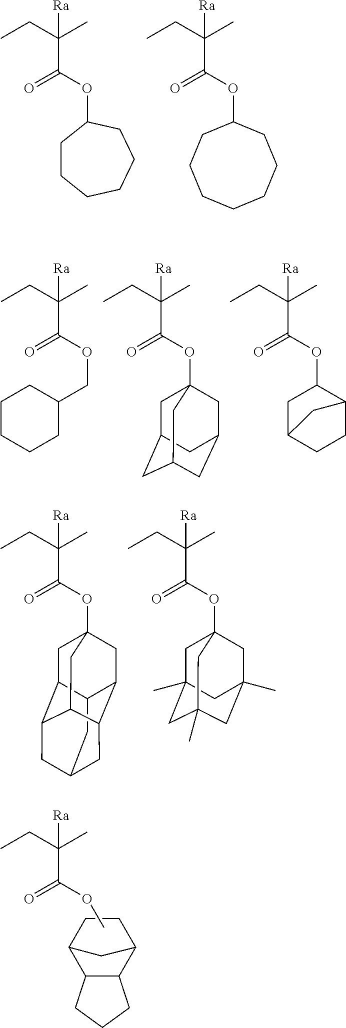

The resin (A) may contain repeating units represented by the following General Formula (nI) or (nII).

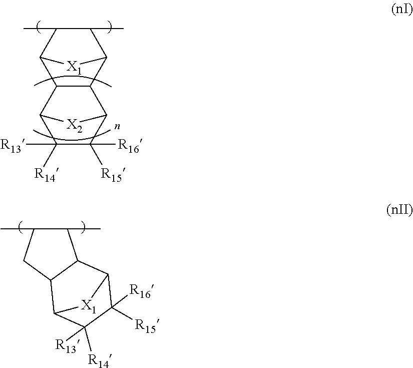

In General Formulae (nI) and (nII),

R₁₃′ to R₁₆′ each independently represent a hydrogen atom, a halogen atom, a cyano group, a hydroxyl group, a carboxyl group, an alkyl group, a cycloalkyl group, an alkoxy group, an alkoxycarbonyl group, an alkylcarbonyl group, a group having a lactone structure, or a group having an acid-decomposable group.

X₁ and X₂ each independently represent a methylene group, an ethylene group, an oxygen atom, or a sulfur atom.

n represents an integer of 0 to 2.

Examples of the acid-decomposable group in a group having an acid-decomposable group as R₁₃′ to R₁₆′ include a cumyl ester group, an enol ester group, an acetal ester group, and a tertiary alkyl ester group, and the acid-decomposable group is preferably a tertiary alkyl ester group represented by —C(═O)—O—R₀.

In the formula, R₀ represents a tertiary alkyl group such as a t-butyl group and a t-amyl group, an isobornyl group, a 1-alkoxyethyl group such as a 1-ethoxyethyl group, a 1-butoxyethyl group, a 1-isobutoxyethyl group, and a 1-cyclohexyloxyethyl group, an alkoxymethyl group such as a 1-methoxymethyl group and a 1-ethoxymethyl group, a 3-oxoalkyl group, a tetrahydropyranyl group, a tetrahydrofuranyl group, a trialkylsilyl ester group, a 3-oxocyclohexyl ester group, a 2-methyl-2-adamantyl group, and a mevalonic lactone residue.

At least one of R₁₃′, . . . , or R₁₆′ is preferably a group having an acid-decomposable group.

Examples of the halogen atom in R₁₃′ to R₁₆′ include a chlorine atom, a bromine atom, a fluorine atom, and an iodine atom.

The alkyl group of R₁₃′ to R₁₆′ is more preferably a group represented by the following General Formula (F1).

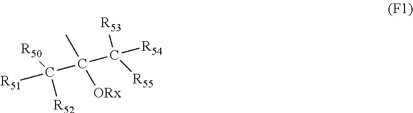

In General Formula (F1),

R₅₀ to R₅₅ each independently represent a hydrogen atom, a fluorine atom, or an alkyl group. However, at least one of R₅₀, . . . , or R₅₅ represents a fluorine atom or an alkyl group having at least one hydrogen atom substituted with a fluorine atom.

Rx represents a hydrogen atom or an organic group (preferably an acid-decomposable protecting group, an alkyl group, a cycloalkyl group, an acyl group, or an alkoxycarbonyl group), and preferably a hydrogen atom.

It is preferable that all of R₅₀ to R₅₅ are fluorine atoms.

Furthermore, from the viewpoint of the effects of the present invention, it is preferable that the acid-decomposable resin has an adamantane structure. In the case where the acid-decomposable resin has an adamantane structure, the glass transition point (Tg) of the polymer increases. As a result, in the case where the acid-decomposable resin has an adamantane structure, the solubility is reduced, and as a result, in the case where there is no high deprotection rate, the acid-decomposable resin is not dissolved in an alkali developer, and thus, the value of Dth(PTI) increases. Further, the solubility in the organic solvent developer is reduced and the patterns start to be cured with a low deprotection rate, and as a result, the value of Dth(NTI) decreases. Therefore, in the case where the acid-decomposable resin has an adamantane structure, ΔDth increases. In order to obtain such an effect, the proportion of the repeating units having an adamantane structures occupying the acid-decomposable resin is preferably 1% by mole or more, more preferably 5% by mole or more, and most preferably 10% by mole or more, with respect to all the repeating units in the acid-decomposable resin. From the viewpoint of the sensitivity, the proportion is still more preferably 50% by mole or less.

Aspects in which the adamantane structure is included in the acid-decomposable resin are not particularly limited, and for example, the adamantane structure may be included in the repeating unit (a-1) having an acid-decomposable group as described above or may be included as the repeating unit represented by General Formula (AIIa) as described above.

In addition to the repeating structural units above, the resin (A) can have a variety of repeating structural units for the purpose of adjusting dry etching resistance, suitability for a standard developer, adhesiveness to a substrate, and a resist profile, and characteristics generally required for the resist, such as resolving power, heat resistance, and sensitivity.

Examples of such repeating structural units include the repeating structural units corresponding to the monomers shown below, but are not limited thereto.

Accordingly, it is possible to minutely adjust the performance required for the resin (A), particularly
(1) solubility in a coating solvent,
(2) film-forming property (glass transition point),
(3) alkali developability,
(4) film reduction (selection of a hydrophilic, hydrophobic or alkali-soluble group),
(5) adhesiveness to a substrate of an unexposed area,
(6) dry etching resistance,
and the like.

Examples of such monomers include a compound having one addition-polymerizable unsaturated bond selected from acrylic acid esters, methacrylic acid esters, acrylamides, methacrylamides, allyl compounds, vinyl ethers, vinyl esters and the like.

In addition to these, an addition-polymerizable unsaturated compound that is copolymerizable with the monomers corresponding to the above-described various repeating structural units may be copolymerized. For example, as described in paragraphs 0029 to 0076 of JP2013-218223A, a repeating unit including a basic structure moiety, a repeating unit having a cyclic carbonate structure, described as Formula (1a-7) in <0045> of WO2011/122336A, or the like may be copolymerized.

In the resin (A), the molar ratio in the contents of the respective repeating structural units is appropriately set in order to control dry etching resistance of the resist, suitability for a standard developer, adhesiveness to a substrate and a resist profile, and performance generally required for the resist, such as resolving power, heat resistance, and sensitivity.

When the composition of the present invention is used for ArF exposure, in view of transparency with ArF light, it is preferable that the resin (A) does not have an aromatic group. Further, from the viewpoint of compatibility with a hydrophobic resin which will be described later, it is preferable that the resin (A) does not contain a fluorine atom and a silicon atom.

The resin (A) is preferably a resin in which all the repeating units are composed of (meth)acrylate-based repeating units. In this case, any one of the resin (A) in which all the repeating units are methacrylate-based repeating units, the resin (A) in which all the repeating units are acrylate-based repeating units, and the resin (A) in which all the repeating units are composed of methacrylate-based repeating units and acrylate-based repeating units can be used, but the content of the acrylate-based repeating units is preferably 50% by mole or less with respect to all the repeating units. It is more preferable that the resin (A) is a copolymer represented by General Formula (AI) including 20% to 50% by mole of (meth)acrylate-based repeating units having an acid-decomposable group, 20%0 to 50% by mole of (meth)acrylate-based repeating units having a lactone group, 5% to 30% by mole of (meth)acrylate-based repeating units having an alicyclic hydrocarbon structure substituted with a hydroxyl group or a cyano group, and further, 0% to 20% by mole of other (meth)acrylate-based repeating units.

In a case where the composition of the present invention is irradiated with KrF excimer laser light, electron beams, X-rays, or high-energy beams at a wavelength of 50 nm or less (EUV or the like), it is preferable that the resin (A) further contains repeating units having aromatic rings, in addition to the repeating units (a-1). Examples of the repeating units include a hydroxystyrene-based repeating unit, a vinylnaphthalene-based repeating unit, an indene-based repeating unit, and an acenaphthylene-based repeating unit. Among these, the hydroxystyrene-based repeating unit is preferably included. A hydroxystyrene-based repeating unit, a hydroxystyrene-based repeating unit protected with an acid-decomposable group, and an acid-decomposable repeating unit such as tertiary alkyl (meth)acrylate are still more preferable.

Preferred examples of the repeating unit having an acid-decomposable group include repeating units by t-butoxycarbonyloxystyrene, 1-alkoxyethoxystyrene, and tertiary alkyl (meth)acrylate, and repeating units by 2-alkyl-2-adamantyl (meth)acrylate and dialkyl(1-adamantyl)methyl (meth)acrylate are more preferable.

In one aspect, when the resin (A) is contained in the composition of the present invention as a resin exemplified below, it is preferable that ΔDth represented by Formula (1) as described above satisfies 0.8 or more. In the following specific examples, tBu represents a t-butyl group.

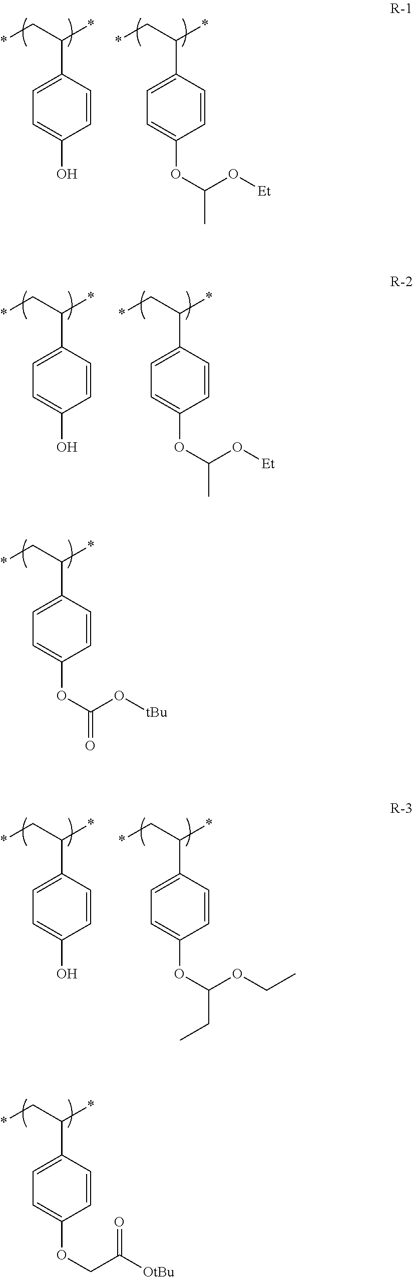

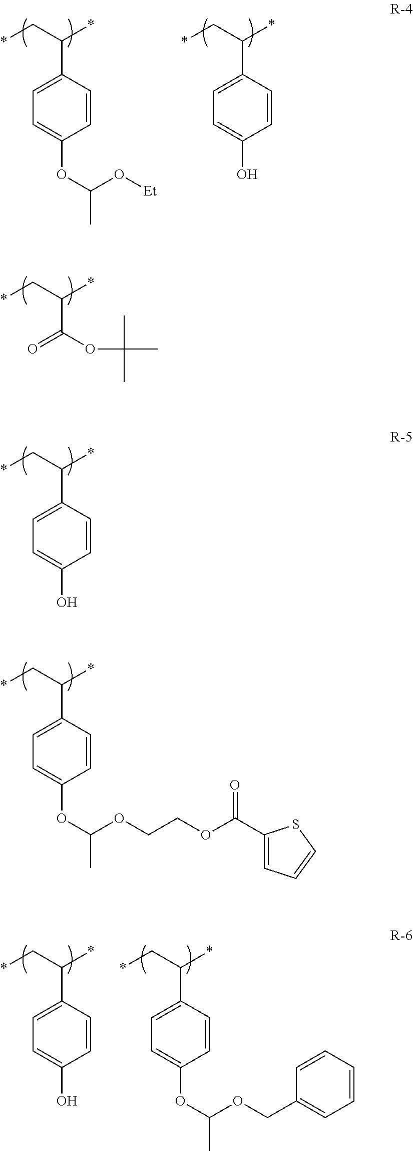

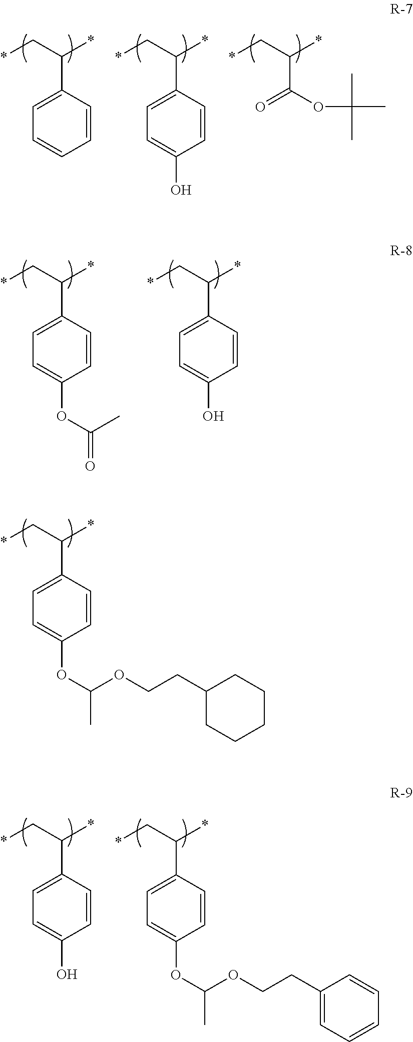

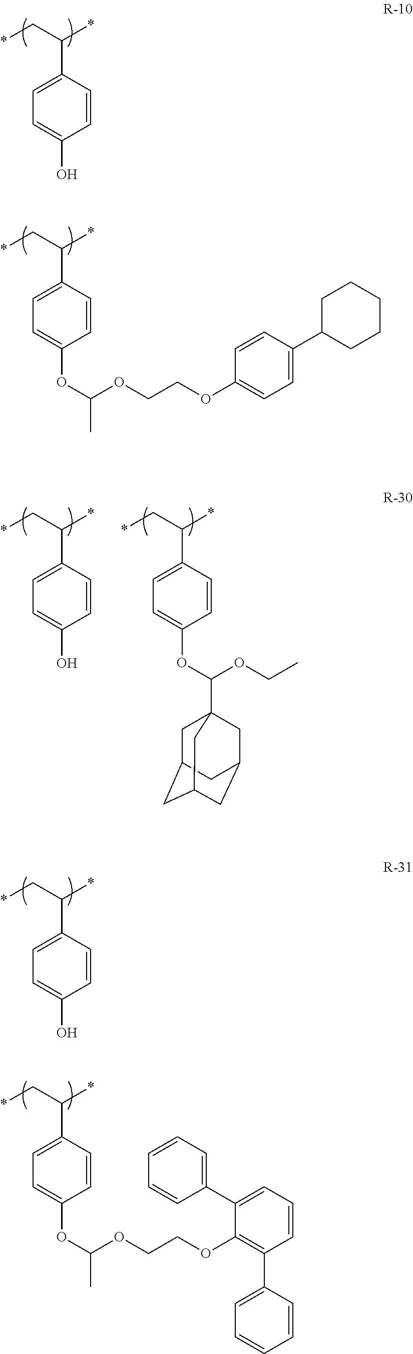

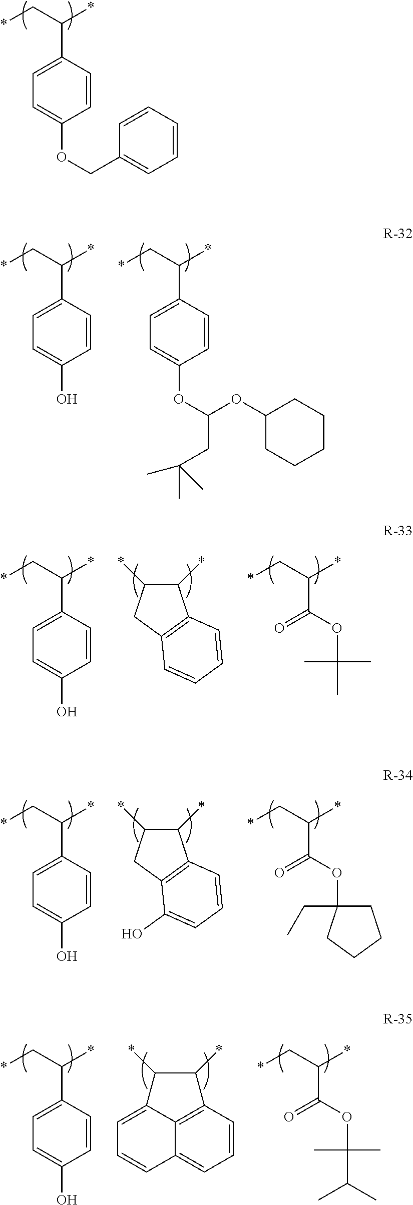

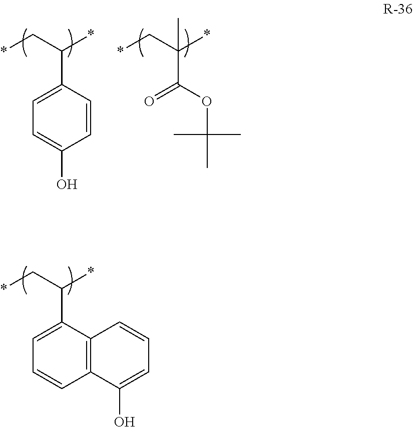

The resin (A) can be synthesized in accordance with an ordinary method such as radical polymerization, anionic polymerization, cationic polymerization, and living radical polymerization. Further, during polymerization, a known chain transfer agent or the like may be used in the field of high molecular polymerization. In addition, examples of the general synthesis method include a bulk polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, with the dropwise addition polymerization method being preferable. Examples of the reaction solvent include ethers such as tetrahydrofuran, 1,4-dioxane, and diisopropyl ether, ketones such as methyl ethyl ketone and methyl isobutyl ketone, ester solvents such as ethyl acetate, amide solvents such as dimethyl formamide and dimethyl acetamide, and a solvent which dissolves the composition of the present invention, such as propylene glycol monomethyl ether acetate, propylene glycol monomethyl ether, and cyclohexanone, which will be described later. It is more preferable to perform polymerization using the same solvent as the solvent used in the composition of the present invention. Thus, generation of the particles during storage can be suppressed.

It is preferable that the polymerization reaction is carried out in an inert gas atmosphere such as nitrogen and argon. As the polymerization initiator, commercially available radical initiators (azo-based initiators, peroxides, or the like) are used to initiate the polymerization. As the radical initiator, an azo-based initiator is preferable, and the azo-based initiator having an ester group, a cyano group, or a carboxyl group is preferable. Preferable initiators include azobisisobutyronitrile, azobisdimethylvaleronitrile, dimethyl 2,2′-azobis(2-methyl propionate), or the like. The initiator is added or added in portionwise, as desired, and after the reaction is completed, the reaction mixture is poured into a solvent, and then a desired polymer is recovered by a method such as powder or solid recovery. The concentration of the reactant is 5% to 50% by mass, and preferably 10% to 30% by mass. The reaction temperature is normally 10° C. to 150° C., preferably 30° C. to 120° C., and more preferably 60° C. to 100° C.

After completion of the reaction, the reaction solution is allowed to be cooled to room temperature and purified. The purification may be performed by normal methods. For example, a liquid-liquid extraction method of applying water washing or combining it with an appropriate solvent to remove the residual monomers or oligomer components; a purification method in a solution state, such as ultrafiltration of extracting and removing only the polymers having a molecular weight not more than a specific value; a re-precipitation method of dropwise adding the resin solution into a poor solvent to solidify the resin in the poor solvent, to thereby remove the residual monomers and the like; and a purification method in a solid state, such as washing of a resin slurry with a poor solvent after separation of the slurry by filtration.

For example, the resin is precipitated as a solid by contacting the reaction solution with a solvent in which the resin is sparingly soluble or insoluble (poor solvent) in a volumetric amount of 10 times or less, and preferably from 10 to 5 times the amount of the reaction solution. It is preferable that the residual monomers or oligomer components are removed by such a method, if possible.

The solvent (precipitation or reprecipitation solvent) for use in the operation of precipitation or reprecipitation from the polymer solution may be sufficient in the case where it is a poor solvent for the polymer, and the solvent which can be used may be appropriately selected from a hydrocarbon, a halogenated hydrocarbon, a nitro compound, an ether, a ketone, an ester, a carbonate, an alcohol, a carboxylic acid, water, and a mixed solvent containing these solvents, according to the kind of the polymer. Among these solvents, a solvent containing at least an alcohol (in particular, methanol or the like) or water is preferred as the precipitation or reprecipitation solvent.

The amount of the precipitation or reprecipitation solvent to be used can be appropriately selected in consideration of efficiency, a yield, and the like, but the amount used is 100 to 10,000 parts by mass, preferably 200 to 2,000 parts by mass, and more preferably 300 to 1,000 parts by mass, with respect to 100 parts by mass of the polymer solution.

The temperature in precipitation or reprecipitation can be appropriately selected in consideration of efficiency or operability, but is usually approximately 0° C. to 50° C., and preferably in the vicinity of room temperature (for example, approximately 20° C. to 35° C.). The precipitation or reprecipitation operation can be carried out using commonly employed mixing vessels such as a stirring tank by a known method such as a batch system and a continuous system.

The precipitated or reprecipitated polymer is usually subjected to commonly employed solid-liquid separation such as filtration and centrifugation, dried, and used. The filtration is carried out using a solvent resisting filter element preferably under pressure. The drying is carried out under atmospheric pressure or reduced pressure (preferably under reduced pressure) at a temperature of approximately 30° C. to 100° C., and preferably approximately 30° C. to 50° C.

Incidentally, after the resin is once precipitated and separated, the resin may be again dissolved in a solvent and then put into contact with a solvent in which the resin is sparingly soluble or insoluble. That is, there may be used a method including, after the completion of radical polymerization reaction, bringing the polymer into contact with a solvent in which the resin is sparingly soluble or insoluble, to precipitate a resin (step a), separating the resin from the solution (step b), dissolving the resin in a new solvent to prepare resin solution A (step c), bringing the resin solution A into contact with a solvent in which the resin is sparingly soluble or insoluble in a volumetric amount of less than 10 times (preferably 5 times or less) the resin solution A, to precipitate a resin solid (step d), and separating the precipitated resin (step e).

Furthermore, for keeping the resin from aggregating or the like after preparation of the composition, as described, for example, in JP2009-037108A, a step of dissolving the synthesized resin in a solvent to make a solution, and heating the solution at approximately 30° C. to 90° C. for approximately 30 minutes to 4 hours may be added.

From the viewpoint of the effects of the present invention, the weight-average molecular weight of the acid-decomposable resin as a value in terms of polystyrene by a GPC method is preferably 10,000 or more. In the case where the weight-average molecular weight of the acid-decomposable resin is large, the solubility in an alkali developer decreases, and accordingly, in the case where there is no high deprotection rate, the acid-decomposable resin is not dissolved in an alkali developer, and thus, the value of Dth(PTI) increases. Further, in the case where the weight-average molecular weight of the acid-decomposable resin is large, the solubility in an organic solvent developer decreases and the patterns start to be cured with a low deprotection rate, and thus, the value of Dth(NTI) decreases. Therefore, in the case where the weight-average molecular weight of the acid-decomposable resin is large, ΔDth increases. The weight-average molecular weight of the acid-decomposable resin is more preferably 15,000 or more, and particularly preferably 20,000 or more. From the viewpoint of suppression of swelling during development, the weight-average molecular weight of the acid-decomposable resin is still more preferably 30,000 or less.

The weight-average molecular weight (Mw), the number-average molecular weight (Mn), and the dispersity (Mw/Mn) of the resin is defined as a value in terms of polystyrene by GPC measurement (solvent: tetrahydrofuran, column: TSK gel Multipore HXL-M type, manufactured by TOSOH CORPORATION, column temperature: 40° C., flow rate: 1.0 mL/min, detector: RI).

The dispersity (molecular weight distribution) in the range of usually 1 to 3, preferably 1 to 2.6, still more preferably 1 to 2, and particularly preferably 1.4 to 1.7 is used. With a smaller molecular weight distribution, the resolution and the resist shape are more excellent.

In the composition of the present invention, the blend amount of the resin (A) in the entire composition is preferably 50% to 990% by mass, and more preferably 60% to 95% by mass, with respect to the total solid content.

Moreover, in the present invention, the resin (A) may be used alone or in combination of two or more kinds thereof. Further, a combination of a resin corresponding to the resin (A) and a resin not corresponding to the resin (A) and capable of decomposing by the action of an acid may also be used. In this case, the proportion of the resin corresponding to the resin (A) is preferably is 50% by mass or more of the total amount of the resin.

<Compound Capable of Generating Acid Upon Irradiation with Actinic Ray or Radiation>

The actinic ray-sensitive or radiation-sensitive resin composition of the present invention may contain a compound capable of generating an acid upon irradiation with actinic ray or radiation (which is hereinafter also referred to as a “compound (B)” or an “acid generator”).

The acid generator may be in a form of a low-molecular-weight compound or a form introduced into a part of a polymer. Further, a combination of the form of a low-molecular-weight compound or the form introduced into a part of a polymer may also be used.

In a case where the acid generator is in the form of a low-molecular-weight compound, the molecular weight is preferably 3,000 or less, more preferably 2,000 or less, and still more preferably 1,000 or less.

In a case where the acid generator is in the form introduced into a part of a polymer, it may be introduced into a part of the acid-decomposable resin as described above or into a resin different from the acid-decomposable resin.

In the present invention, the acid generator is preferably in the form of a low-molecular-weight compound.

In one aspect of the present invention, examples of the acid generator include the compounds represented by the following General Formula (ZI), (ZII) or (ZIII).

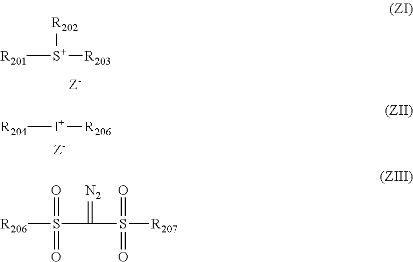

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two members out of R₂₀₁ to R₂₀₃ may be bonded to each other to form a ring structure, and the ring may contain an oxygen atom, a sulfur atom, an ester bond, an amide bond, or a carbonyl group. Examples of the group formed by the mutual bonding of two members out of R₂₀₁ to R₂₀₃ include an alkylene group (for example, a butylene group and a pentylene group).

Moreover, the acid generator may be a compound having a plurality of structures represented by General Formula (ZI). For example, the acid generator may be a compound having a structure in which at least one of R₂₀₁, . . . , or R₂₀₃ of the compound represented by General Formula (ZI) is bonded to at least one of R₂₀₁, . . . , or R₂₀₃ of another compound represented by General Formula (ZI) through a single bond or a linking group.

Z⁻ refers to a non-nucleophilic anion (an anion having an extremely low ability of causing a nucleophilic reaction).

Examples of Z⁻ include a sulfonate anion (an aliphatic sulfonate anion, an aromatic sulfonate anion, and a camphorsulfonate anion), a carboxylate anion (an aliphatic carboxylate anion, an aromatic carboxylate anion, and an aralkylcarboxylate anion), a sulfonylimido anion, a bis(alkylsulfonyl)imido anion, and a tris(alkylsulfonyl)methide anion.

The aliphatic moiety in the aliphatic sulfonate anion and the aliphatic carboxylate anion may be an alkyl group, or a cycloalkyl group, and preferred examples thereof include a linear or branched alkyl group having 1 to 30 carbon atoms or a cycloalkyl group having 3 to 30 carbon atoms.

Preferred examples of the aromatic group in the aromatic sulfonate anion and the aromatic carboxylate anion include an aryl group having 6 to 14 carbon atoms, such as a phenyl group, a tolyl group, and a naphthyl group.

The aforementioned alkyl group, cycloalkyl group, and aryl group may have a substituent. Specific examples of the substituent include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). The aryl group or ring structure which each of the groups has may further have an alkyl group (preferably having 1 to 15 carbon atoms) as a substituent.

The aralkyl group in the aralkylcarboxylate anion is preferably an aralkyl group having 7 to 12 carbon atoms, and examples thereof include a benzyl group, a phenethyl group, a naphthylmethyl group, a naphthylethyl group and a naphthylbutyl group.

Examples of the sulfonylimido anion include a saccharin anion.

The alkyl group in the bis(alkylsulfonyl)imido anion and tris(alkylsulfonyl)methide anion is preferably an alkyl group having 1 to 5 carbon atoms, and examples of the substituent on this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom and a fluorine atom-substituted alkyl group being preferred.

Other examples of Z⁻ include fluorinated phosphorus (for example, PF₆⁻), fluorinated boron (for example, BF₄⁻), and fluorinated antimony (for example, SbF₆⁻).

Z⁻ is preferably an aliphatic sulfonate anion substituted with a fluorine atom at least at the α-position of sulfonic acid, an aromatic sulfonate anion substituted with a fluorine atom or a group having a fluorine atom, a bis(alkylsulfonyl)imido anion in which the alkyl group is substituted with a fluorine atom, or a tris(alkylsulfonyl)methide anion in which the alkyl group is substituted with a fluorine atom.

In one aspect of the present invention, the number of fluorine atoms included in the anion as Z⁻ is preferably 2 or 3.

From the viewpoint of the acid strength, the pKa of the acid generated is preferably −1 or less so as to enhance the sensitivity.

Examples of the organic group of R₂₀₁, R₂₀₂, and R₂₀₃ include an aryl group (preferably having 6 to 15 carbon atoms), a linear or branched alkyl group (preferably having 1 to 10 carbon atoms), and a cycloalkyl group (preferably having 3 to 15 carbon atoms).

It is preferable that at least one of R₂₀₁, R₂₀₂, or R₂₀₃ is an aryl group, and it is more preferable that all of these three members are aryl groups. The aryl group may be a heteroaryl group such as indole residue and pyrrole residue, other than a phenyl group, a naphthyl group, and the like.

The aryl group, the alkyl group, and the cycloalkyl group of R₂₀₁, R₂₀₂, and R₂₀₃ may further have a substituent, and examples of the substituent include, but are not limited to, a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

Furthermore, two members selected from R₂₀₁, R₂₀₂, and R₂₀₃ may be bonded through a single bond or a linking group. Examples of the linking group include, but are not limited to, an alkylene group (preferably having 1 to 3 carbon atoms), —O—, —S—, —CO—, and —SO₂—.

Examples of the preferred structure in a case where at least one of R₂₀₁, R₂₀₂, or R₂₀₃ is not an aryl group include cation structures such as the compounds exemplified in paragraphs 0046 and 0047 of JP2004-233661A, paragraphs 0040 to 0046 of JP2003-35948A, the compounds exemplified as Formulae (I-1) to (I-70) in US2003/0224288A1, and the compounds exemplified as Formulae (IA-1) to (IA-54), and Formulae (IB-1) to (IB-24) in US2003/0077540A1.

More preferred examples of the compound represented by General Formula (ZI) include a compound represented by General Formula (ZI-3) or (ZI-4) which will be described below. First, the compound represented by General Formula (ZI-3) will be described.

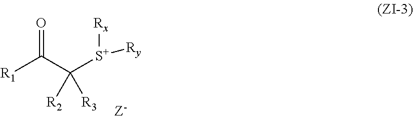

In General Formula (ZI-3),

R₁ represents an alkyl group, a cycloalkyl group, an alkoxy group, a cycloalkoxy group, an aryl group, or an alkenyl group,

R₂ and R₃ each independently represent a hydrogen atom, an alkyl group, a cycloalkyl group, or an aryl group, and R₂ and R₃ may be linked to each other to form a ring,

R₁ and R₂ may be linked to each other to form a ring structure,

R_{X} and R_{y} each independently represent an alkyl group, a cycloalkyl group, an alkenyl group, an aryl group, a 2-oxoalkyl group, a 2-oxocycloalkyl group, an alkoxycarbonylalkyl group, an alkoxycarbonylcycloalkyl group. R_{X} and R_{y} may be linked to each other to form a ring structure, and this ring structure may include an oxygen atom, a nitrogen atom, a sulfur atom, a ketone group, an ether bond, an ester bond, or an amide bond.

Z⁻ represents a non-nucleophilic anion.

The alkyl group as R₁ preferably a linear or branched alkyl group having 1 to 20 carbon atoms, and may have an oxygen atom, a sulfur atom, or a nitrogen atom in the alkyl chain. Specific examples thereof include branched alkyl groups. The alkyl group of R₁ may have a substituent.

The cycloalkyl group as R₁ is preferably a cycloalkyl group having 3 to 20 carbon atoms, and may have an oxygen atom or a sulfur atom in the ring. The cycloalkyl group of R₁ may have a substituent.

The alkoxy group as R₁ is preferably an alkoxy group having 1 to 20 carbon atoms. The alkoxy group as R₁ may have a substituent.

The cycloalkoxy group as R₁ preferably a cycloalkoxy group having 3 to 20 carbon atoms. The cycloalkoxy group of R₁ may have a substituent.

The aryl group as R₁ is preferably an aryl group having 6 to 14 carbon atoms. The aryl group of R₁ may have a substituent.

Examples of the alkenyl group as R₁ include a vinyl group and an allyl group.

R₂ and R₃ represent a hydrogen atom, an alkyl group, a cycloalkyl group, or an aryl group, and R₂ and R₃ may be linked to each other to form a ring. However, at least one of R₂ or R₃ represents an alkyl group, a cycloalkyl group, or an aryl group. Specific and preferred examples of the alkyl group, the cycloalkyl group, and the aryl group for R₂ or R₃ are the same specific and preferred examples as described above for R₁. In a case where R₂ and R₃ are linked to each other to form a ring, the total number of carbon atoms contributing to formation of a ring included in R₂ and R₃ is preferably 4 to 7, and particularly preferably 4 or 5.

R₁ and R₂ may be linked to each other to form a ring structure. In a case where R₁ and R₂ are linked to each other to form a ring, it is preferable that R₁ is an aryl group (preferably a phenyl group having a substituent or a naphthyl group having a substituent) and R₂ is an alkylene group having 1 to 4 carbon atoms (preferably a methylene group or an ethylene group), and preferred examples of the substituent include the same ones as the substituent which the aryl group as R₁ may have. In another aspect of a case where R₁ and R₂ are linked to each other to form a ring, it is also preferable that R₁ is a vinyl group and R₂ is an alkylene group having 1 to 4 carbon atoms.

The alkyl group represented by R_{X} and R_{y} is preferably an alkyl group having 1 to 15 carbon atoms.

The cycloalkyl group represented by R_{X} and R_{y} is preferably a cycloalkyl group having 3 to 20 carbon atoms.

The alkenyl group represented by R_{X} and R_{y} is preferably an alkenyl group having 2 to 30 carbon atoms, and examples thereof include a vinyl group, an allyl group, and a styryl group.

The aryl group represented by R_{X} and R_{y} is preferably, for example, an aryl group having 6 to 20 carbon atoms, and preferably a phenyl group or a naphthyl group, and more preferably a phenyl group.

Examples of the alkyl group moiety of the 2-oxoalkyl group and the alkoxycarbonylalkyl group represented by R_{X} and R_{y} include those enumerated above as R_{X} and R_{y}.

Examples of the cycloalkyl group moiety in the 2-oxocycloalkyl group and the alkoxycarbonylcycloalkyl group represented by R_{X} and R_{y} include those enumerated above as R_{X} and R_{y}.

In one aspect, R_{X} and R_{y} are preferably bonded to each other to form a ring structure. This ring structure is preferably a 5-membered ring or 6-membered ring including the sulfur atom of General Formula (ZI-3). Further, an aspect in which this ring structure includes an ether bond is preferable since it is expected that decomposition products upon irradiation with actinic ray or radiation are less volatilized as an out gas.

Examples of Z⁻ include those enumerated above as Z⁻ in General Formula (ZI) as described above.

Specific examples of the cationic moiety of the compound represented by General Formula (ZI-3) will be described below.

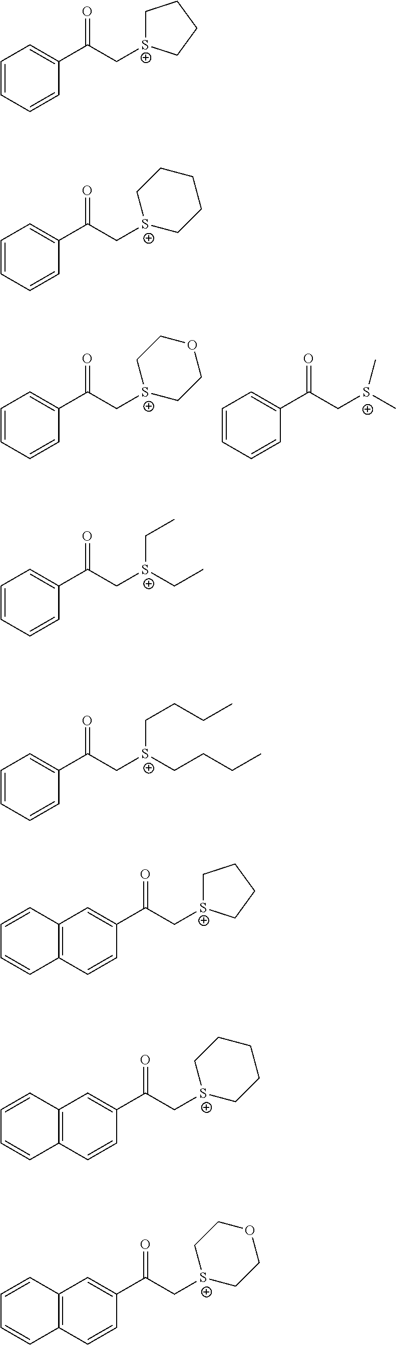

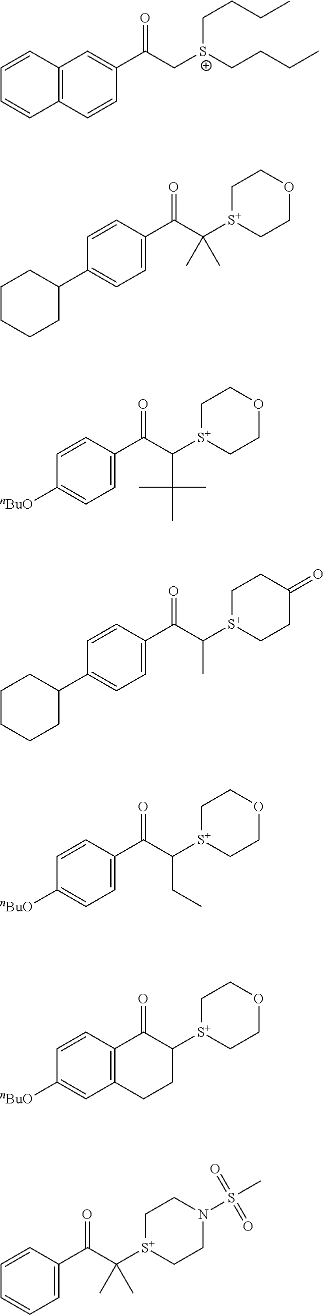

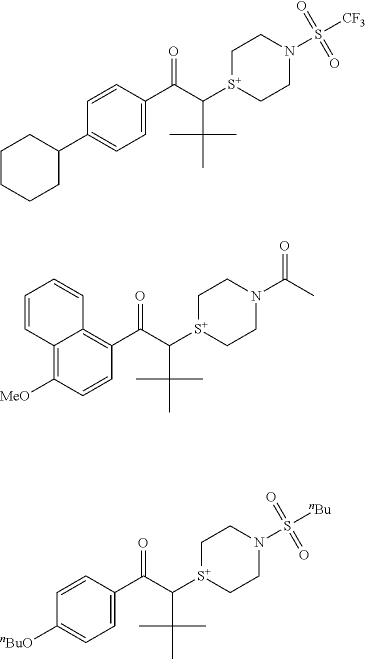

Next, the compound represented by General Formula (ZI-4) will be described.

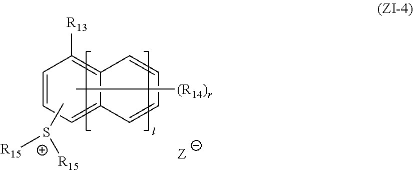

In General Formula (ZI-4),

R₁₃ represents a hydrogen atom, a fluorine atom, a hydroxyl group, an alkyl group, a cycloalkyl group, an alkoxy group, an alkoxycarbonyl group or a group having a cycloalkyl group. These groups may have substituents.

In a case where there are a plurality of R₁₄'s, R₁₄'s each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have substituents.

R₁₅'s each independently represent an alkyl group, a cycloalkyl group or a naphthyl group. Two R₁₅'s may be bonded to each other to form a ring, and may contain a heteroatom as an atom constituting the ring such as an oxygen atom, a sulfur atom and a nitrogen atom. These groups may have substituents.

l represents an integer of 0 to 2.

r represents an integer of 0 to 8.

Z⁻ represents a non-nucleophilic anion, and examples thereof include the non-nucleophilic anions as Z⁻ in General Formula (ZI).

In General Formula (ZI-4), the alkyl group of R₁₃, R₁₄, or R₁₅ is linear or branched, and preferably has 1 to 10 carbon atoms.

The cycloalkyl group of R₁₃, R₁₄, or R₁₅ may be a monocyclic or polycyclic cycloalkyl group.

The alkoxy group of R₁₃ or R₁₄ is linear or branched, and preferably has 1 to 10 carbon atoms.

The alkoxycarbonyl group of R₁₃ or R₁₄ is linear or branched, and preferably has 2 to 11 carbon atoms.

Examples of a group having the cycloalkyl group of R₁₃ or R₁₄ include groups having monocyclic or polycyclic cycloalkyl groups. These groups may further have substituents.

Examples of the alkyl group in the alkylcarbonyl group of R₁₄ include the same specific examples as mentioned for the alkyl groups as R₁₃ to R₁₅.

The alkylsulfonyl group and the cycloalkylsulfonyl group of R₁₄ are linear, branched, or cyclic, and preferably have 1 to 10 carbon atoms.

Examples of a substituent that each group may have include halogen atoms (for example, a fluorine atom), a hydroxyl group, a carboxyl group, a cyano group, a nitro group, an alkoxy group, an alkoxyalkyl group, an alkoxycarbonyl group, and an alkoxycarbonyloxy group.

Examples of the ring structure which may formed by the mutual bonding of two R₁₅'s include a 5- or 6-membered ring formed by two R₁₅'s together with a sulfur atom in General Formula (ZI-4), and particularly preferably a 5-membered ring (that is, a tetrahydrothiophene ring or a 2,5-dihydrothiophene ring) and may be fused with an aryl group or a cycloalkyl group. Two R₁₅'s may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, and an alkoxycarbonyloxy group. A plurality of substituents may be present for the ring structure, and may be bonded to each other to form a ring.

In General Formula (ZI-4), R₁₅ is preferably a methyl group, an ethyl group, a naphthyl group or a divalent group capable of forming a tetrahydrothiophene ring structure together with the sulfur atom by the mutual bonding of two R₁₅'s, and is particularly preferably a divalent group capable of forming a tetrahydrothiophene ring structure together with the sulfur atom by the mutual bonding of two R₁₅'s.

The substituent that R₁₃ and R₁₄ may have is preferably a hydroxyl group, an alkoxy group, an alkoxycarbonyl group or a halogen atom (particularly a fluorine atom).

l is preferably 0 or 1, and more preferably 1.

r preferably ranges from 0 to 2.

Specific examples of the cationic structure in the compound represented by General Formula (ZI-3) or (ZI-4) as described above include the cationic structures of chemical structures exemplified in paragraphs 0046, 0047, 0072 to 0077, 0107 to 0110 of JP2011-53360A, and the chemical structures exemplified in paragraphs 0135 to 0137, 0151, 0196 to 0199 of JP2011-53430A as well as the cationic structures of the compounds exemplified in the specification of JP2004-233661A, JP2003-35948A, US2003/0224288A1, and US2003/0077540A1.

In General Formulae (ZII) and (ZIII),

R₂₀₄ to R₂₀₇ each independently represent an aryl group, an alkyl group, or a cycloalkyl group.

The aryl group, the alkyl group, and the cycloalkyl group of R₂₀₄ to R₂₀₇ are the same as the aryl group, the alkyl group, and the cycloalkyl group of R₂₀₁ to R₂₀₃ in the compound (ZI) as described above.

The aryl group, the alkyl group, and the cycloalkyl group of R₂₀₄ to R₂₀₇ may have substituents. The substituents may be the same as those which the aryl group, the alkyl group, and the cycloalkyl group of R₂₀₁ to R₂₀₃ in the compound (ZI) as described above may have.

Examples of Z⁻ include those enumerated as Z⁻ in General Formula (ZI) as described above.

Next, preferred structures of non-nucleophilic anion Z⁻ will be described.

The non-nucleophilic anion Z⁻ is preferably a sulfonate anion represented by General Formula (2).

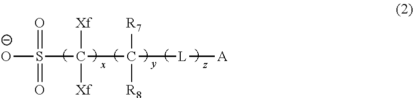

In General Formula (2),

Xf's each independently represent a fluorine atom or an alkyl group substituted with at least one fluorine atom.

R₇ and R₈ each independently represent a hydrogen atom, a fluorine atom, an alkyl group, or an alkyl group substituted with at least one fluorine atom, and in a case where R₇ and R₈ are present in plural numbers, they may be the same as or different from each other.

L represents a divalent linking group, and in a case where L's are present in plural numbers, they may be the same as or different from each other.

A represents an organic group including a cyclic structure.

x represents an integer of 1 to 20. y represents an integer of 0 to 10. z represents an integer of 0 to 10.

The anion of General Formula (2) will be described in more detail.

Xf is a fluorine atom or an alkyl group substituted with at least one fluorine atom, as described above, and as an alkyl group in the alkyl group substituted with a fluorine atom, an alkyl group having 1 to 10 carbon atoms is preferable, and an alkyl group having 1 to 4 carbon atoms is more preferable. Further, the alkyl group substituted with a fluorine atom of Xf is preferably a perfluoroalkyl group.

Xf is preferably a fluorine atom or a perfluoroalkyl group having 1 to 4 carbon atoms. Specifically, Xf is a fluorine atom or CF₃. It is particularly preferable that both Xf's are fluorine atoms.

R₇ and R₈ each represent a hydrogen atom, a fluorine atom, an alkyl group, or an alkyl group substituted with at least one fluorine atom as described above, and the alkyl group is preferably an alkyl group having 1 to 4 carbon atoms, and more preferably a perfluoroalkyl group having 1 to 4 carbon atoms. As a specific example of the alkyl group substituted with at least one fluorine atom in R₇ and R₈, CF₃ is preferable.

L represents a divalent linking group, —COO—, —OCO—, —CO—, —O—, —S—, —SO—, —SO₂—, —N(Ri)- (in the formula, Ri represents a hydrogen atom or an alkyl group), an alkylene group (preferably having 1 to 6 carbon atoms), a cycloalkylene group (preferably having 3 to 10 carbon atoms), an alkenylene group (preferably having 2 to 6 carbon atoms), or a divalent linking group formed by combination of these plurality of groups. L is preferably —COO—, —OCO—, —CO—, —SO₂—, —CON(Ri)-, —SO₂N(Ri)-, —CON(Ri)-alkylene group-, —N(Ri)CO-alkylene group-, —COO-alkylene group-, or —OCO-alkylene group-, and more preferably —COO—, —OCO—, —SO₂—, —CON(Ri)-, or —SO₂N(Ri)-. In a case where L's are present in plural numbers, they may be the same as or different from each other.

The alkyl group as Ri is preferably a linear or branched alkyl group having 1 to 20 carbon atoms, and may have an oxygen atom, a sulfur atom, or a nitrogen atom in the alkyl chain. Specific examples of the alkyl group include a linear alkyl group and a branched alkyl group. Examples of the alkyl group having a substituent include a cyanomethyl group, a 2,2,2-trifluoroethyl group, a methoxycarbonylmethyl group, and an ethoxycarbonylmethyl group.

The organic group including a cyclic structure of A is not particularly limited as long as it has a cyclic structure, and examples thereof include structures with an alicyclic group, an aryl group, a heterocyclic group (including not only an aromatic heterocyclic group but also a non-aromatic heterocyclic group, for example, a tetrahydropyran ring and a lactone ring structure).

The alicyclic group may be monocyclic or polycyclic. Further, a nitrogen atom-containing alicyclic group such as a piperidine group, a decahydroquinoline group, and a decahydroisoquinoline group is preferable. Among these, an alicyclic group having a bulky structure having 7 or more carbon atoms, such as a norbornyl group, a tricyclodecanyl group, a tetracyclodecanyl group, a tetracyclododecanyl group, an adamantyl group, a decahydroquinoline group, a decahydroisoquinoline group, and a steroid skeleton is preferable from the viewpoints of suppressing diffusion in a film in a post exposure baking (PEB) step, and improving exposure latitude.

Examples of the aryl group include a benzene ring, a naphthalene ring, a phenanthrene ring, and an anthracene ring. Among these, naphthalene having a low light absorbance is preferable from the viewpoint of the light absorbance at 193 nm.

Examples of the heterocyclic group include a furan ring, a thiophene ring, a benzofuran ring, a benzothiophene ring, a dibenzofuran ring, a dibenzothiophene ring, and a pyridine ring. Among these, a furan ring, a thiophene ring, and a pyridine ring are preferable.

The cyclic organic group may have a substituent, and examples of its substituent include an alkyl group (which may be linear, branched, or cyclic, and preferably has 1 to 12 carbon atoms), an aryl group (preferably having 6 to 14 carbon atoms), a hydroxy group, an alkoxy group, an ester group, an amido group, an urethane group, an ureido group, a thioether group, a sulfonamido group, a sulfonic acid ester group, and a cyano group.

Moreover, carbon constituting an organic group including a cyclic structure (carbon contributing ring formation) may be carbonyl carbon.

x is preferably 1 to 8, more preferably 1 to 4, and particularly preferably 1. y is preferably 0 to 4, more preferably 0 or 1, and still more preferably 0. z is preferably 0 to 8, more preferably 0 to 4, and still more preferably 1.

Furthermore, in one aspect of the present invention, the number of fluorine atoms in the anion represented by General Formula (2) is preferably 2 or 3, and with this number, the effects of the present invention can be enhanced.

Specific examples of the sulfonate anion structure represented by General Formula (2) are shown below, but the present invention is not limited thereto.

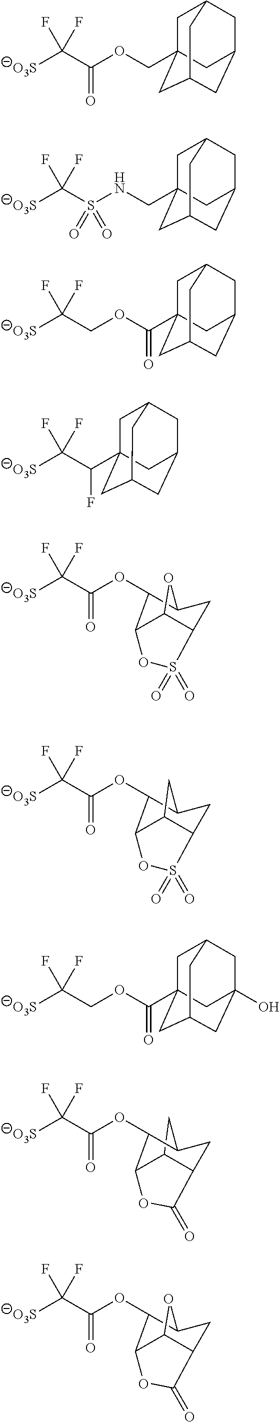

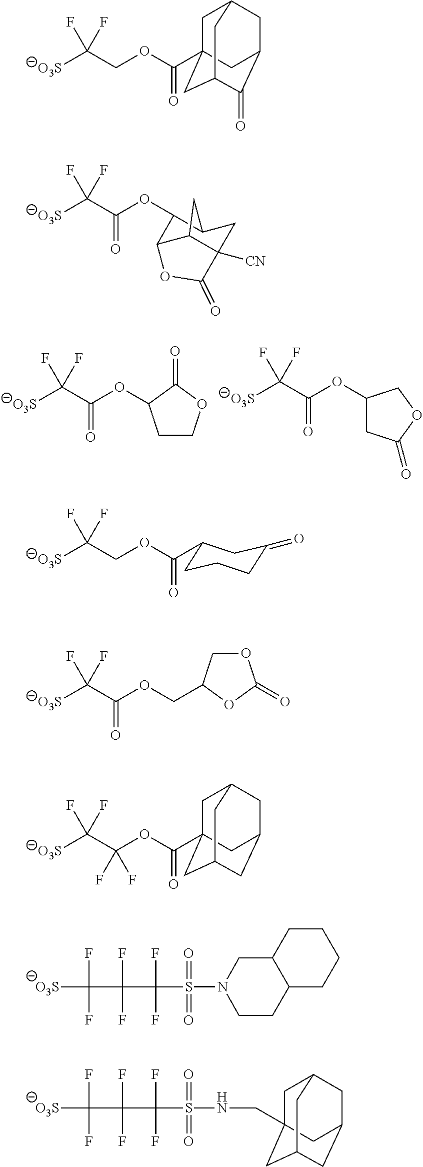

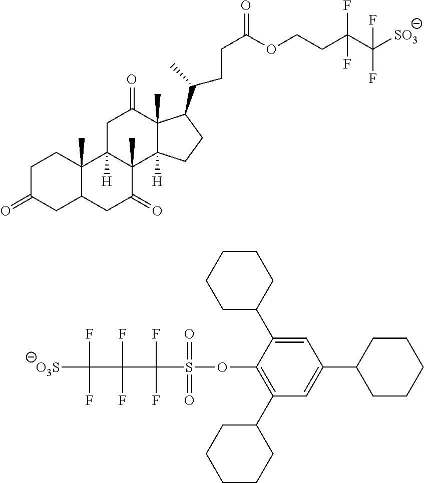

Z⁻ is also preferably a sulfonate anion represented by the following General Formula (B-1).

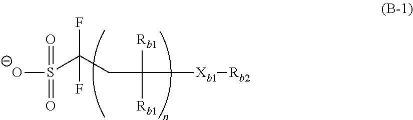

In General Formula (B-1),

R_{b1}'s each independently represent a hydrogen atom, a fluorine atom, or a trifluoromethyl group (CF₃).

n represents an integer of 0 to 4.

n is preferably an integer of 0 to 3, and more preferably 0 or 1.

X_{b1} represents a single bond, an alkylene group, an ether bond, an ester bond (—OCO— or —COO—), a sulfonic acid ester bond (—OSO₂— or —SO₃—), or a combination thereof.

X_{b1} is preferably an ester bond (—OCO— or —COO—) or a sulfonic acid ester bond (—OSO₂— or —SO₃—), and more preferably an ester bond (—OCO— or —COO—).

R_{b2} represents an organic group having 6 or more carbon atoms.

As for R₁₂, the organic group having 6 or more carbon atoms is preferably a bulky group, and may be an alkyl group, an alicyclic group, an aryl group, or a heterocyclic group which has 6 or more carbon atoms.

As for R_{b2}, the alkyl group having 6 or more carbon atoms may be linear or branched, and is preferably a linear or branched alkyl group having 6 to 20 carbon atoms. Examples thereof may include a linear or branched hexyl group, a linear or branched heptyl group, and a linear or branched octyl group. From the viewpoint of volume, a branched alkyl group is preferred.

As for R_{b2}, the alicyclic group having 6 or more carbon atoms may be monocyclic or polycyclic. Among them, an alicyclic group with a bulky structure having 7 or more carbon atoms such a norbornyl group, a tricyclodecanyl group, a tetracyclodecanyl group, a tetracyclododecanyl group or an adamantyl group is preferable from the viewpoints of inhibiting diffusivity into the film during post exposure baking (PEB) process and improving MEEF (Mask Error Enhancement Factor).

As for R_{b2}, the aryl group having 6 or more carbon atoms may be monocyclic or polycyclic. Examples of the aryl group include a phenyl group, a naphthyl group, a phenanthryl group and an anthryl group. Among them, a naphthyl group showing a relatively low light absorbance at 193 nm is preferable.

As for R_{b2}, the heterocyclic group having 6 or more carbon atoms may be monocyclic or polycyclic, but is preferably polycyclic so as to suppress acid diffusion. Further, the heterocyclic group may have aromaticity or may not have aromaticity. Examples of the heterocycle having aromaticity include a benzofuran ring, a benzothiophene ring, a dibenzofuran ring and a dibenzothiophene ring. Examples of the heterocycle having no aromaticity include a tetrahydropyran ring, a lactone ring, a sultone ring, and a decahydroisoquinoline ring.

As for R_{b2}, the substituent having 6 or more carbon atoms may further have a substituent. Examples of the substituent may include an alkyl group (which may be linear or branched, and preferably has 1 to 12 carbon atoms), a cycloalkyl group (which may be monocyclic, polycyclic, or spirocyclic, and preferably has 3 to 20 carbon atoms), an aryl group (preferably having 6 to 14 carbon atoms), a hydroxy group, an alkoxy group, an ester group, an amido group, an urethane group, an ureido group, a thioether group, a sulfonamido group and a sulfonic acid ester group. Meanwhile, a carbon which constitutes the alicyclic group, the aryl group or the heterocyclic group as described above (a carbon contributing to ring formation) may be a carbonyl carbon.

Specific examples of the sulfonate anion structure represented by General Formula (B-1) are shown below, but the present is not limited thereto. In addition, the following specific examples also include those corresponding to the sulfonate anion represented by General Formula (2) as described above.

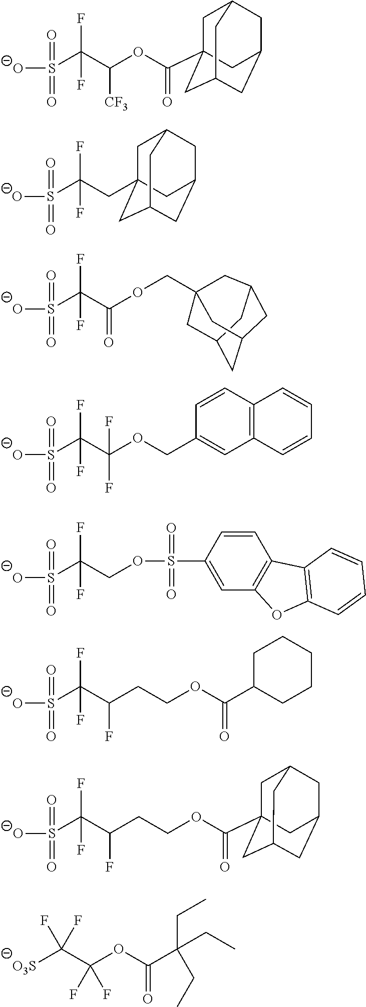

Z⁻ is also preferably a sulfonate anion represented by the following General Formula (A-I).

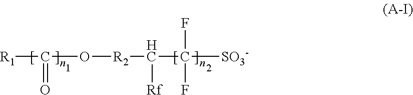

In General Formula (A-I),

R₁ is an alkyl group, a monovalent alicyclic hydrocarbon group, an aryl group or a heteroaryl group.

R₂ is a divalent linking group.

Rf is a fluorine atom or an alkyl group substituted with at least one fluorine atom.

n₁ and n₂ each independently are 0 or 1.

The alkyl group represented by R₁ is preferably an alkyl group having 1 to 20 carbon atoms, more preferably an alkyl group having 1 to 10 carbon atoms, still more preferably an alkyl group having 1 to 5 carbon atoms, and particularly preferably an alkyl group having 1 to 4 carbon atoms.

Furthermore, the alkyl group may have a substituent (preferably a fluorine atom), and the alkyl group having the substituent is preferably a perfluoroalkyl group having 1 to 5 carbon atoms.

The monovalent alicyclic hydrocarbon group represented by R₁ preferably has 5 or more carbon atoms. Further, the carbon number of the monovalent alicyclic hydrocarbon group is preferably 20 or less, and more preferably 15 or less. The monovalent alicyclic hydrocarbon group may be a monocyclic alicyclic hydrocarbon group or a polycyclic alicyclic hydrocarbon group. A part of —CH₂— in the alicyclic hydrocarbon group may be substituted with —O— or —C(═O)—.

The monocyclic alicyclic hydrocarbon group preferably has 5 to 12 carbon atoms, and is preferably a cyclopentyl group, a cyclohexyl group, or a cyclooctyl group.

The polycyclic alicyclic hydrocarbon group preferably has 10 to 20 carbon atoms, and is preferably a norbornyl group, an adamantyl group, or a noradamantyl group.

The aryl group represented by R₁ preferably has 6 or more carbon atoms. Further, the carbon number of the aryl group is preferably 20 or less, and more preferably 15 or less.

The heteroaryl group represented by R₁ preferably has 2 or more carbon atoms. Further, the carbon number of the heteroaryl group is preferably 20 or less, and more preferably 15 or less.

The aryl group or the heteroaryl group may be a monocyclic aryl group or a monocyclic heteroaryl group, and may be a polycyclic aryl group or a polycyclic heteroaryl group. Specific examples thereof include a phenyl group, a naphthyl group, an anthracenyl group, a pyridyl group, a thienyl group, a furanyl group, a quinolyl group, and an isoquinolyl group.

As for R₁, the monovalent alicyclic hydrocarbon group, the aryl group and the heteroaryl group may further have substituents, and examples of the substituents may include a hydroxyl group, a halogen atom (a fluorine atom, a chlorine atom, a bromine atom, an iodine atom, and the like), a nitro group, a cyano group, an amido group, a sulfonamido group, an alkyl group, an alkoxy group, an alkoxycarbonyl group, an acyl group, an acyloxy group, and a carboxy group.

R₁ is particularly preferably a cyclohexyl group or an adamantyl group.

The divalent linking group represented by R₂ is not particularly limited, but examples thereof include —COO—, —OCO—, —CO—, —O—, —S—, —SO—, —SO₂—, an alkylene group (preferably an alkylene group having 1 to 30 carbon atoms), a cycloalkylene group (preferably a cycloalkylene group having 3 to 30 carbon atoms), an alkenylene group (preferably an alkenylene group having 2 to 30 carbon atoms), an arylene group (preferably an arylene group having 6 to 30 carbon atoms), a heteroarylene group (preferably a heteroarylene group having 2 to 30 carbon atoms) and a group obtained by combining two or more kinds of these. The alkylene group, the cycloalkylene group, the alkenylene group, the arylene group and the heteroarylene group may further have substituents, and specific examples of the substituents may be the same as those described for the monovalent alicyclic hydrocarbon group, the aryl group and the heteroaryl group as R₁.

The divalent linking group represented by R₂ is preferably an alkylene group, a cycloalkylene group, an alkenylene group, an arylene group, or a heteroarylene group, more preferably an alkylene group, still more preferably an alkylene group having 1 to 10 carbon atoms, and particularly preferably an alkylene group having 1 to 5 carbon atoms.

Rf is preferably a fluorine atom or an alkyl group substituted with at least one fluorine atom. The number of carbon atoms of the alkyl group is more preferably 1 to 4. Further, the alkyl group substituted with at least one fluorine atom is preferably a perfluoroalkyl group. More specifically, Rf is preferably a fluorine atom or CF₃.

n₁ is preferably 1.

n₂ is preferably 1.

Preferred specific examples of the sulfonate anion represented by General Formula (A-I) are shown below, but the present invention is not limited thereto. In addition, the following specific examples also include those corresponding to the sulfonate anion represented by General Formula (2) as described above.

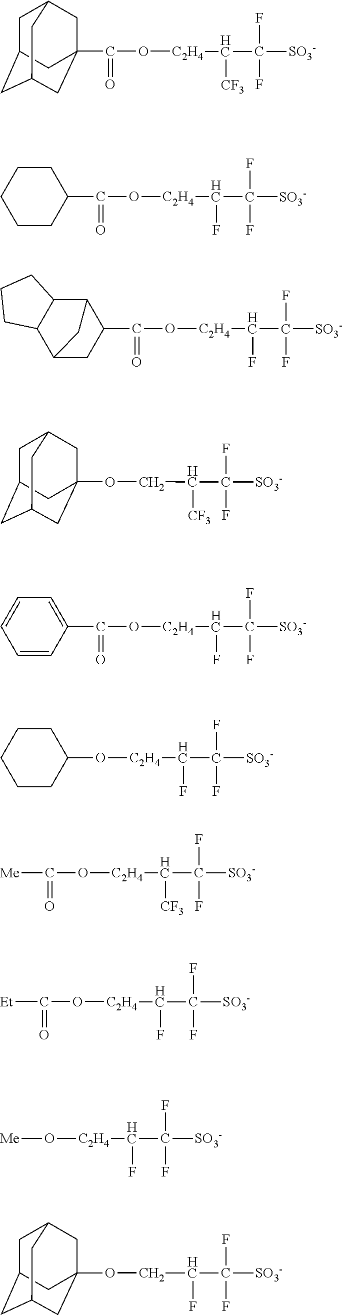

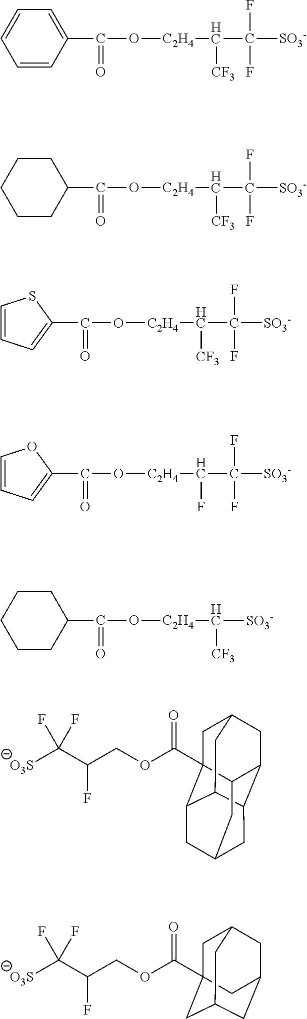

The non-nucleophilic anion Z⁻ may be a disulfonylimidate anion represented by General Formula (2′).

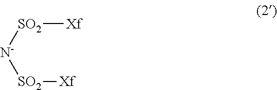

In General Formula (2′),

Xf is the same as defined in General Formula (2) and preferred examples are also the same. Two Xf's in General Formula (2′) may be linked to each other to form a ring structure.

As for Z⁻, the disulfonylimidate anion is preferably a bis(alkylsulfonyl)imido anion.

The alkyl group in the bis(alkylsulfonyl)imido anion is preferably an alkyl group having 1 to 5 carbon atoms.

Two alkyl groups in the bis(alkylsulfonyl)imido anion may be linked to each other to form an alkylene group (preferably having 2 to 4 carbon atoms), or may form a ring together with an imido group and two sulfonyl groups. The ring structure which the bis(alkylsulfonyl)imido anion may form is preferably a 5- to 7-membered ring, and more preferably a 6-membered ring.

Examples of the substituent which an alkylene group formed by the mutual linking of these alkyl groups, and two alkyl groups include a halogen atom, an alkyl group substituted with a halogen atom, an alkoxy group, an alkylthio group, an alkyloxysulfonyl group, an aryloxysulfonyl group, and a cycloalkylaryloxysulfonyl group, with a fluorine atom or an alkyl group substituted with a fluorine atom being preferable.

Examples of the acid generator further include a compound represented by the following General Formula (ZV).

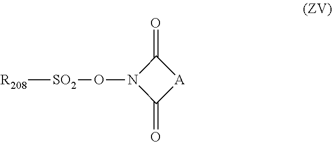

In General Formula (ZV),

R₂₀₈ represents an alkyl group, a cycloalkyl group, or an aryl group.

A represents an alkylene group, an alkenylene group, or an arylene group.

Specific examples of the aryl group of R₂₀₈ include the same specific examples as mentioned for the aryl group as R₂₀₁ to R₂₀₃ in General Formula (ZI).

Specific example of the alkyl group and the cycloalkyl group of R₂₀₈ may be the same as those for the alkyl group and the cycloalkyl group, respectively as R₂₀₁ to R₂₀₃ in General Formula (ZI).

Examples of the alkylene group of A include an alkylene group having 1 to 12 carbon atoms, examples of the alkenylene group of A include an alkenylene group having 2 to 12 carbon atoms, and examples of the arylene group of A include an arylene group having 6 to 10 carbon atom.

Examples of the acid generator are shown below, but the present invention is not limited thereto.

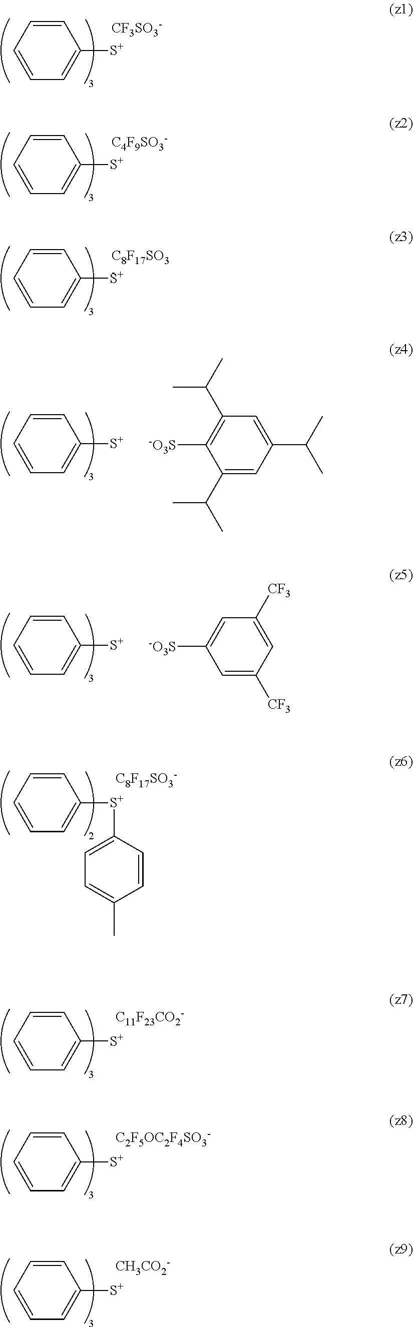

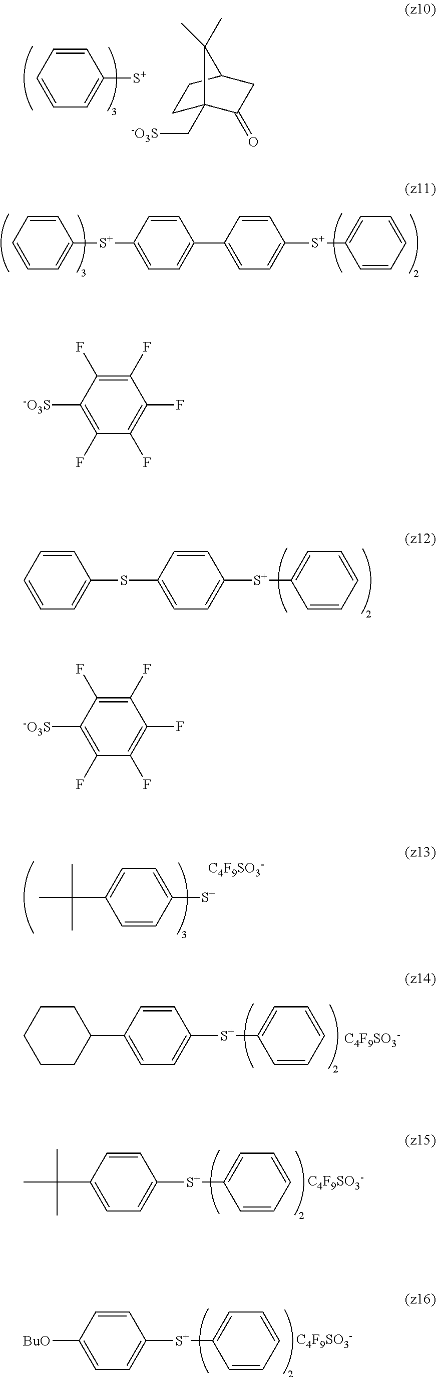

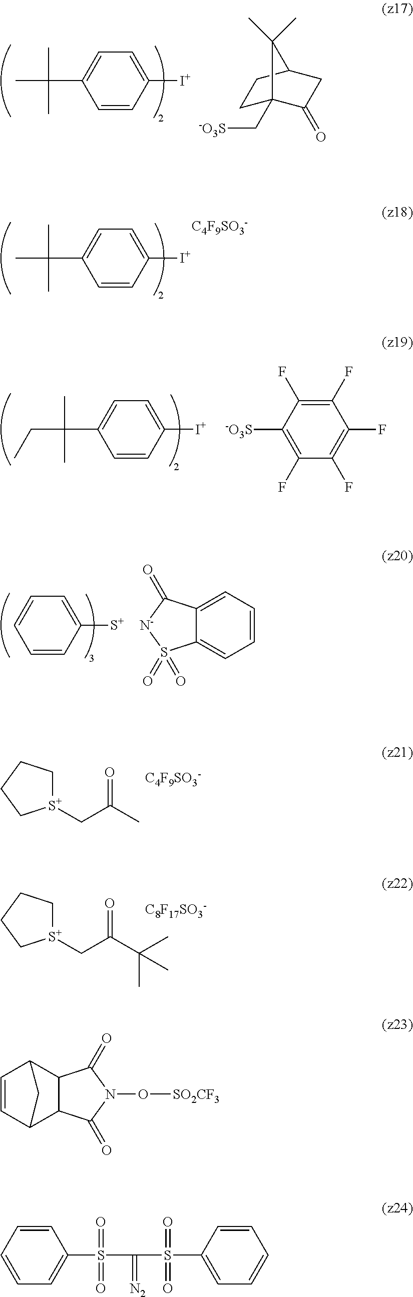

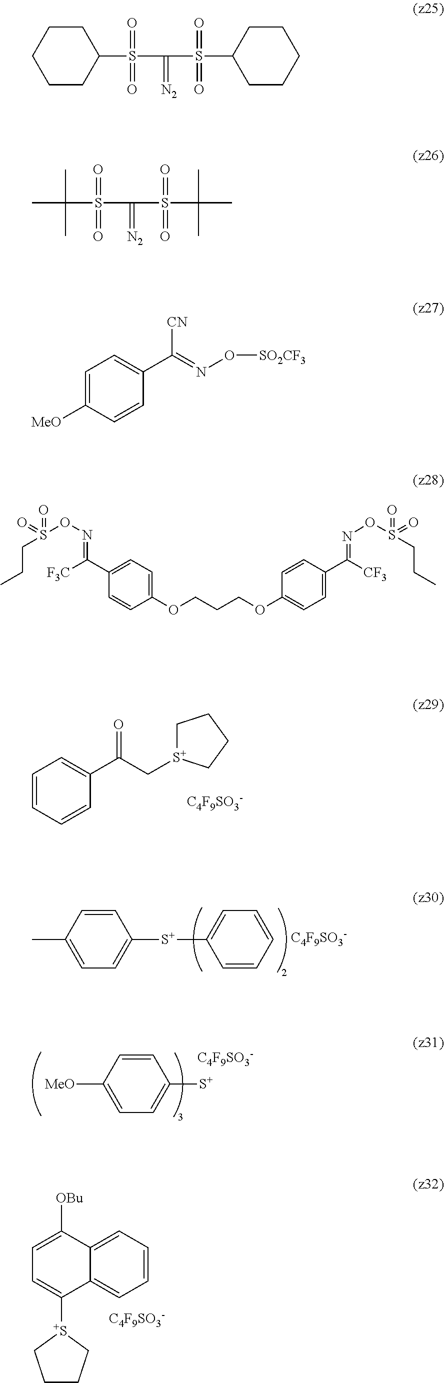

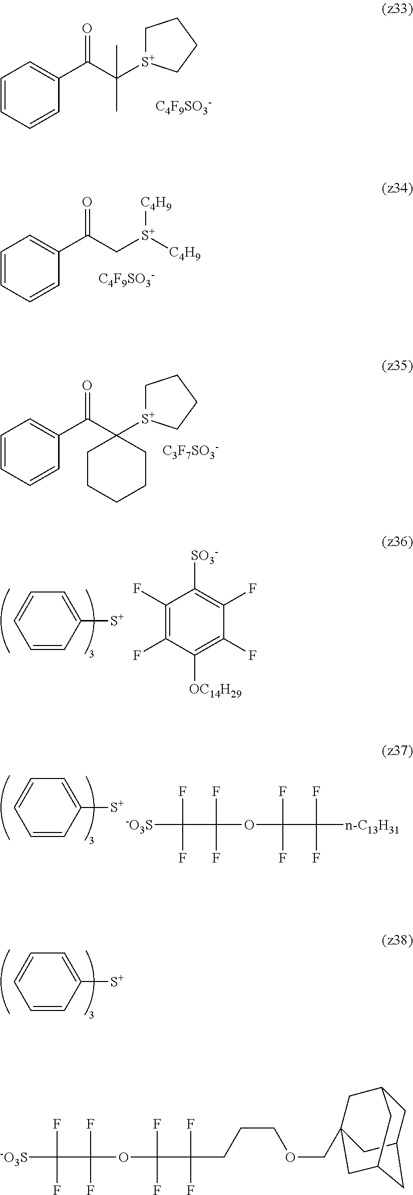

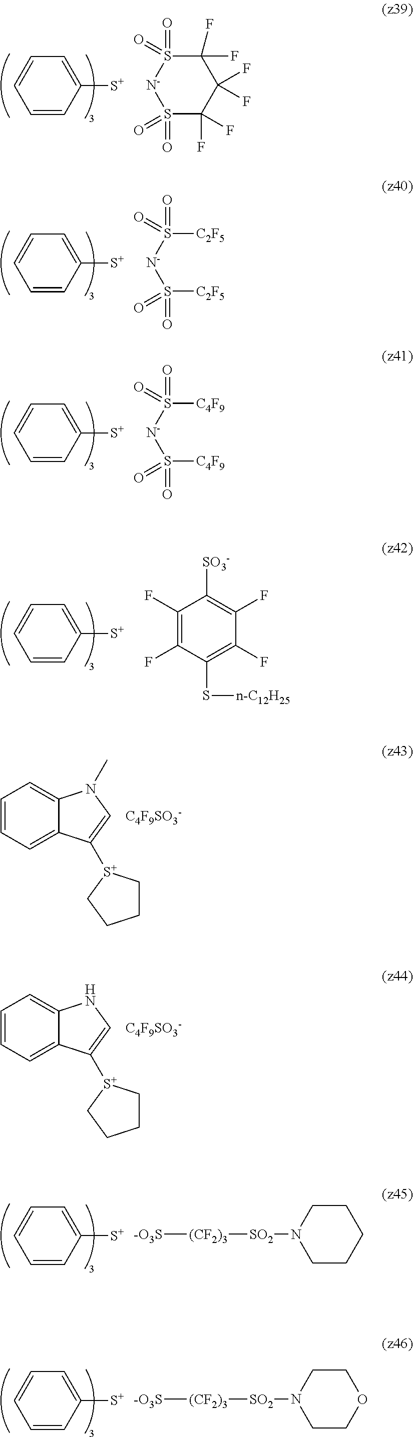

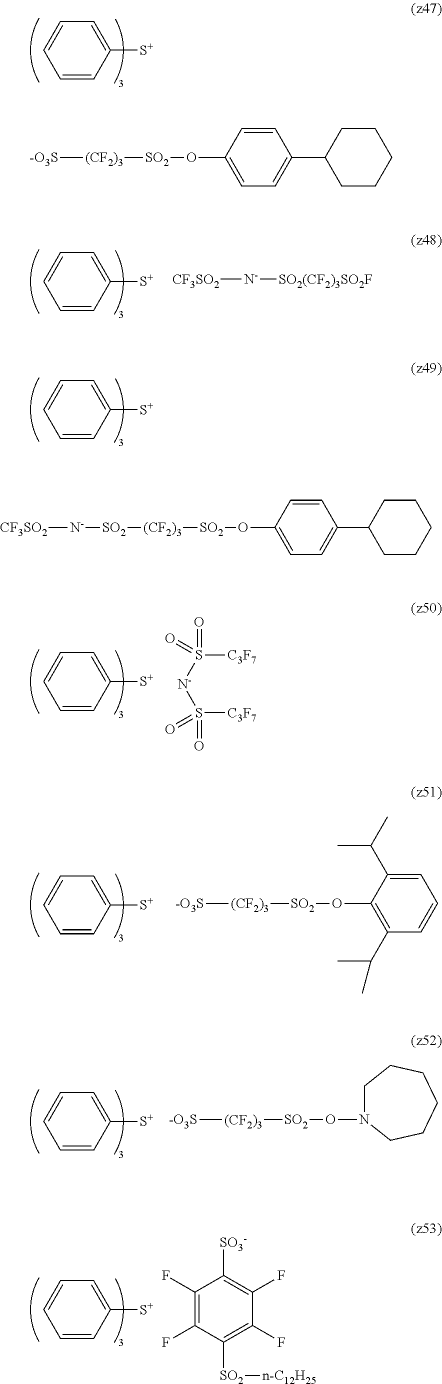

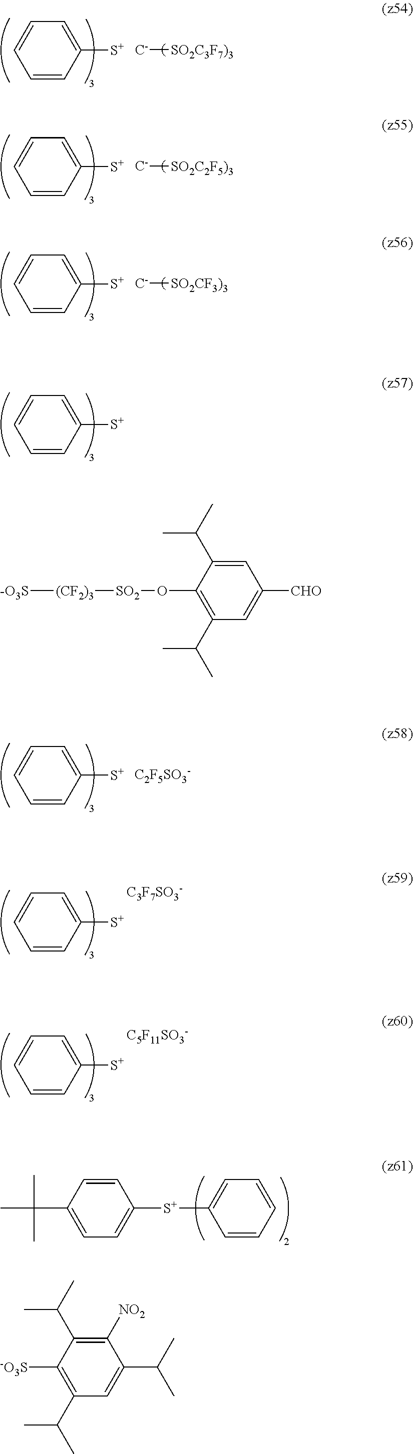

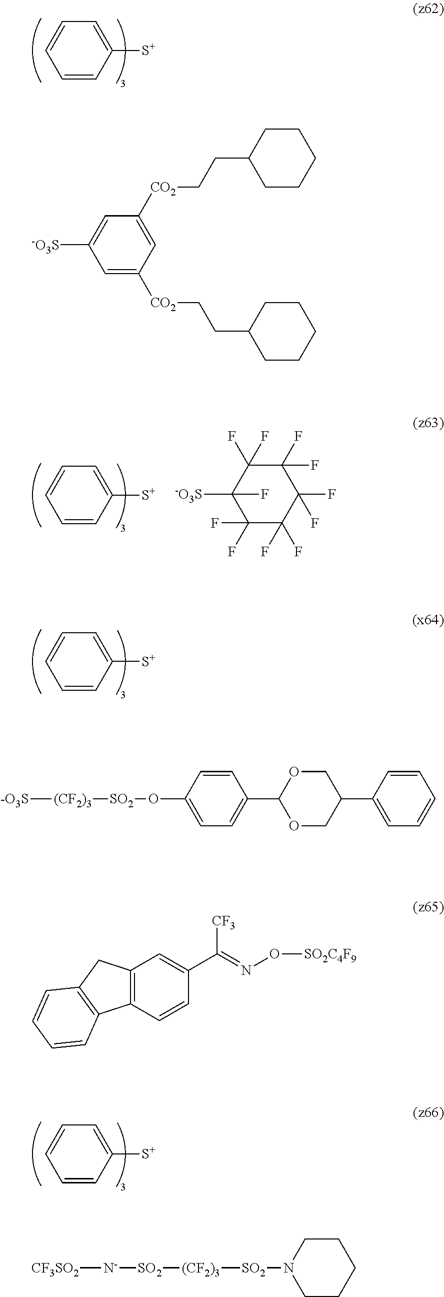

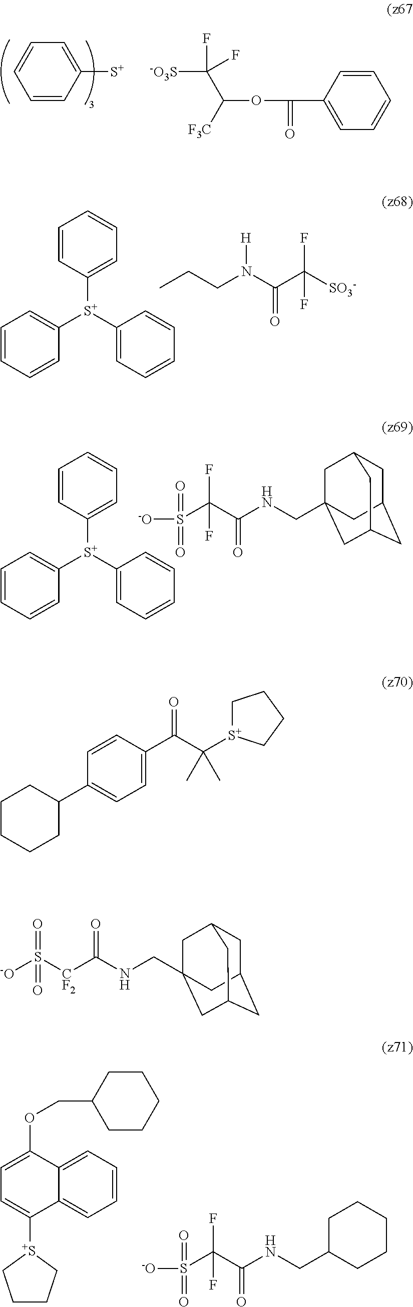

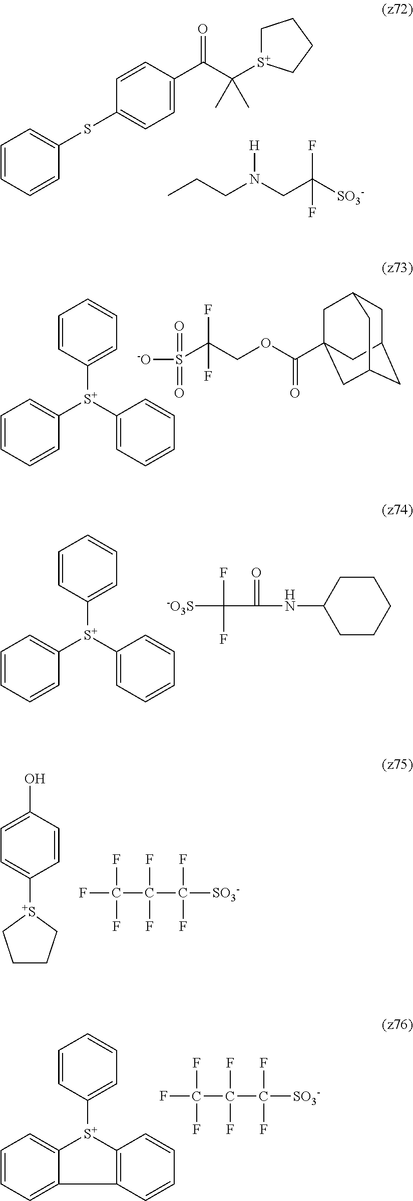

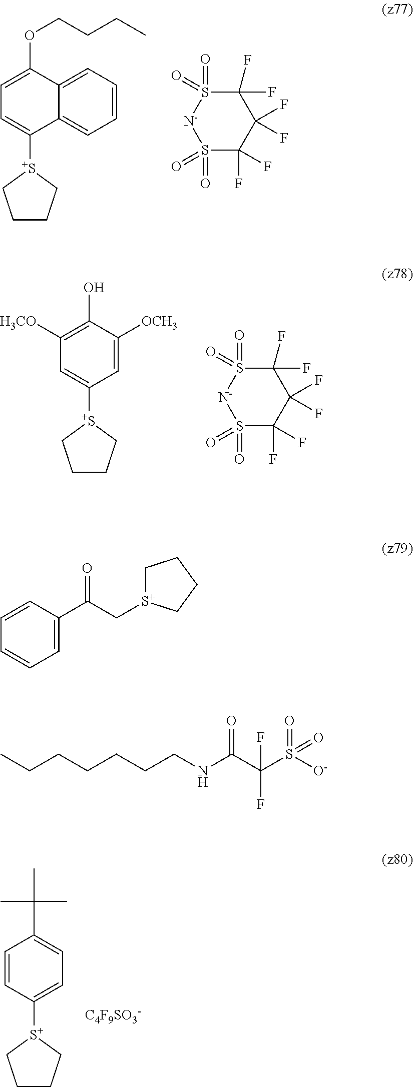

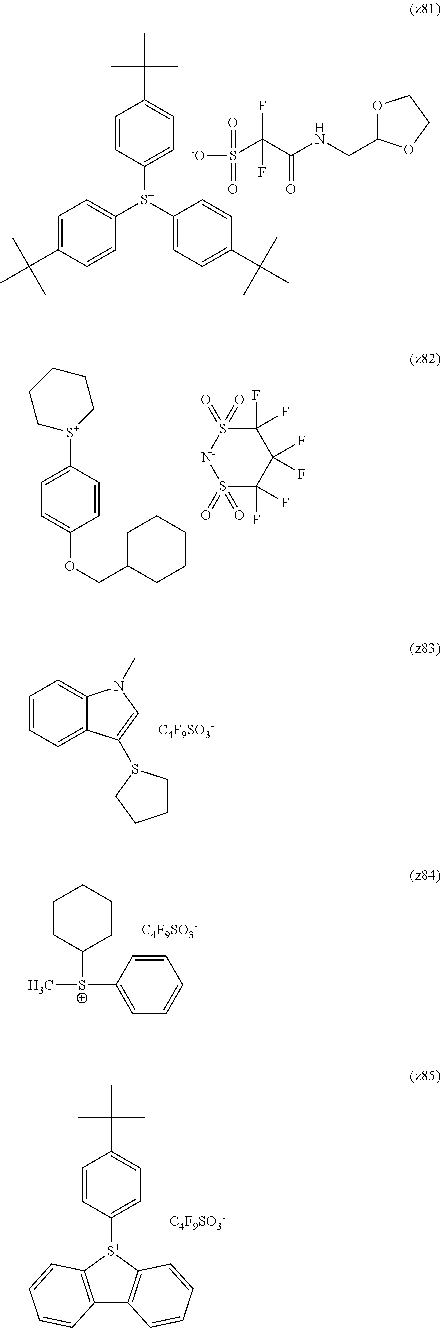

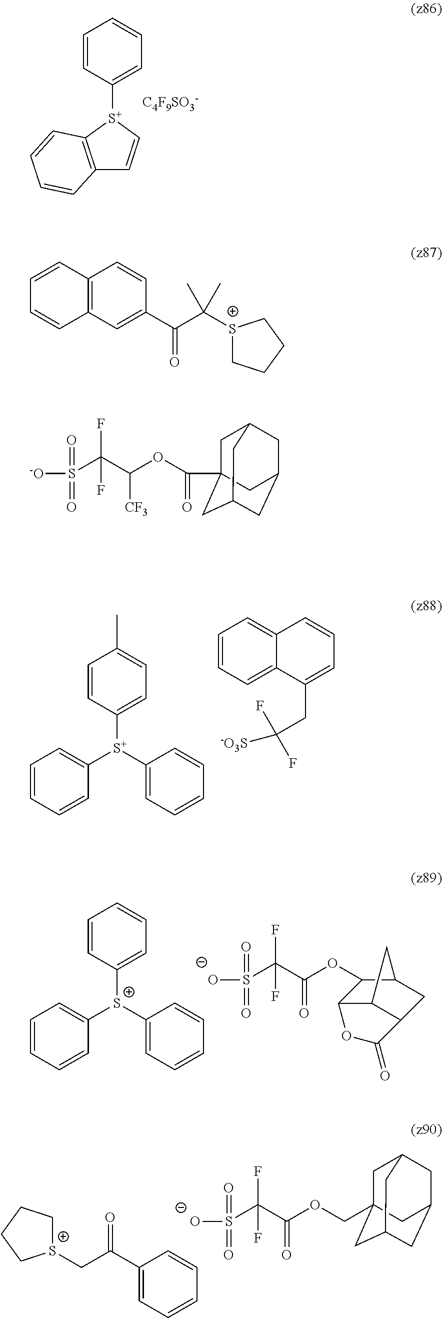

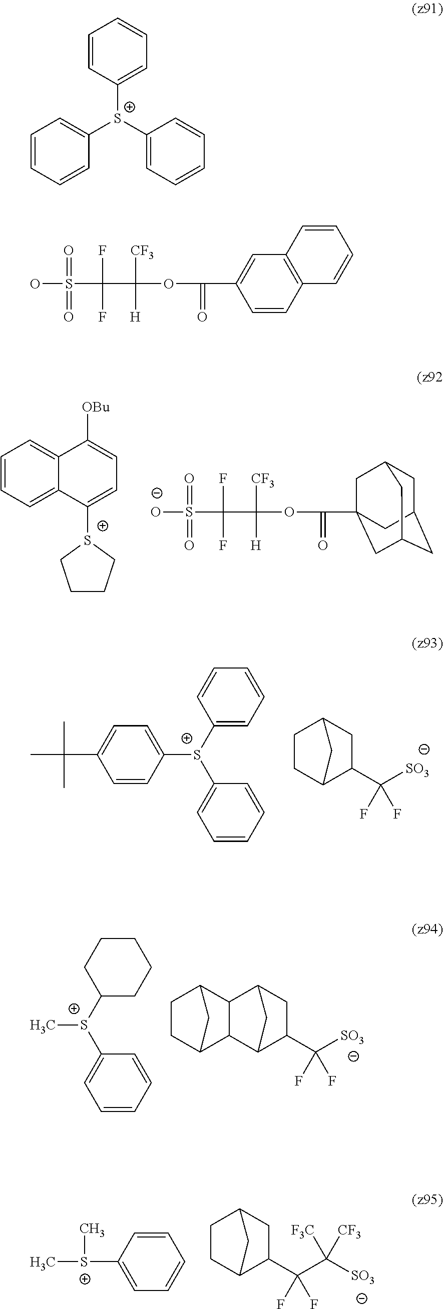

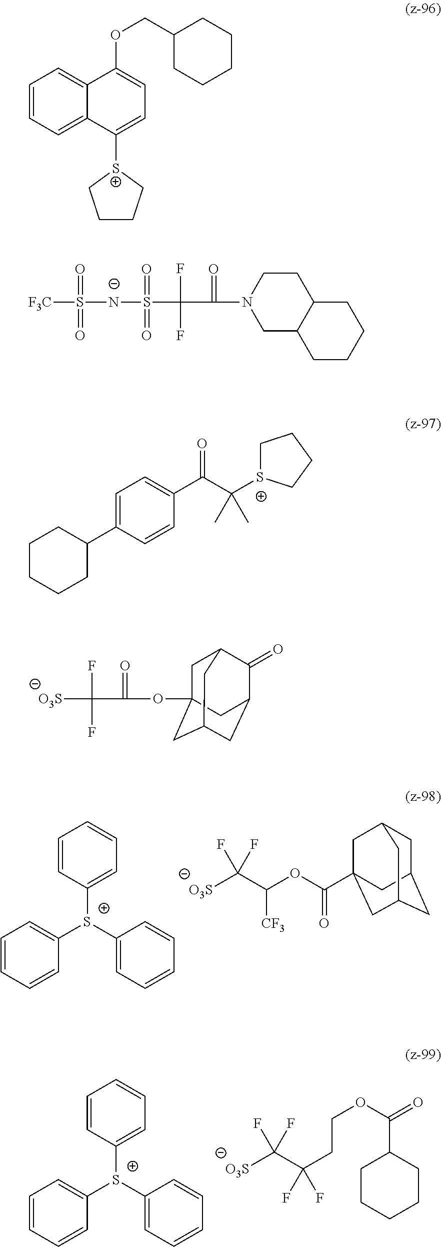

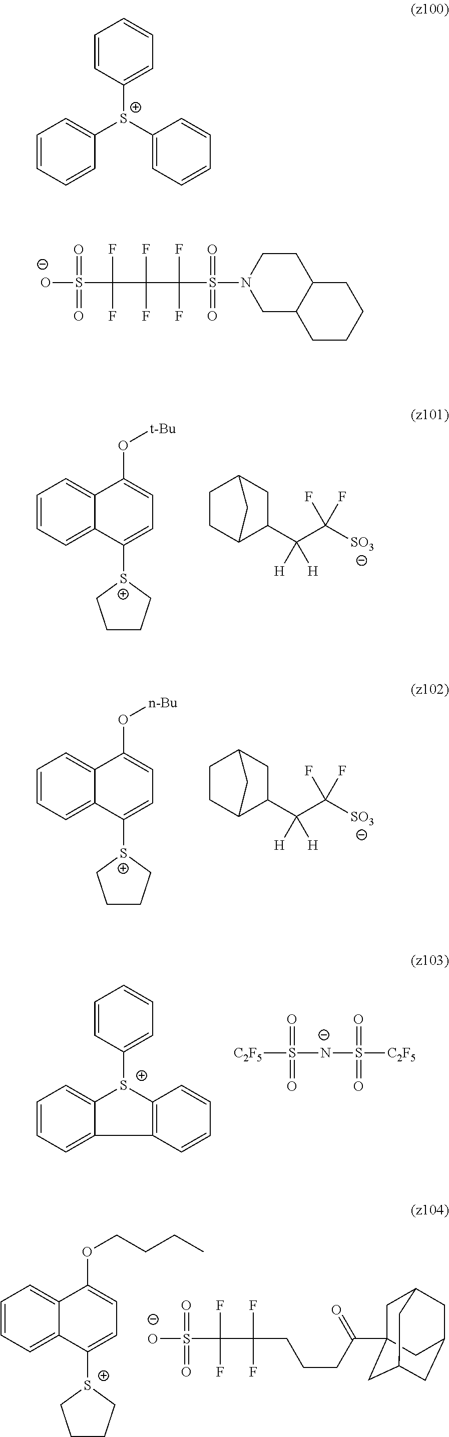

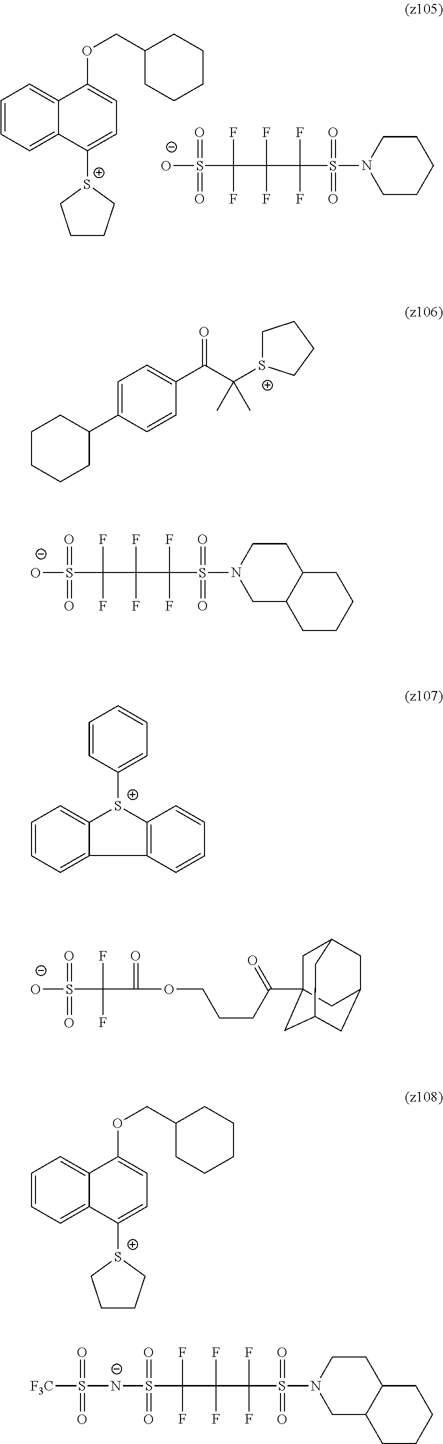

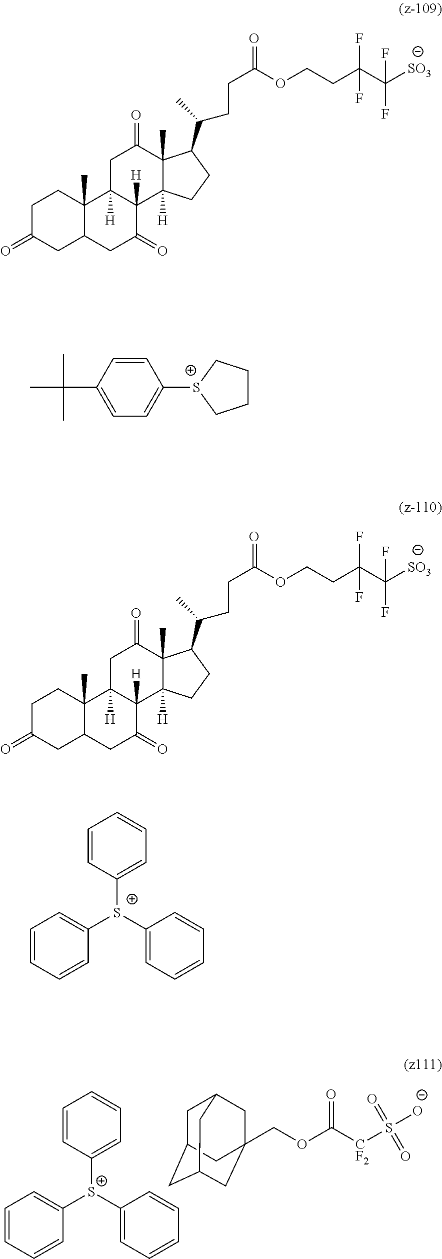

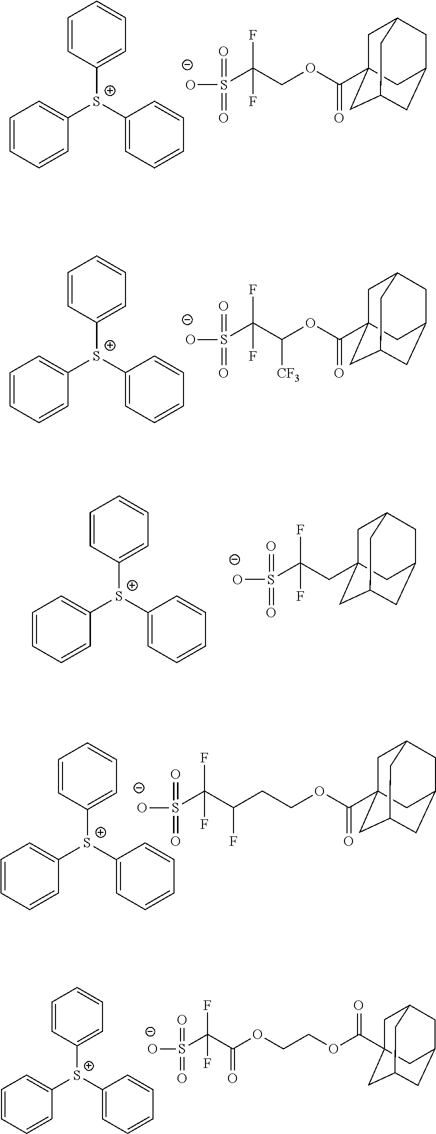

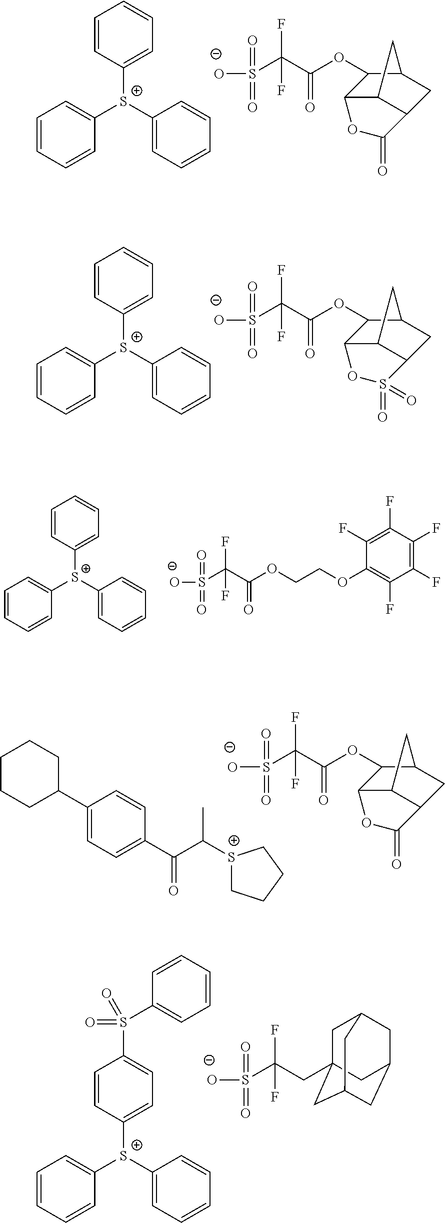

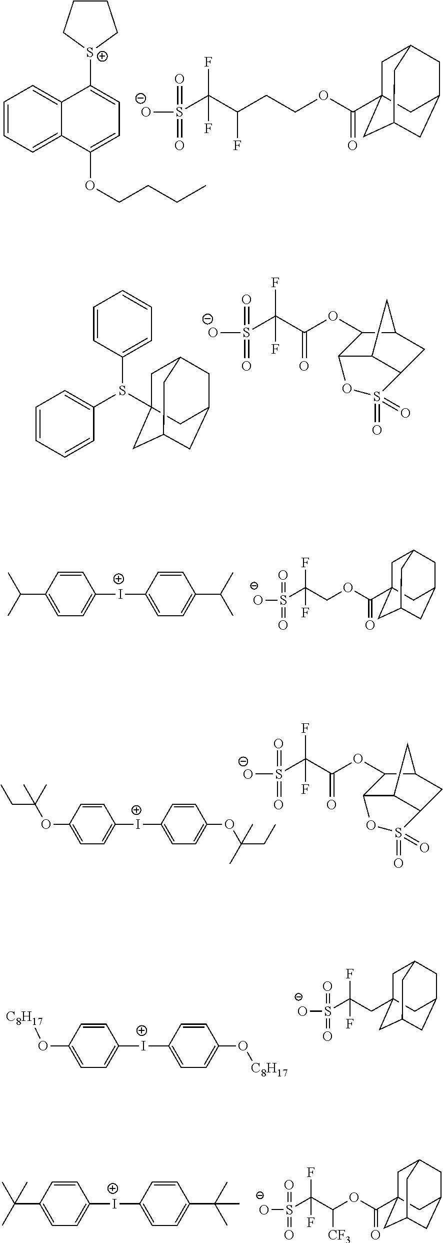

The acid generator can be synthesized using a known method, and can be synthesized by, for example, the methods described in JP2007-161707A, <0200> to <0210> in JP2010-100595A, <0051> to <0058> in WO2011/093280A, <0382> to <0385> in WO2008/153110A, JP2007-161707A, or the like.

The acid generator may be used alone or in combination of two or more kinds thereof.

The content ratio of the compound capable of generating an acid upon irradiation with actinic ray or radiation in the composition is preferably 0.1% to 30% by mass, more preferably 0.5% to 25% by mass, still more preferably 3% to 20% by mass, and particularly preferably 3% to 15% by mass, with respect to the total solid content of the composition of the present invention.

Furthermore, depending on the actinic ray-sensitive or radiation-sensitive resin composition as described above, there is also an aspect (B′) in which a structure corresponding to an acid generator is carried on the resin (A). Specific examples of such an aspect include the structure described in JP2011-248019A (in particular, the structure described in paragraphs 0164 to 0191, and the structure which is included in a resin described in Examples in paragraph 0555), and the repeating units (R) described in paragraphs 0023 to 0210 of JP2013-80002A. Here, even in an aspect in which the structure corresponding to an acid generator is carried on the resin (A), the actinic ray-sensitive or radiation-sensitive resin composition may further include an acid generator which is not carried on the resin (A).

Examples of the aspect (B′) include the repeating units as follows, but the present invention is not limited thereto.

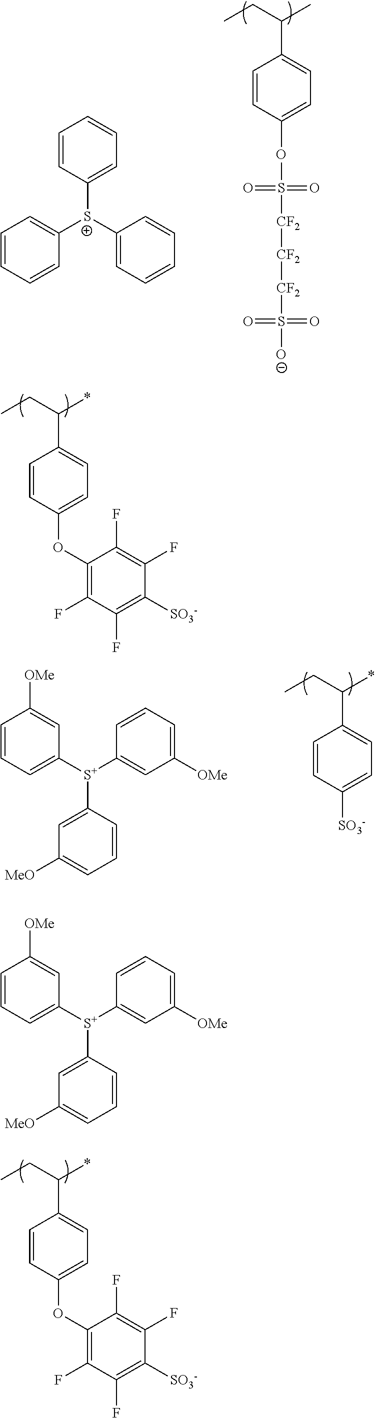

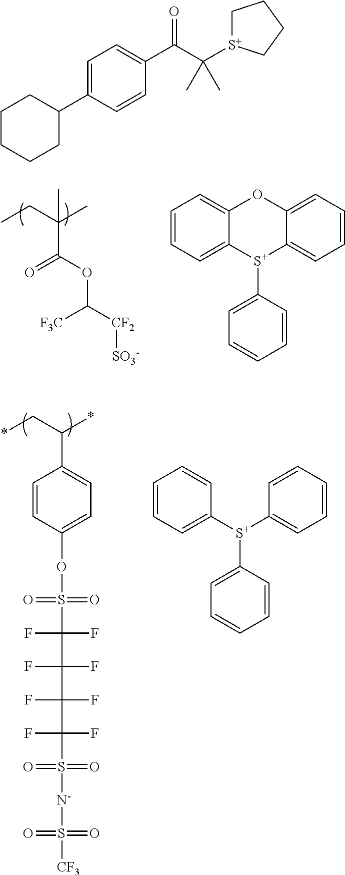

<Hydrophobic Resin (HR)>

The composition of the present invention may contain a hydrophobic resin. Further, the hydrophobic resin is preferably different from the resin (A).

Although the hydrophobic resin is preferably designed to be unevenly localized on an interface, it does not necessarily have to have a hydrophilic group in its molecule as different from the surfactant, and does not need to contribute to uniform mixing of polar/nonpolar materials.

Examples of the effect of addition of the hydrophobic resin include control of the static/dynamic contact angle of the resist film surface with respect to water, improvement of the immersion liquid tracking properties, and inhibition of out gas. The inhibition of out gas is required, in particular, in a case where exposure is carried out with EUV light.

The hydrophobic resin preferably has at least one of a “fluorine atom”, a “silicon atom”, or a “CH₃ partial structure which is contained in a side chain moiety of a resin” from the point of view of uneven distribution on the film surface layer, and more preferably has two or more kinds.

In a case where hydrophobic resin contains a fluorine atom and/or a silicon atom, the fluorine atom and/or the silicon atom in the hydrophobic resin may be contained in the main chain or the side chain of the resin.

In a case where the hydrophobic resin contains a fluorine atom, the resin is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group such as a phenyl group and a naphthyl group, in which at least one hydrogen atom is substituted with a fluorine atom, and may further have a substituent other than a fluorine atom.

Preferred examples of the alkyl group having a fluorine atom, the cycloalkyl group having a fluorine atom, and the aryl group having a fluorine atom include groups represented by the following General Formulae (F2) to (F4), but the present invention is not limited thereto.

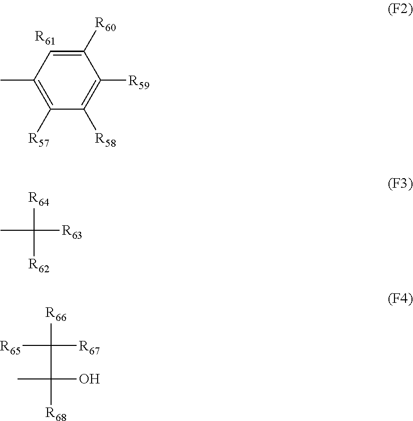

In General Formulae (F2) to (F4),

R₅₇ to R₆₈ each independently represent a hydrogen atom, a fluorine atom, or an (linear or branched) alkyl group, provided that at least one of R₅₇, . . . , or R₆₁, at least one of R₆₂, . . . , or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include those exemplified in [0500] of US2012/0251948A.

Specific examples of the group represented by General Formula (F4) include —C(CF₃)₂OH, —C(C₂F₅)₂OH, —C(CF₃)(CH₃)OH, and —CH(CF₃)OH, with —C(CF₃)₂OH being preferable.

The partial structure having a fluorine atom may be bonded directly to the main chain or may be bonded to the main chain through a group selected from the group consisting of an alkylene group, a phenylene group, an ether bond, a thioether bond, a carbonyl group, an ester bond, an amide bond, an urethane bond, and an ureylene bond, or a group formed by combination of two or more thereof.

The hydrophobic resin may contain a silicon atom. The resin preferably has, as the partial structure having a silicon atom, an alkylsilyl structure (preferably a trialkylsilyl group) or a cyclic siloxane structure.

Examples of the alkylsilyl structure or the cyclic siloxane structure include the partial structures described in paragraphs <0304> to <0307> of JP2013-178370A.

Examples of the repeating unit having a fluorine atom or a silicon atom include those exemplified in [0519] of US2012/0251948A.

Furthermore, it is also preferable that the hydrophobic resin contains a CH₃ partial structure in the side chain moiety as described above.

Here, the CH₃ partial structure (hereinafter also simply referred to as a “side chain CH₃ partial structure”) contained in the side chain moiety in the hydrophobic resin includes a CH₃ partial structure contained in an ethyl group, a propyl group, and the like.

On the other hand, a methyl group bonded directly to the main chain of the hydrophobic resin (for example, an α-methyl group in the repeating unit having a methacrylic acid structure) makes only a small contribution of uneven distribution to the surface of the hydrophobic resin due to the effect of the main chain, and it is therefore not included in the CH₃ partial structure in the present invention.

More specifically, in a case where the hydrophobic resin contains a repeating unit derived from a monomer having a polymerizable moiety with a carbon-carbon double bond, such as repeating units represented by the following General Formula (M), and in addition, R₁₁ to R₁₄ are CH₃ “themselves”, such CH₃ is not included in the CH₃ partial structure contained in the side chain moiety in the present invention.

On the other hand, a CH₃ partial structure which is present via a certain atom from a C—C main chain corresponds to the CH₃ partial structure in the present invention. For example, in a case where R₁₁ is an ethyl group (CH₂CH₃), the hydrophobic resin has “one” CH₃ partial structure in the present invention.

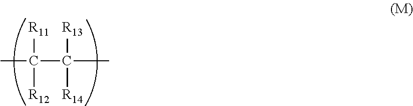

In General Formula (M),

R₁₁ to R₁₄ each independently represent a side chain moiety.

Examples of R₁₁ to R₁₄ at the side chain moiety include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The hydrophobic resin is preferably a resin including a repeating unit having the CH₃ partial structure in the side chain moiety thereof. Further, the hydrophobic resin preferably has, as such a repeating unit, at least one repeating unit (x) selected from repeating units represented by the following General Formula (II) and repeating units represented by the following General Formula (III).

Hereinafter, the repeating unit represented by General Formula (II) will be described in detail.

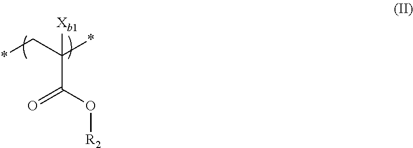

In General Formula (II), X_{b1} represents a hydrogen atom, an alkyl group, a cyano group, or a halogen atom, and R₂ represents an organic group which has one or more CH₃ partial structures and is stable against an acid. Here, more specifically, the organic group which is stable against an acid is preferably an organic group which does not have an “acid-decomposable group” described with respect to the resin (A).

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably 2 to 10, and more preferably 2 to 8.

Specific preferred examples of the repeating unit represented by General Formula (II) are shown below, but the present invention is not limited thereto.

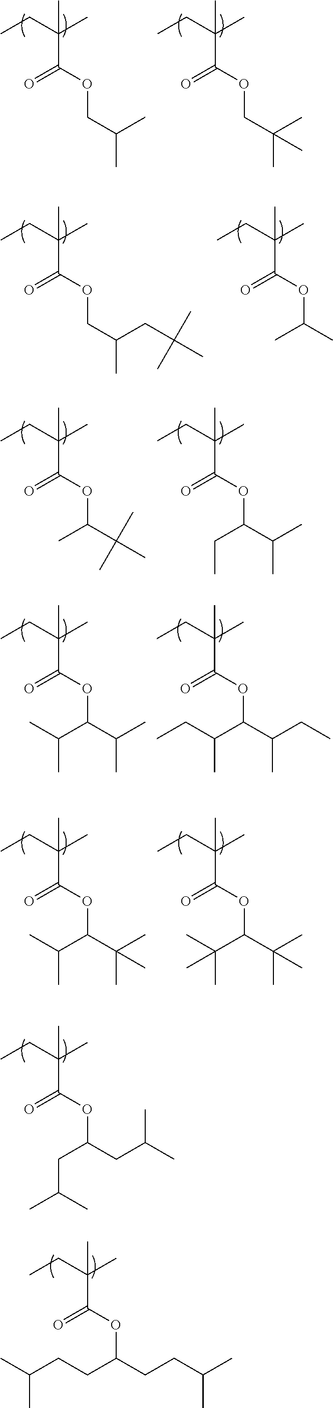

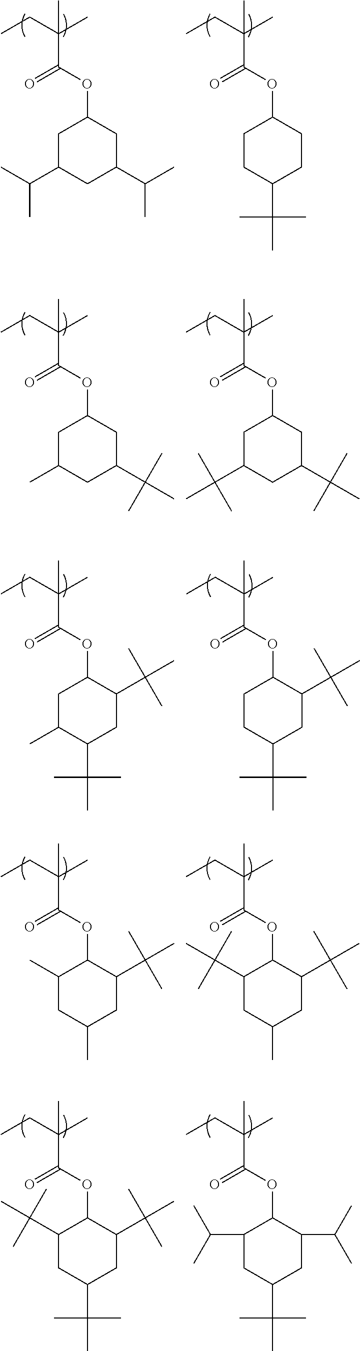

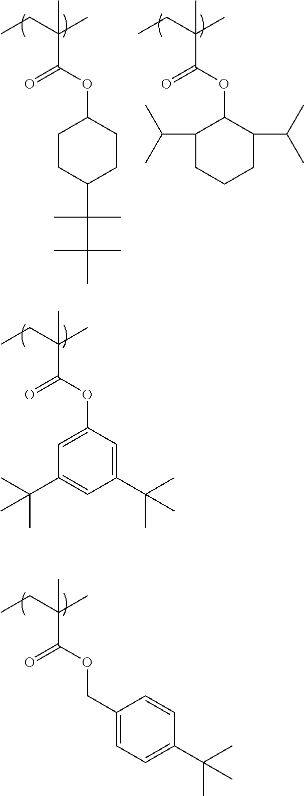

The repeating unit represented by General Formula (II) is preferably a repeating unit which is stable against an acid (acid-indecomposable), and specifically, it is preferably a repeating unit not having a group capable of decomposing by the action of an acid to generate a polar group.

Hereinafter, the repeating unit represented by General Formula (III) will be described in detail.

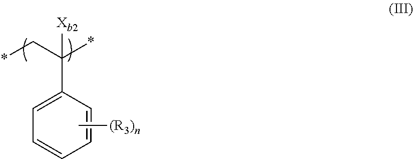

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group stable against an acid, and more specifically, R₃ is preferably an organic group which does not have the “acid-decomposable group” described with respect to the resin (A).

Examples of R₃ include an alkyl group having one or more CH₃ partial structures.

The number of the CH₃ partial structures contained in the organic group which has one or more CH₃ partial structures and is stable against an acid as R₃ is preferably 1 to 10, more preferably 1 to 8, and still more preferably 1 to 4.

n represents an integer of 1 to 5, more preferably 1 to 3, and still more preferably 1 or 2.

Specific preferred examples of the repeating unit represented by General Formula (III) are shown below, but the present invention is not limited thereto.

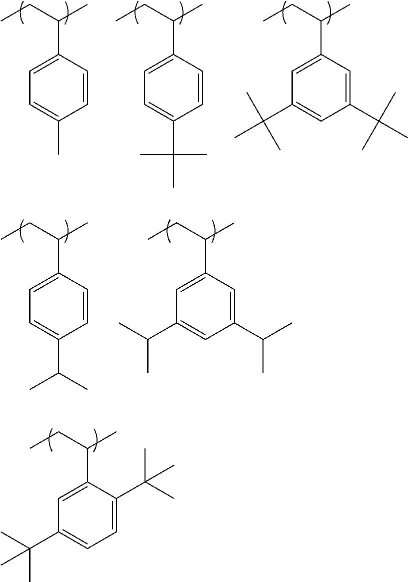

The repeating unit represented by General Formula (III) is preferably a repeating unit which is stable against an acid (acid-indecomposable), and specifically, it is a repeating unit which does not have a group capable of decomposing by the action of an acid to generate a polar group.

In a case where the hydrophobic resin contains a CH₃ partial structure in the side chain moiety thereof, and in particular, it does not have any one of a fluorine atom and a silicon atom, the content of at least one repeating unit (x) of the repeating unit represented by General Formula (II) and the repeating unit represented by General Formula (III) is preferably 90% by mole or more, and more preferably 95% by mole or more, with respect to all the repeating units of the hydrophobic resin. Further, the content is usually 100% by mole or less with respect to all the repeating units of the hydrophobic resin.

By incorporating at least one repeating unit (x) of the repeating unit represented by General Formula (II) and the repeating unit represented by General Formula (III) in a proportion of 90% by mole or more with respect to all the repeating units of the hydrophobic resin into the hydrophobic resin, the surface free energy of the hydrophobic resin is increased. As a result, it is difficult for the hydrophobic resin to be unevenly distributed on the surface of the resist film and the static/dynamic contact angle of the resist film with respect to water can be securely increased, thereby enhancing the immersion liquid tracking properties.

In addition, in a case where the hydrophobic resin contains (i) a fluorine atom and/or a silicon atom or (ii) a CH₃ moiety structure in the side chain moiety, the hydrophobic resin may have at least one group selected from the following groups (x) to (z):

(x) an acid group,

(y) a group having a lactone structure, an acid anhydride group, or an acid imido group, and

(z) a group capable of decomposing by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the acid group include a fluorinated alcohol group (preferably hexafluoroisopropanol), a sulfonimido group, and a bis(alkylcarbonyl)methylene group.

Examples of the repeating unit containing an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent containing an acid group during the polymerization. All of these cases are preferable. The repeating unit having an acid group (x) may have at least one of a fluorine atom or a silicon atom.

The content of the repeating units containing an acid group (x) is preferably 1% to 50% by mole, more preferably 3% to 35% by mole, and still more preferably 5% to 20% by mole, with respect to all the repeating units in the hydrophobic resin.

Specific preferred examples of the repeating unit containing an acid group (x) are shown below, but the present invention is not limited thereto. In the formulae, Rx represents a hydrogen atom, CH₃, CF₃, or CH₂OH.

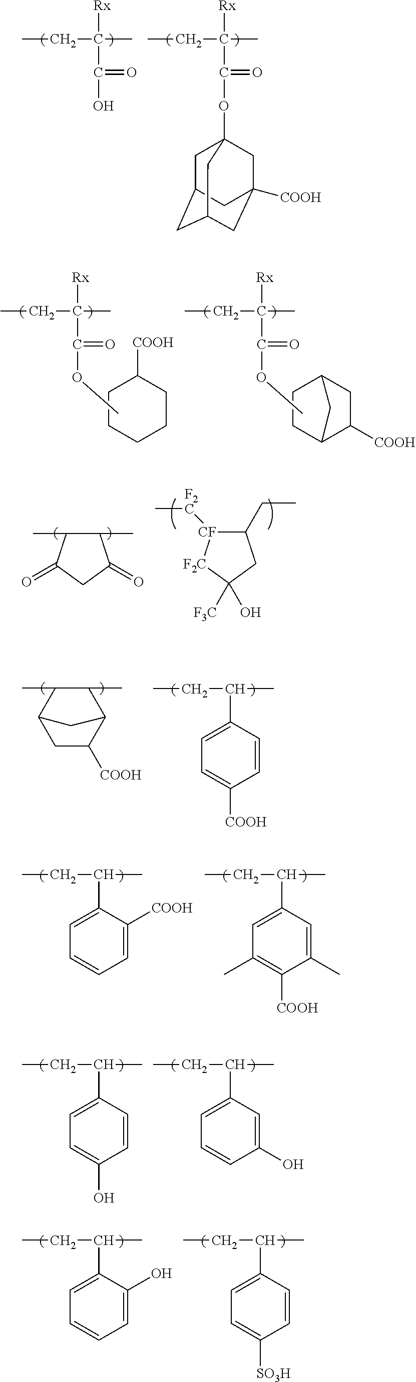

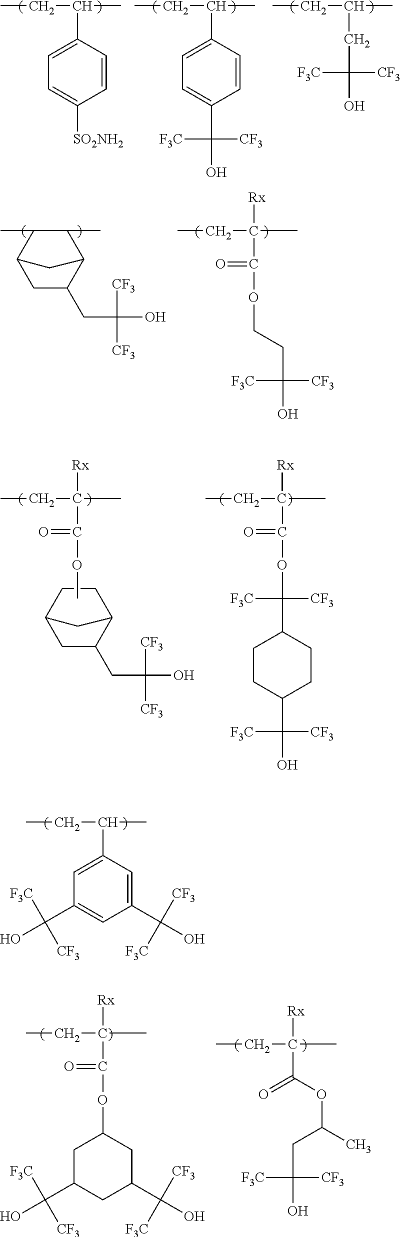

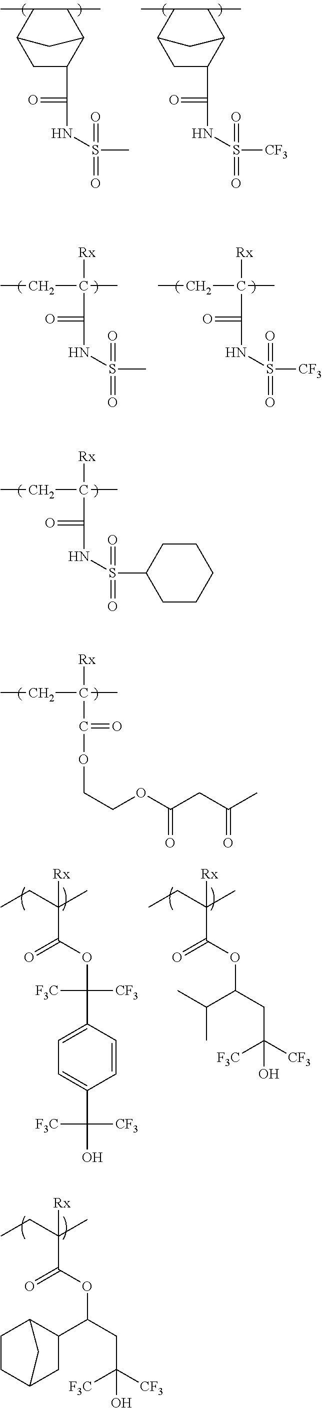

As the group having a lactone structure, the acid anhydride group, or the acid imido group (y), a group having a lactone structure is particularly preferable.

The repeating unit containing such a group is, for example, a repeating unit in which the group is directly bonded to the main chain of the resin, such as a repeating unit by an acrylic ester or a methacrylic ester. This repeating unit may be a repeating unit in which the group is bonded to the main chain of the resin through a linking group. Alternatively this repeating unit may be introduced into the terminal of the resin by using a polymerization initiator or chain transfer agent containing the group during the polymerization.

Examples of the repeating unit containing a group having a lactone structure include the same ones as the repeating unit having a lactone structure as described earlier in the section of the resin (A).

The content of the repeating units having a group having a lactone structure, an acid anhydride group, or an acid imido group is preferably 1% to 100% by mole, more preferably 3% to 98% by mole, and still more preferably 5% to 95% by mole, with respect to all the repeating units in the hydrophobic resin.

With respect to the hydrophobic resin, examples of the repeating unit having a group (z) capable of decomposing by the action of an acid include the same ones as the repeating units having an acid-decomposable group, as mentioned with respect to the resin (A). The repeating unit having a group (z) capable of decomposing by the action of an acid may have at least one of a fluorine atom or a silicon atom. With respect to the hydrophobic resin, the content of the repeating units having a group (z) capable of decomposing by the action of an acid is preferably 1% to 80% by mole, more preferably 10% to 80% by mole, and still more preferably 20% to 60% by mole, with respect to all the repeating units in the hydrophobic resin.

The hydrophobic resin may further have repeating units represented by the following General Formula (III).

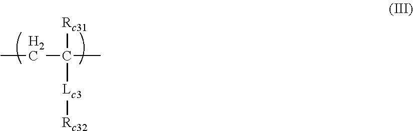

In General Formula (III),

R_{c31} represents a hydrogen atom, an alkyl group (which may be substituted with a fluorine atom or the like), a cyano group, or a —CH₂—O-Rac₂ group, in which Rac₂ represents a hydrogen atom, an alkyl group, or an acyl group, and R_{c31} is preferably a hydrogen atom, a methyl group, a hydroxymethyl group, or a trifluoromethyl group, and particularly preferably a hydrogen atom or a methyl group.

R_{c32} represents a group having an alkyl group, a cycloalkyl group, an alkenyl group, a cycloalkenyl group, or an aryl group, each of which may be substituted with a group containing a fluorine atom or a silicon atom.

L_{c3} represents a single bond or a divalent linking group.

In General Formula (III), the alkyl group of R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an ether bond, a phenylene group, or an ester bond (a group represented by —COO—).

The content of the repeating units represented by formula (III) is preferably 1% to 100% by mole, more preferably 10% to 90% by mole, and still more preferably 30% to 70% by mole, with respect to all the repeating units in the hydrophobic resin.

It is also preferable that the hydrophobic resin further has repeating units represented by the following General Formula (CII-AB).

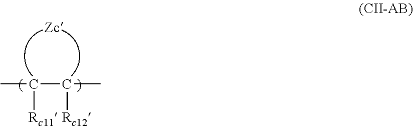

In Formula (CH-AB),

R_{c11}′ and R_{c12}′ each independently represent a hydrogen atom, a cyano group, a halogen atom, or an alkyl group.

Zc′ represents an atomic group for forming an alicyclic structure containing two carbon atoms (C—C) to which Zc′ is bonded.

The content of the repeating units represented by General Formula (CII-AB) is preferably 1% to 100% by mole, more preferably 10% to 90% by mole, and still more preferably 30% to 70% by mole, with respect to all the repeating units in the hydrophobic resin.

Specific examples of the repeating units represented by General Formulae (III) and (CII-AB) are shown below, but the present invention is not limited thereto. In the formulae, Ra represents H, CH₃, CH₂OH, CF₃, or CN.

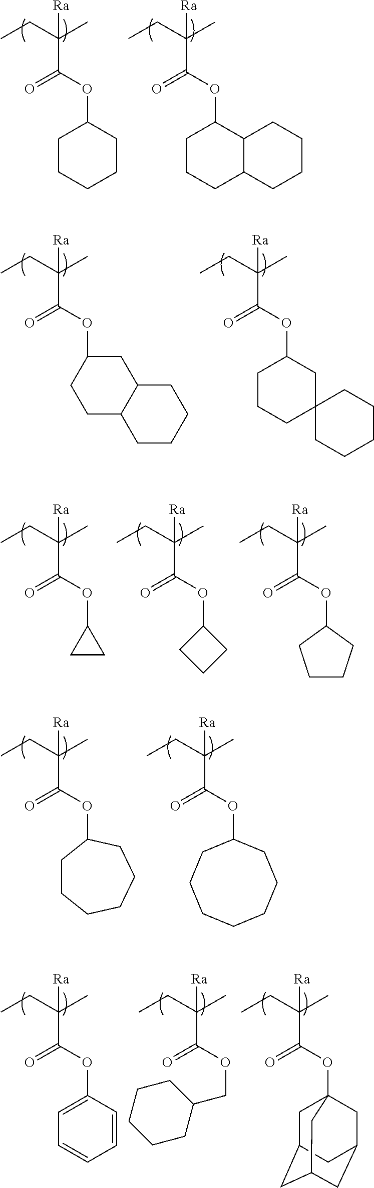

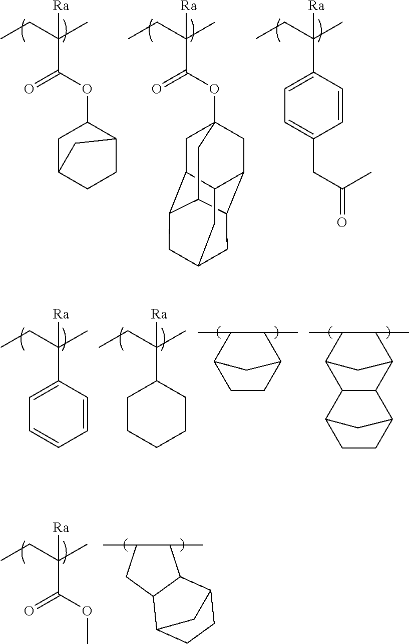

In a case where the hydrophobic resin has a fluorine atom, the content of the fluorine atom is preferably 5% to 80% by mass, and more preferably 10% to 80% by mass, with respect to the weight-average molecular weight of the hydrophobic resin. Further, the proportion of the repeating units containing a fluorine atom is preferably 10% to 100% by mole, and more preferably 30% to 100% by mole, with respect to all the repeating units included in the hydrophobic resin.

In a case where the hydrophobic resin has a silicon atom, the content of the silicon atom is preferably 2% to 50% by mss, and more preferably 2% to 30% by mss, with respect to the weight-average molecular weight of the hydrophobic resin. Further, the proportion of the repeating unit containing a silicon atom is preferably 10% to 100% by mole, and more preferably 20% in to 100% by mole, with respect to all the repeating units included in the hydrophobic resin.

On the other hand, in particular, in a case where the hydrophobic resin contains a CH₃ partial structure in the side chain moiety thereof, it is also preferable that the hydrophobic resin has a form not having substantially any one of a fluorine atom and a silicon atom. In this case, specifically the content of the repeating units containing a fluorine atom or a silicon atom is preferably 5% by mole or less, more preferably 3% by mole or less, still more preferably 1% by mole or less, and ideally 0% by mole, that is, not containing any one of a fluorine atom and a silicon atom, with respect to all the repeating units in the hydrophobic resin. In addition, it is preferable that the hydrophobic resin is composed substantially of a repeating unit constituted with only an atom selected from the group consisting of a carbon atom, an oxygen atom, a hydrogen atom, a nitrogen atom, and a sulfur atom. More specifically the proportion of the repeating unit constituted with only an atom selected from the group consisting of a carbon atom, an oxygen atom, a hydrogen atom, a nitrogen atom, and a sulfur atom is preferably 95% by mole or more, more preferably 97% by mole or more, still more preferably 99% by mole or more, and ideally 100% by mole, of all the repeating units in the hydrophobic resin.

The weight-average molecular weight of the hydrophobic resin in terms of standard polystyrene is preferably 1,000 to 100,000, more preferably 1,000 to 50,000, and still more preferably 2,000 to 15,000.

Furthermore, the hydrophobic resins may be used alone or in combination of two or more kinds thereof.

The content of the hydrophobic resins in the composition is preferably 0.01% to 10% by mass, more preferably 0.05% to 8% by mass, and still more preferably 0.1% to 7% by mass, with respect to the total solid content of the composition of the present invention.

In the hydrophobic resin, it is certain that the content of impurities such as metal is small, but the content of residual monomers or oligomer components is also preferably 0.01% to 5% by mass, more preferably 0.01% to 3% by mass, and still more preferably 0.05% to 1% by mass. Within these ranges, a composition free from in-liquid extraneous materials and a change in sensitivity or the like with aging can be obtained. Further, from the viewpoints of a resolution, a resist profile, the side wall of a resist pattern, a roughness, and the like, the molecular weight distribution (Mw/Mn, also referred to as a dispersity) is preferably in the range of 1 to 5, more preferably in the range of 1 to 3, and still more preferably in the range of 1 to 2.

As the hydrophobic resin, various commercial products may be used, or the resin may be synthesized by an ordinary method (for example, radical polymerization). Examples of the general synthesis method include a batch polymerization method of dissolving monomer species and an initiator in a solvent and heating the solution, thereby carrying out the polymerization, and a dropwise-addition polymerization method of adding dropwise a solution containing monomer species and an initiator to a heated solvent for 1 to 10 hours, with the dropwise-addition polymerization method being preferable.

The reaction solvent, the polymerization initiator, the reaction conditions (a temperature, a concentration, and the like) and the method for purification after reaction are the same as ones described for the resin (A), but in the synthesis of the hydrophobic resin, the concentration of the reactant is preferably 30 to 50% by mass.

Specific examples of the hydrophobic resin are shown below. Further, the molar ratio of the repeating units (corresponding to the respective repeating units in order from the left side), the weight-average molecular weight, and the dispersity with respect to the respective resins are shown in Tables below. Here, the weight-average molecular weight and the dispersity have the same definitions as the weight-average molecular weight and the dispersity in the resin (A).

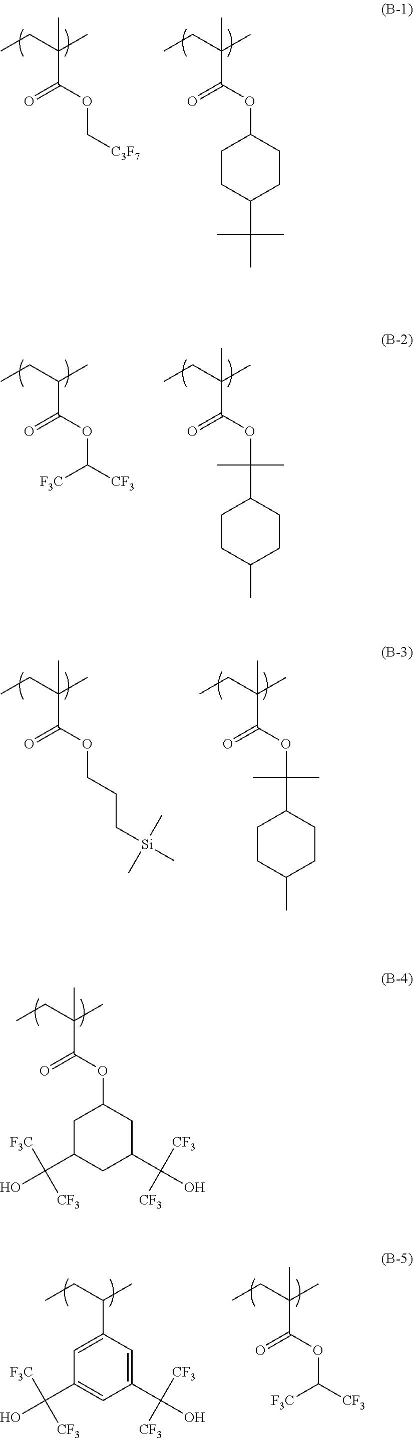

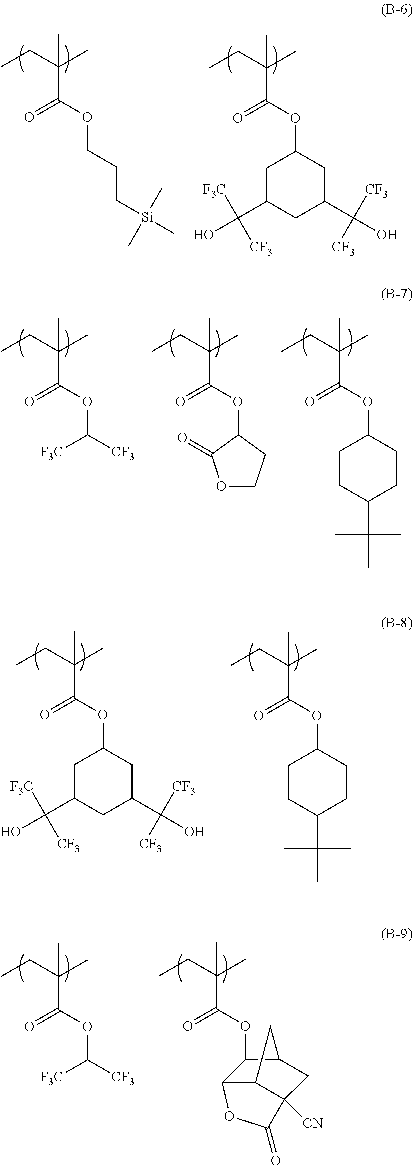

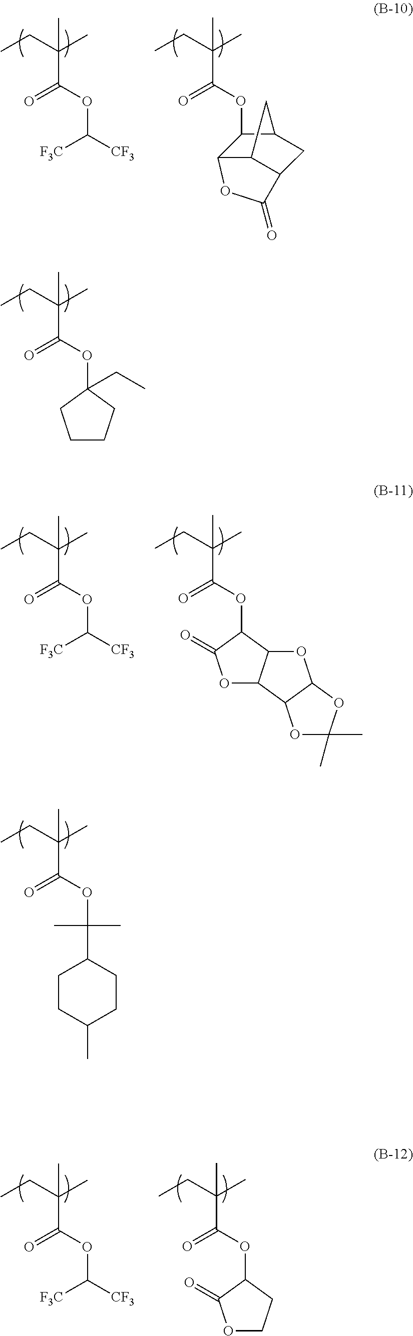

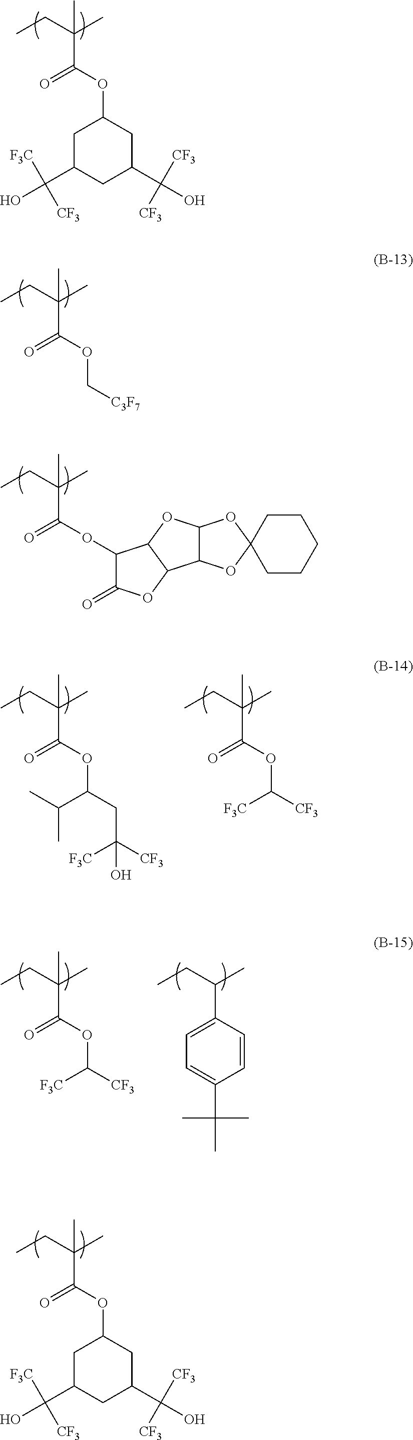

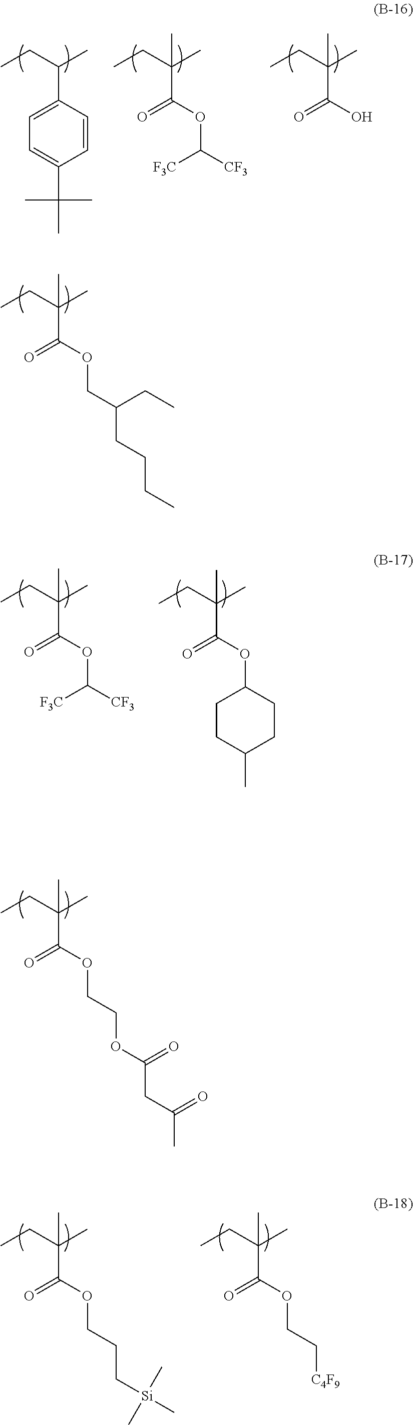

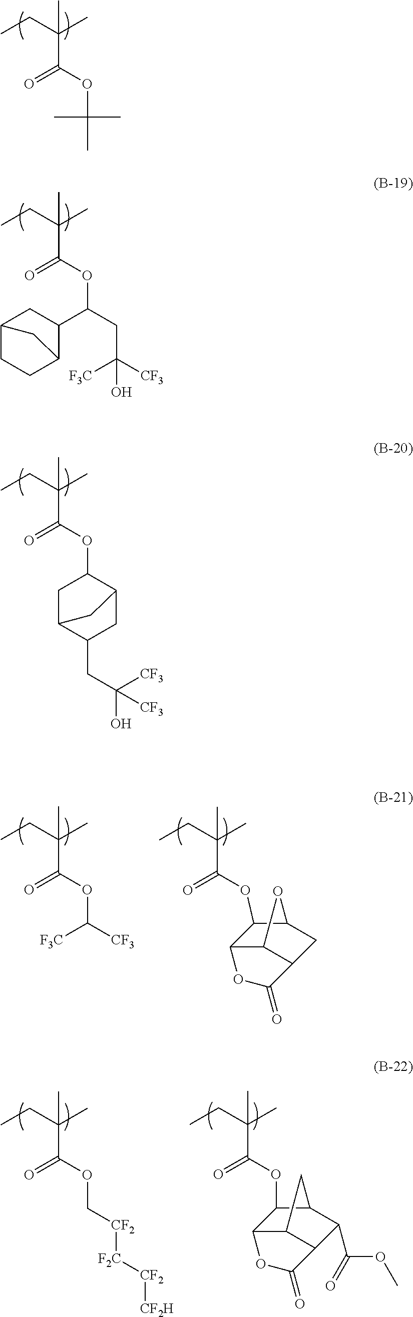

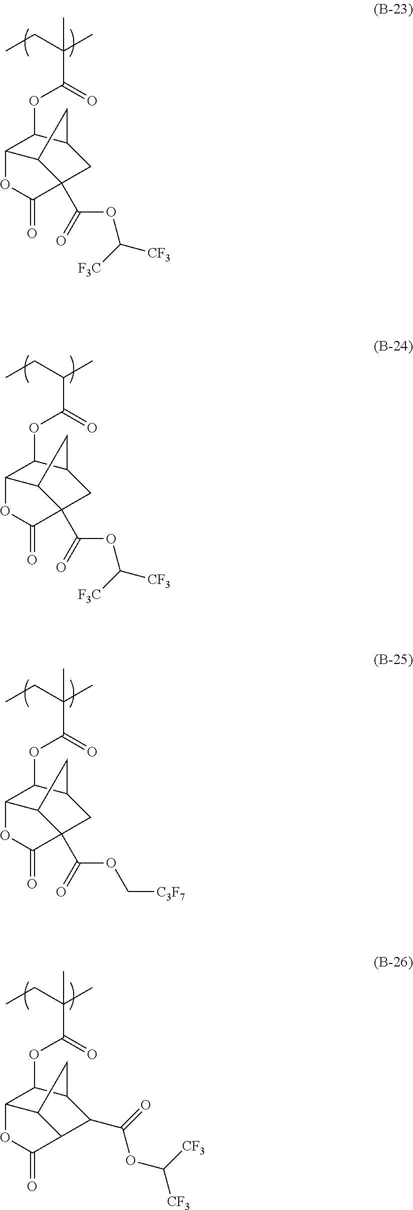

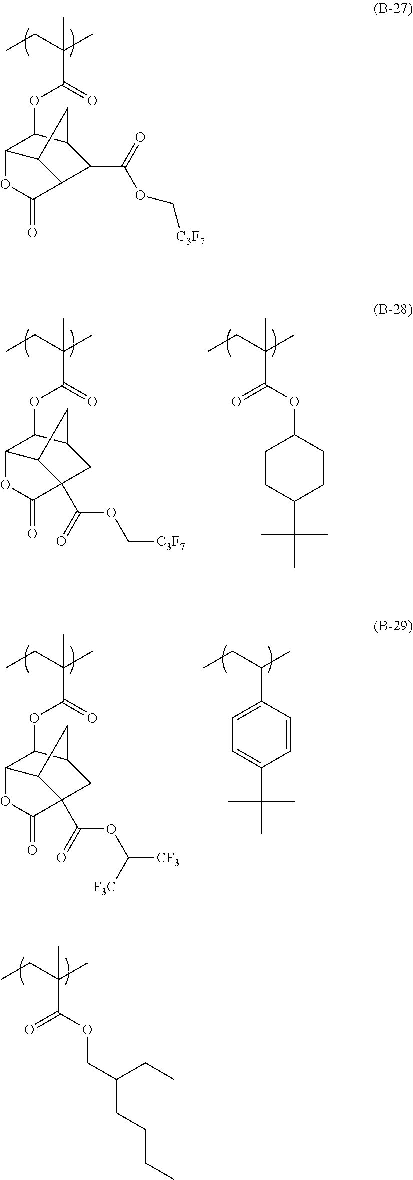

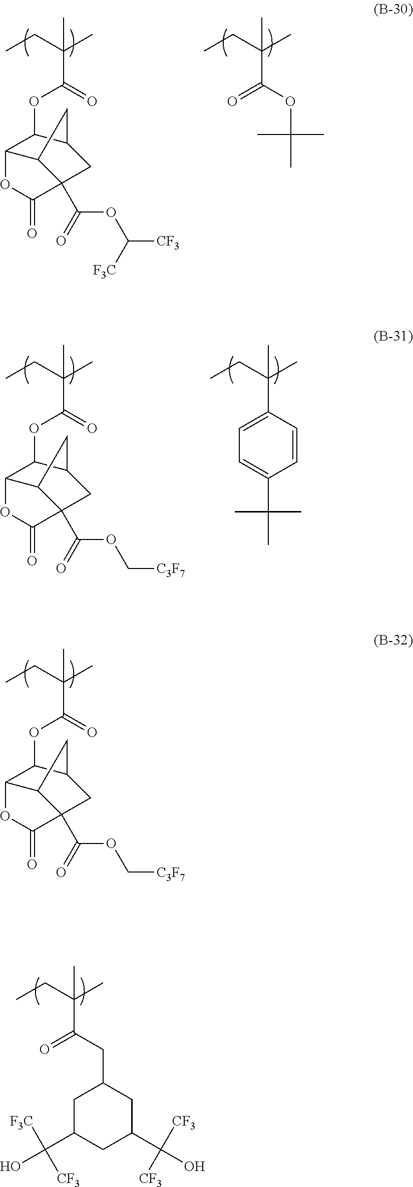

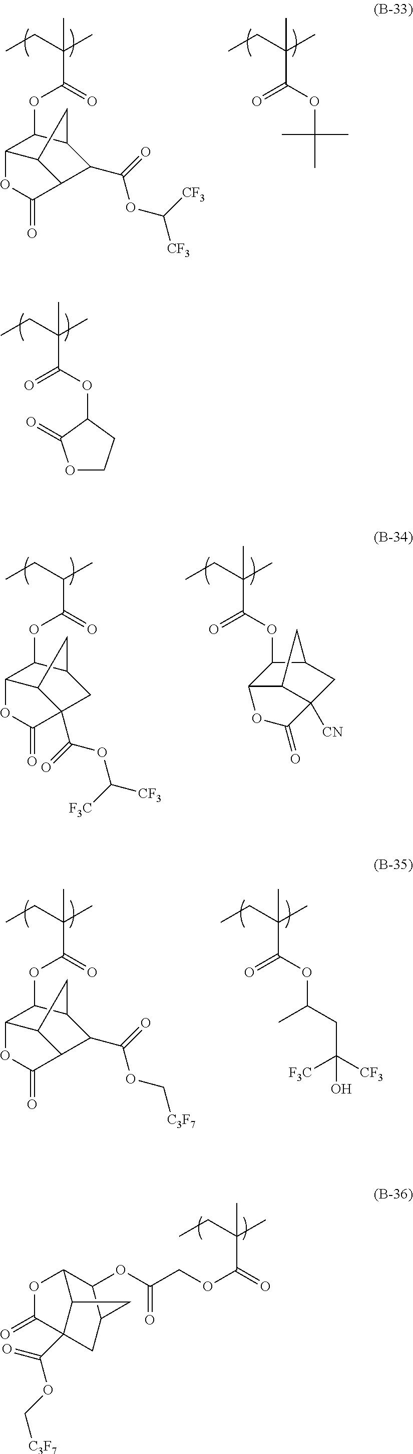

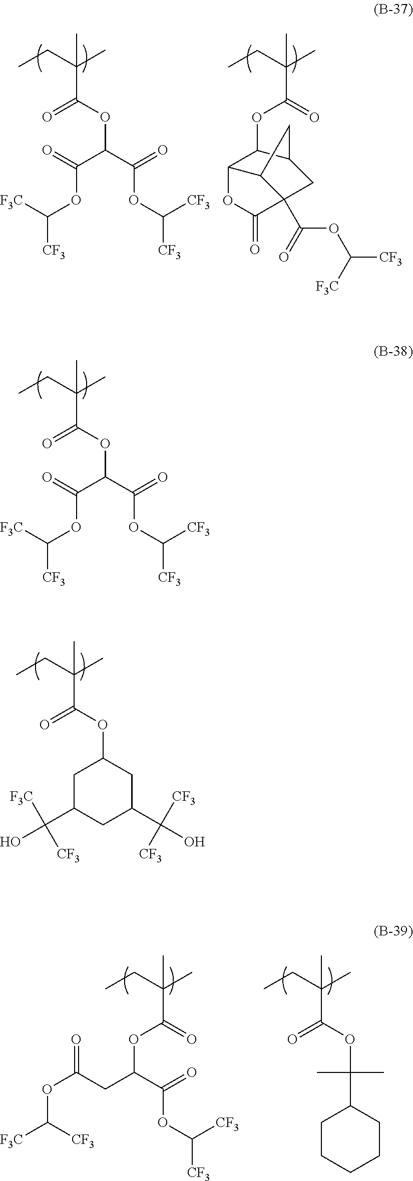

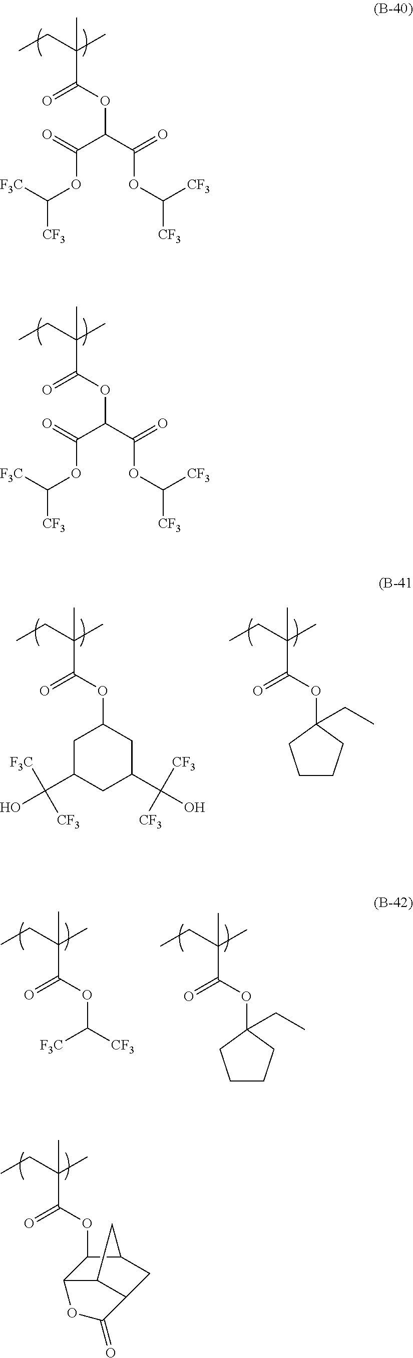

TABLE 1-1

| | Compositional | Molecular | |
|---|---|---|---|
| Resin | ratio | weight | Dispersity |
| B-1 | 50/50 | 4,800 | 1.4 |
| B-2 | 50/50 | 5,100 | 2.1 |
| B-3 | 40/60 | 6,600 | 1.8 |
| B-4 | 100 | 5,500 | 1.7 |
| B-5 | 45/55 | 4,400 | 1.6 |
| B-6 | 50/50 | 6,000 | 1.5 |
| B-7 | 40/10/50 | 6,200 | 1.6 |
| B-8 | 50/50 | 5,800 | 1.5 |
| B-9 | 80/20 | 4,800 | 1.8 |
| B-10 | 50/20/30 | 4,900 | 1.9 |
| B-11 | 50/10/40 | 5,300 | 2.0 |
| B-12 | 40/20/40 | 5,500 | 1.4 |
| B-13 | 60/40 | 5,900 | 1.3 |
| B-14 | 50/50 | 6,200 | 1.5 |
| B-15 | 40/15/45 | 6,100 | 1.8 |
| B-16 | 57/39/2/2 | 6,000 | 1.6 |
| B-17 | 45/20/35 | 6,600 | 1.6 |
| B-18 | 40/30/30 | 5,500 | 1.7 |
| B-19 | 100 | 4,900 | 1.6 |
| B-20 | 100 | 4,400 | 1.8 |
| B-21 | 60/40 | 4,500 | 1.9 |
| B-22 | 55/45 | 6,200 | 1.3 |
| B-23 | 100 | 5,700 | 1.5 |
| B-24 | 100 | 5,800 | 2.0 |
| B-25 | 100 | 6,000 | 1.5 |
| B-26 | 100 | 6,000 | 1.6 |
| B-27 | 100 | 6,200 | 1.8 |
| B-28 | 50/50 | 6,500 | 1.7 |
| B-29 | 90/8/2 | 6,500 | 1.5 |
| B-30 | 90/10 | 6,900 | 1.7 |
| B-31 | 95/5 | 4,900 | 1.8 |
| B-32 | 80/20 | 5,200 | 1.9 |
| B-33 | 75/15/10 | 5,900 | 1.6 |
| B-34 | 75/25 | 6,000 | 1.5 |
| B-35 | 80/20 | 5,700 | 1.4 |
| B-36 | 100 | 5,300 | 1.7 |
| B-37 | 20/80 | 5,400 | 1.6 |
| B-38 | 50/50 | 4,800 | 1.6 |
| B-39 | 70/30 | 4,500 | 1.6 |
| B-40 | 100 | 5,500 | 1.5 |
| B-41 | 40/40/20 | 5,800 | 1.5 |
| B-42 | 35/35/30 | 6,200 | 1.4 |

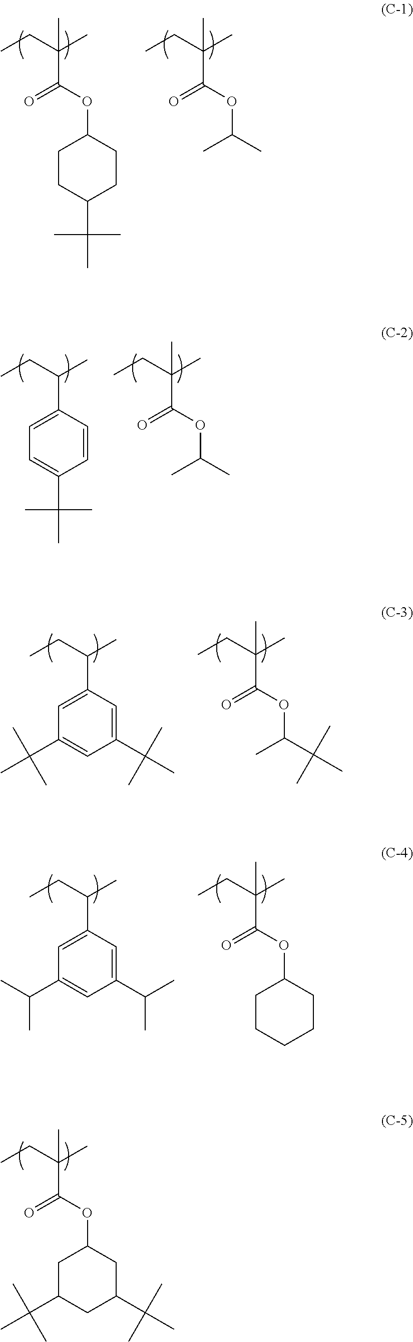

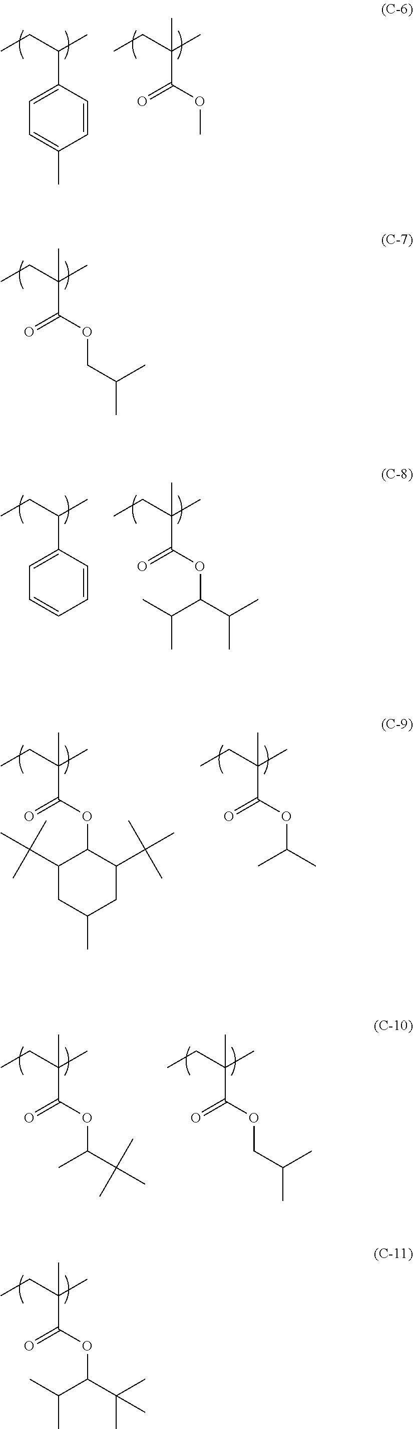

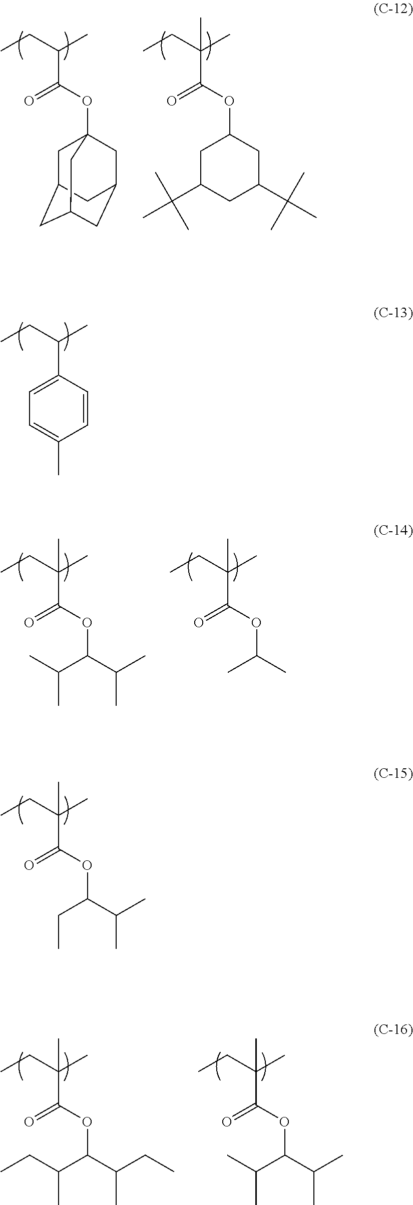

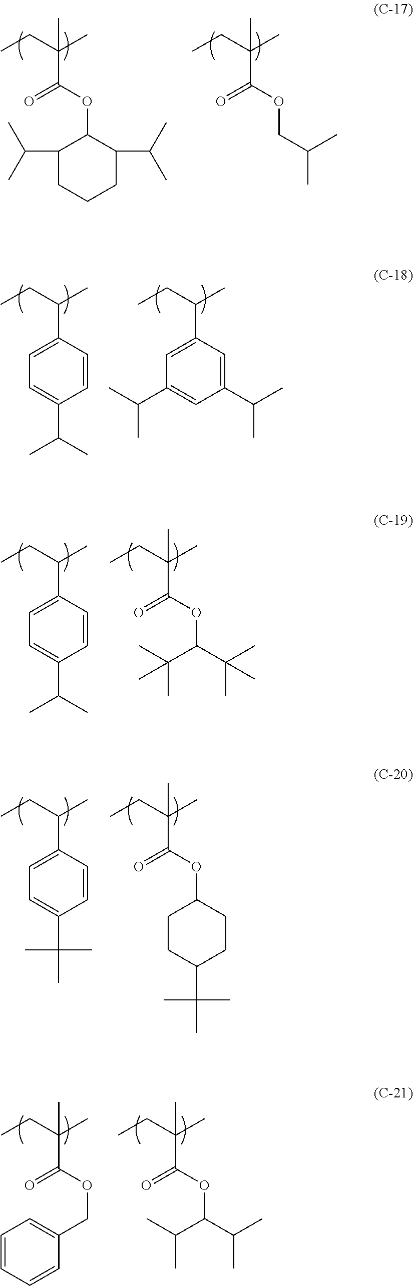

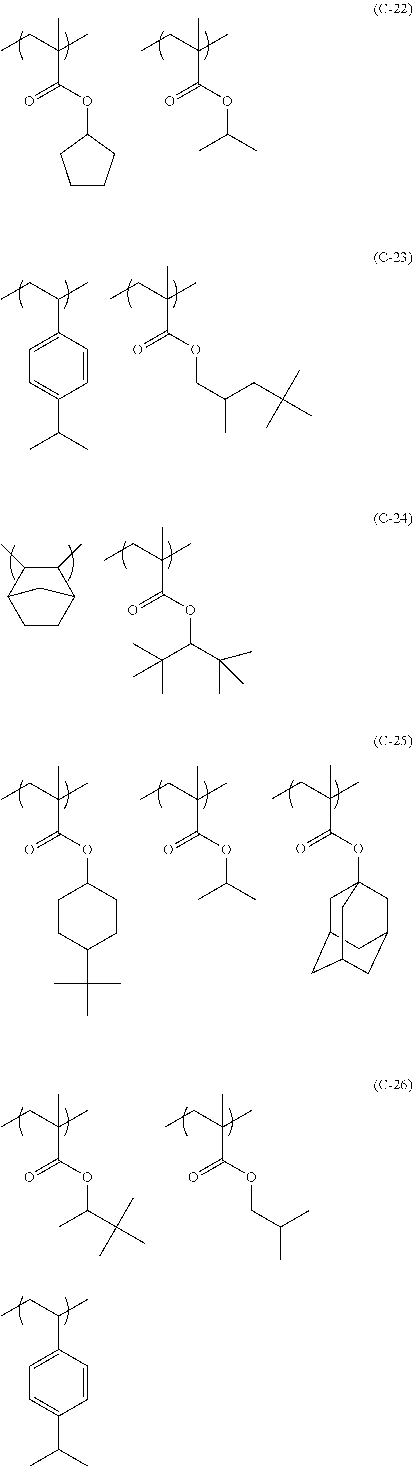

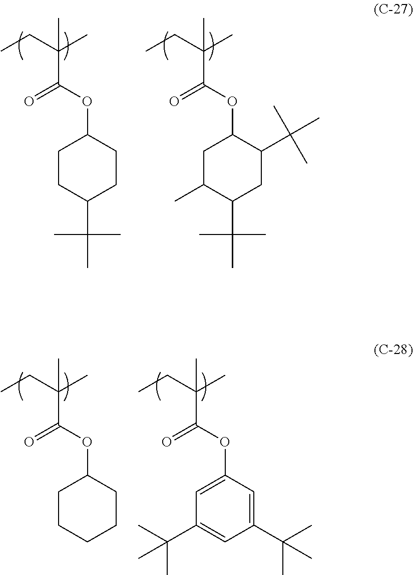

TABLE 1-2

| Resin | Composition | Mw | Mw/Mn |
|---|---|---|---|
| C-1 | 50/50 | 9,600 | 1.74 |
| C-2 | 60/40 | 34,500 | 1.43 |
| C-3 | 30/70 | 19,300 | 1.69 |
| C-4 | 90/10 | 26,400 | 1.41 |
| C-5 | 100 | 27,600 | 1.87 |
| C-6 | 80/20 | 4,400 | 1.96 |
| C-7 | 100 | 16,300 | 1.83 |
| C-8 | 5/95 | 24,500 | 1.79 |
| C-9 | 20/80 | 15,400 | 1.68 |
| C-10 | 50/50 | 23,800 | 1.46 |
| C-11 | 100 | 22,400 | 1.57 |
| C-12 | 10/90 | 21,600 | 1.52 |
| C-13 | 100 | 28,400 | 1.58 |
| C-14 | 50/50 | 16,700 | 1.82 |
| C-15 | 100 | 23,400 | 1.73 |
| C-16 | 60/40 | 18,600 | 1.44 |
| C-17 | 80/20 | 12,300 | 1.78 |
| C-18 | 40/60 | 18,400 | 1.58 |
| C-19 | 70/30 | 12,400 | 1.49 |
| C-20 | 50/50 | 23,500 | 1.94 |
| C-21 | 10/90 | 7,600 | 1.75 |
| C-22 | 5/95 | 14,100 | 1.39 |
| C-23 | 50/50 | 17,900 | 1.61 |
| C-24 | 10/90 | 24,600 | 1.72 |
| C-25 | 50/40/10 | 23,500 | 1.65 |
| C-26 | 60/30/10 | 13,100 | 1.51 |
| C-27 | 50/50 | 21,200 | 1.84 |
| C-28 | 10/90 | 19,500 | 1.66 |

<Acid Diffusion Control Agent>

The composition of the present invention preferably contains an acid diffusion control agent. The acid diffusion control agent acts as a quencher that inhibits a reaction of the acid-decomposable resin (resin (A)) in the unexposed area by excessive generated acids by trapping the acids generated from a photoacid generator or the like upon exposure. As the acid diffusion control agent, a basic compound, a low-molecular-weight compound having a nitrogen atom and a group capable of leaving by the action of an acid, a basic compound whose basicity is reduced or lost upon irradiation with actinic ray or radiation, or an onium salt which becomes a relatively weak acid with respect to a photoacid generator can be used.

Preferred examples of the basic compound include compounds having structures represented by the following General Formulae (A) to (E).

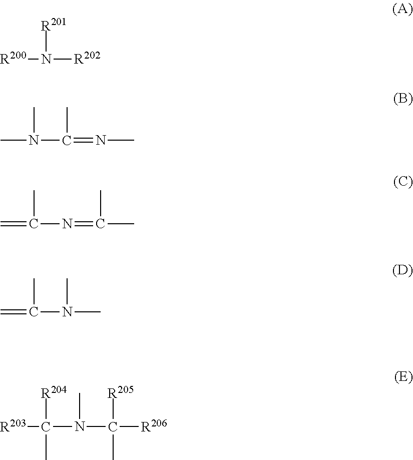

In General Formulae (A) to (E),

R²⁰⁰, R²⁰¹, and R²⁰² may be the same as or different from each other, represent a hydrogen atom, an alkyl group (preferably having 1 to 20 carbon atoms), a cycloalkyl group (preferably having 3 to 20 carbon atoms) or an aryl group (having 6 to 20 carbon atoms), and R²⁰¹ and R²⁰² may be bonded to each other to form a ring.

R²⁰³, R²⁰⁴, R²⁰⁵, and R²⁰⁶ may be the same as or different from each other, and represent an alkyl group having 1 to 20 carbon atoms.

As for the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl group in General Formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Specific examples of the preferred compound include the compounds exemplified in <0379> of US2012/0219913A.

Examples of the anion of the ammonium salt compound include a halogen atom, sulfonate, borate, and phosphate, and among these, the halogen atom and sulfonate are preferable.

Moreover, the following compounds are also preferable as the basic compound.

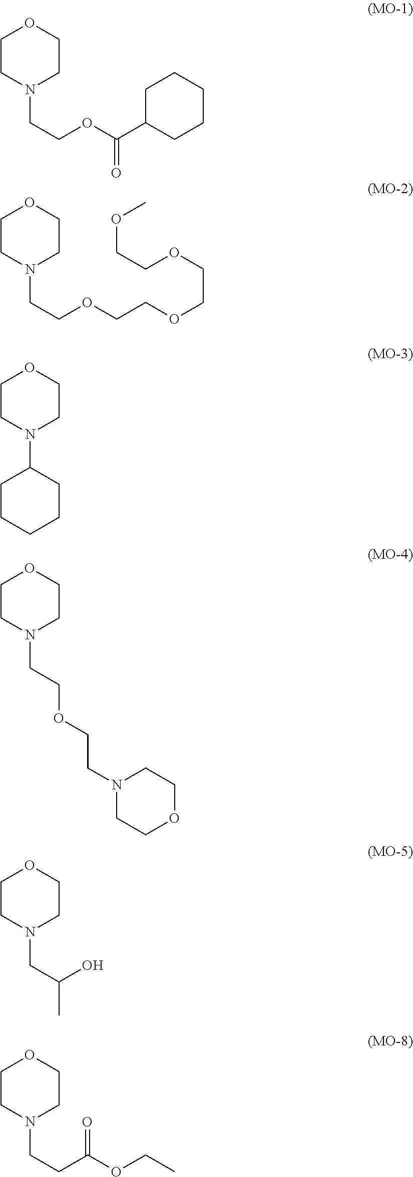

In addition to the compounds as described above, as the basic compound, the compounds described in <0180> to <0225> of JP2011-22560A, <0218> and <0219> of JP2012-137735A, and <0416> to <0438> of WO2011/158687A, and the like can also be used.

These basic compounds may be used alone or in combination of two or more kinds thereof.

The composition of the present invention may or may not contain the basic compound, but in a case where it contains the basic compound, the content of the basic compound is preferably 0.001% to 10% by mass, and more preferably 0.01% to 5% by mass, with respect to the solid content of the composition.

The ratio between the photoacid generator (including the photoacid generator (A′)) and the basic compound used in the composition is preferably photoacid generator/basic compound (molar ratio)=2.5 to 300. That is, the molar ratio is preferably 2.5 or more in view of sensitivity and resolution, and is preferably 300 or less in view of suppressing the reduction in resolution due to thickening of the resist pattern with aging after exposure until the heat treatment. The photoacid generator/basic compound (molar ratio) is more preferably 5.0 to 200, and still more preferably 7.0 to 150.

The low-molecular-weight compound (hereinafter referred to as a “compound (C)”) which has a nitrogen atom and a group capable of leaving by the action of an acid is preferably an amine derivative having a group capable of leaving by the action of an acid on a nitrogen atom.

As the group capable of leaving by the action of an acid, an acetal group, a carbonate group, a carbamate group, a tertiary ester group, a tertiary hydroxyl group, or a hemiaminal ether group are preferable, and a carbamate group or a hemiaminal ether group is particularly preferable.

The molecular weight of the compound (C) is preferably 100 to 1,000, more preferably 100 to 700, and particularly preferably 100 to 500.

The compound (C) may contain a carbamate group having a protecting group on a nitrogen atom. The protecting group constituting the carbamate group can be represented by the following General Formula (d-1).

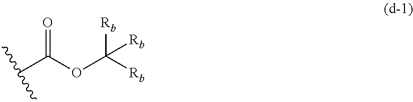

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, or the aralkyl group represented by R_{b} may be substituted with a functional group such as a hydroxyl group, a cyano group, an amino group, a pyrrolidino group, a piperidino group, a morpholino group, and an oxo group, an alkoxy group, or a halogen atom. This shall apply to the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by the mutual linking of two R_{b}'s include an alicyclic hydrocarbon group, an aromatic hydrocarbon group, a heterocyclic hydrocarbon group, and derivatives thereof.

Examples of the specific structure of the group represented by General Formula (d-1) include, but are not limited to, the structures disclosed in paragraph <0466> of US2012/0135348A.

It is particularly preferable that the compound (C) has a structure represented by the following General Formula (6).

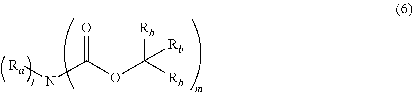

In General Formula (6), Rₐ represents a hydrogen atom, an alkyl group, a cycloalkyl group, an aryl group, or an aralkyl group. When 1 is 2, two Rₐ's may be the same as or different from each other. Two Rₐ's may be linked to each other to form a heterocycle together with the nitrogen atom in the formula. The heterocycle may contain a hetero atom other than the nitrogen atom in the formula.

R_{b} has the same meaning as R_{b} in General Formula (d-1), and preferred examples are also the same.

l represents an integer of 0 to 2, and m represents an integer of 1 to 3, satisfying l+m=3.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, the cycloalkyl group, the aryl group, and the aralkyl group may be substituted with the groups as described above) of Re include the same groups as the specific examples as described above with respect to R_{b}.

Specific examples of the particularly preferred compounds (C) in the present invention are shown below, but the present invention is not limited thereto.

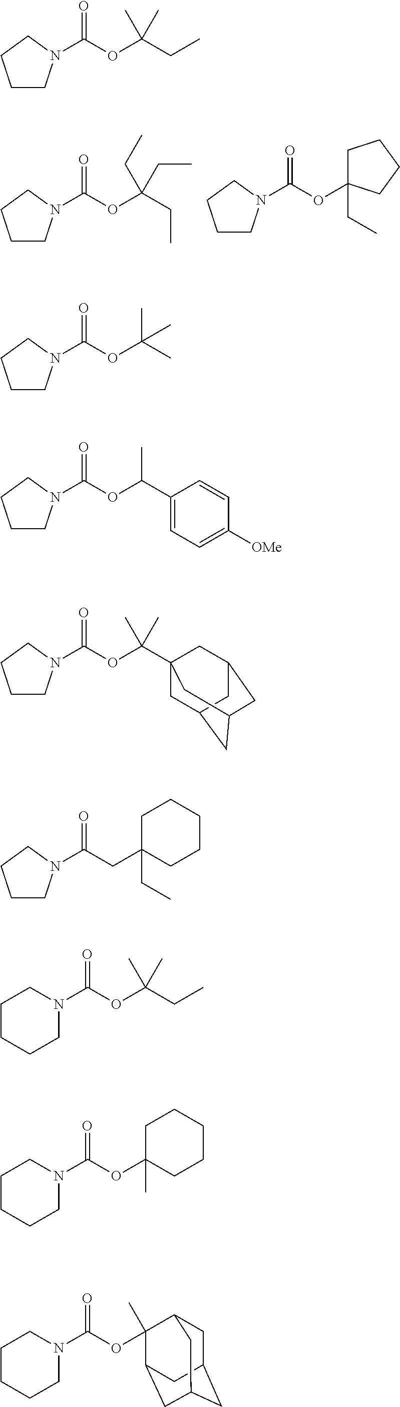

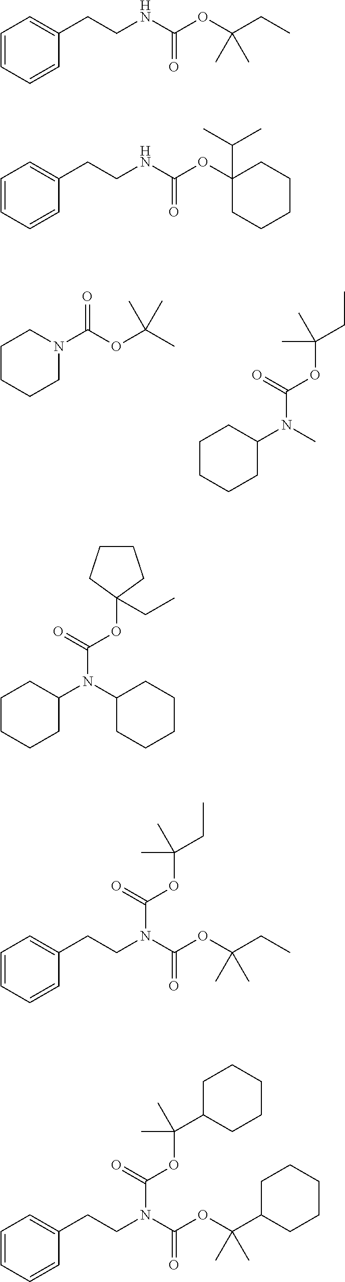

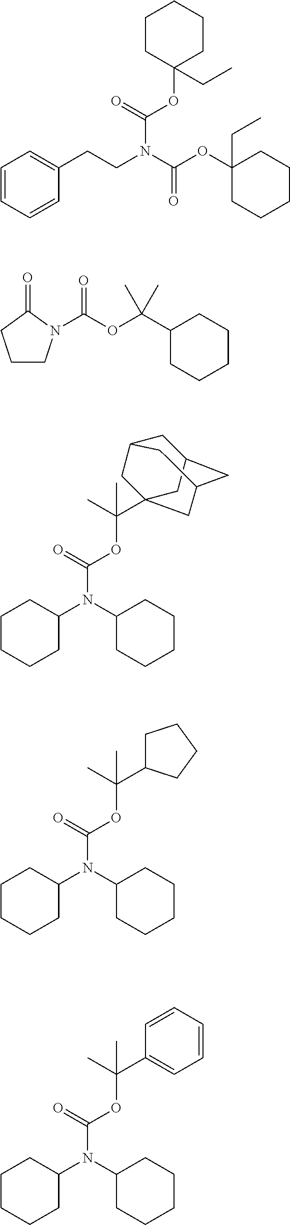 [SMILES: CCC1(OC(=O)N(CCc2ccccc2)C(=O)OC2(CC)CCCCC2)CCCCC1 ; CC(C)(OC(=O)N1CCCC1=O)C1CCCCC1 ; CC(C)(OC(=O)N(C1CCCCC1)C1CCCCC1)C12CC3CC(CC(C3)C1)C2 ; CC(C)(OC(=O)N(C1CCCCC1)C1CCCCC1)C1CCCC1 ; CC(C)(OC(=O)N(C1CCCCC1)C1CCCCC1)c1ccccc1]

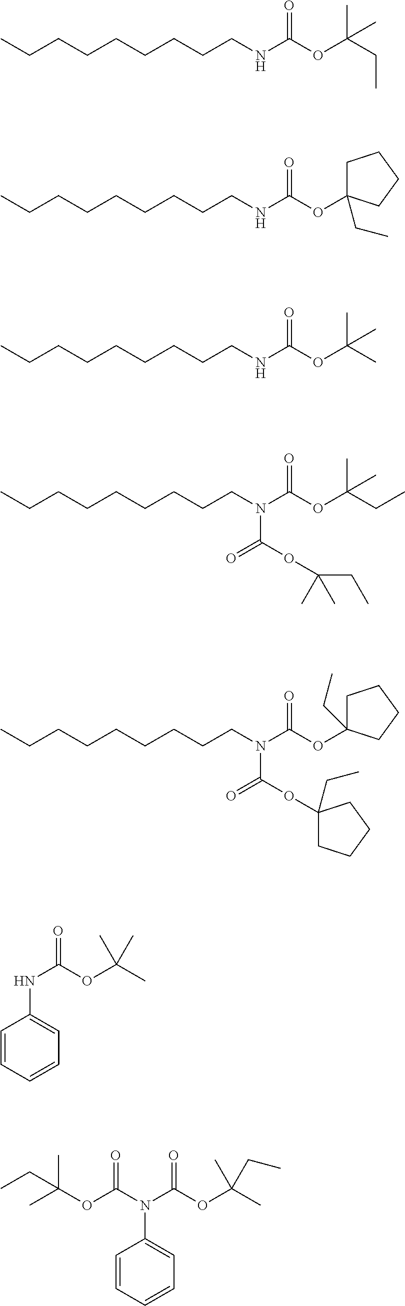

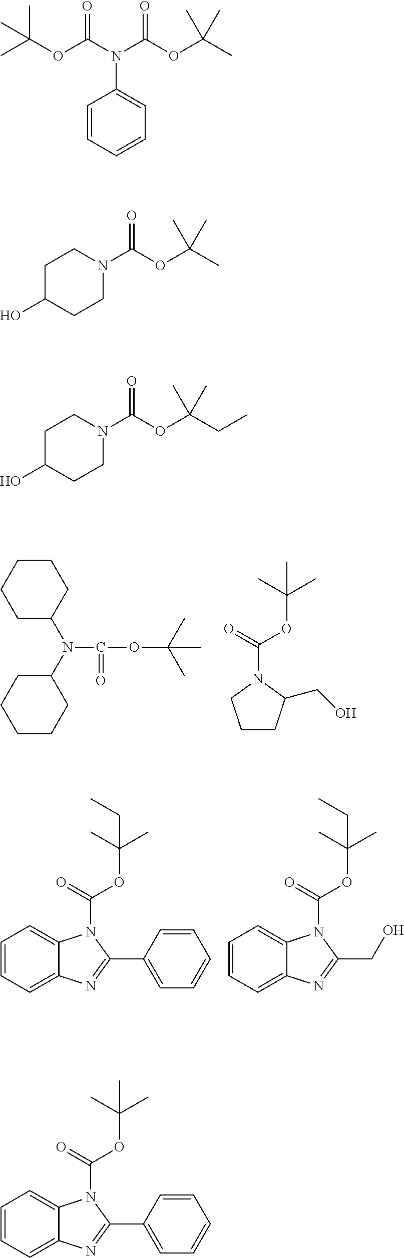

The compounds represented by General Formula (6) can be synthesized in accordance with JP2007-298569A, JP2009-199021A, and the like.

In the present invention, the compound (C) may be used alone or in combination of two or more kinds thereof.

The content of the compound (C) in the composition of the present invention is preferably 0.001% to 20% h by mass, more preferably 0.001% to 10% by mass, and still more preferably 0.01% to 5% by mass, with respect to the total solid content of the composition

The basic compound whose basicity is reduced or lost upon irradiation with actinic ray or radiation (hereinafter also referred to as a “compound (PA)”) is a compound which has a functional group with proton acceptor properties, and decomposes under irradiation with actinic ray or radiation to exhibit deterioration in proton acceptor properties, no proton acceptor properties, or a change from the proton acceptor properties to acid properties. The functional group with proton acceptor properties refers to a function group having a group or an electron which is capable of electrostatically interacting with a proton, and for example, means a functional group with a macrocyclic structure, such as a cyclopolyether, or a functional group containing a nitrogen atom having an unshared electron pair not contributing to n-conjugation. The nitrogen atom having an unshared electron pair not contributing to π-conjugation is, for example, a nitrogen atom having a partial structure represented by the following formula.

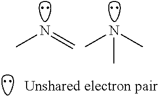

Preferred examples of the partial structure of the functional group with proton acceptor properties include crown ether, azacrown ether, primary to tertiary amines, pyridine, imidazole, and pyrazine structures.

The compound (PA) decomposes upon irradiation with actinic ray or radiation to generate a compound exhibiting deterioration in proton acceptor properties, no proton acceptor properties, or a change from the proton acceptor properties to acid properties. Here, exhibiting deterioration in proton acceptor properties, no proton acceptor properties, or a change from the proton acceptor properties to acid properties means a change of proton acceptor properties due to the proton being added to the functional group with proton acceptor properties, and specifically a decrease in the equilibrium constant at chemical equilibrium when a proton adduct is generated from the compound (PA) having the functional group with proton acceptor properties and the proton.

The proton acceptor properties can be confirmed by carrying out pH measurement.

In the present invention, the acid dissociation constant pKa of the compound generated by the decomposition of the compound (PA) upon irradiation with actinic ray or radiation preferably satisfies pKa <−1, more preferably −13<pKa <−1, and still more preferably −13<pKa <−3.

In the present invention, the acid dissociation constant pKa indicates an acid dissociation constant pKa in an aqueous solution, and is described, for example, in Chemical Handbook (II) (Revised 4^{th} Edition, 1993, compiled by the Chemical Society of Japan, Maruzen Company, Ltd.), and a lower value thereof indicates higher acid strength. Specifically, the acid dissociation constant, pKa, in an aqueous solution may be measured by using an infinite-dilution aqueous solution and measuring the acid dissociation constant at 25° C., or a value based on the Hammett substituent constants and the database of publicly known literature data can also be obtained by computation using the following software package 1. All the values of pKa described in the present specification indicate values determined by computation using this software package.

Software package 1: Advanced Chemistry Development (ACD/Labs) Software V 8.14 for Solaris (1994-2007 ACD/Labs).

The compound (PA) generates a compound represented by the following General Formula (PA-1), for example, as the proton adduct generated by decomposition upon irradiation with actinic ray or radiation. The compound represented by General Formula (PA-1) is a compound exhibiting deterioration in proton acceptor properties, no proton acceptor properties, or a change from the proton acceptor properties to acid properties since the compound has a functional group with proton acceptor properties as well as an acidic group, as compared with the compound (PA).

Q-A-(X)ₙ—B—R (PA-1)

In General Formula (PA-1),

Q represents —SO₃H, —CO₂H, or —W₁NHW₂R_{f}, in which R_{f} represents an alkyl group (preferably having 1 to 20 carbon atoms), a cycloalkyl group (preferably having 3 to 20 carbon atoms), or an aryl group (preferably having 6 to 30 carbon atoms), and W₁ and W₂ each independently represent —SO₂— or —CO—.

A represents a single bond or a divalent linking group.

X represents —SO₂— or —CO—.

n represents 0 or 1.

B represents a single bond, an oxygen atom, or —N(Rₓ)R_{y}—, in which Rₓ represents a hydrogen atom or a monovalent organic group, and R_{y} represents a single bond or a divalent organic group, provided that Rₓ may be bonded to R_{y} to form a ring or may be bonded to R to form a ring.

R represents a monovalent organic group having a functional group with proton acceptor properties.

General Formula (PA-1) will be described in more detail.

The divalent linking group in A is preferably a divalent linking group having 2 to 12 carbon atoms, such as and examples thereof include an alkylene group and a phenylene group. The divalent linking group is more preferably an alkylene group having at least one fluorine atom, preferably having 2 to 6 carbon atoms, and more preferably having 2 to 4 carbon atoms. The alkylene chain may contain a linking group such as an oxygen atom and a sulfur atom. In particular, the alkylene group is preferably an alkylene group in which 30 to 100% by number of the hydrogen atoms are substituted with fluorine atoms, and more preferably, the carbon atom bonded to the Q site has a fluorine atom. The alkylene group is still more preferably a perfluoroalkylene group, and even still more preferably a perfluoroethylene group, a perfluoropropylene group, or a perfluorobutylene group.

The monovalent organic group in Rₓ is preferably an organic group having 1 to 30 carbon atoms, and examples thereof include an alkyl group, a cycloalkyl group, an aryl group, an aralkyl group, and an alkenyl group. These groups may further have a substituent.

The alkyl group in Rₓ may have a substituent, is preferably a linear and branched alkyl group having 1 to 20 carbon atoms, and may have an oxygen atom, a sulfur atom, or a nitrogen atom in the alkyl chain.

The cycloalkyl group in Rₓ may have a substituent, is preferably a monocyclic cycloalkyl group or a polycyclic cycloalkyl group having 3 to 20 carbon atoms, and may have an oxygen atom, a sulfur atom, or a nitrogen atom in the ring.

The aryl group in Rₓ may have a substituent, is preferably an aryl group having 6 to 14 carbon atoms, and examples thereof include a phenyl group and a naphthyl group.

The aralkyl group in Rₓ may have a substituent, is preferably an aralkyl group having 7 to 20 carbon atoms, and examples thereof include a benzyl group and a phenethyl group.

The alkenyl group in Rₓ may have a substituent and may be linear, branched, or chained. The alkenyl group is preferably an alkenyl group having 3 to 20 carbon atoms. Examples of the alkenyl group include a vinyl group, an allyl group, and a styryl group.

Examples of a substituent in a case where Rₓ further has a substituent include a halogen atom, a linear, branched, or cyclic alkyl group, an alkenyl group, an alkynyl group, an aryl group, an acyl group, an alkoxycarbonyl group, an aryloxycarbonyl group, a carbamoyl group, a cyano group, a carboxyl group, a hydroxyl group, an alkoxy group, an aryloxy group, an alkylthio group, an arylthio group, a heterocyclic oxy group, an acyloxy group, an amino group, a nitro group, a hydrazino group, and a heterocyclic group.

Preferred examples of the divalent organic group in R_{y} include an alkylene group.

Examples of the ring structure which may be formed by the mutual bonding of Rₓ and R_{y} include a 5- to 10-membered ring, and particularly preferably a 6-membered ring, each containing a nitrogen atom.

The functional group with proton acceptor properties in R is the same as above, and examples thereof include groups having a heterocyclic aromatic, nitrogen-containing structure such as azacrown ether, primary to tertiary amines, pyridine, and imidazole.

The organic group having such a structure is preferably an organic group having 4 to 30 carbon atoms, and examples thereof include an alkyl group, a cycloalkyl group, an aryl group, an aralkyl group, and an alkenyl group.

In the alkyl group, the cycloalkyl group, the aryl group, the aralkyl group, or the alkenyl group containing a functional group with proton acceptor properties or an ammonium group in R, the alkyl group, the cycloalkyl group, the aryl group, the aralkyl group, or the alkenyl group is the same as the alkyl group, the cycloalkyl group, the aryl group, the aralkyl group, or the alkenyl group as mentioned as Rₓ, respectively.

When B is —N(Rₓ)R_{y}—, it is preferable that R and Rₓ are bonded to each other to form a ring. The formation of a ring structure improves the stability and enhances the storage stability of a composition using the same. The number of carbon atoms which form a ring is preferably 4 to 20, the ring may be monocyclic or polycyclic, and an oxygen atom, a sulfur atom, or a nitrogen atom may be contained in the ring.

Examples of the monocyclic structure include a 4-membered ring, a 5-membered ring, a 6-membered ring, a 7-membered ring, and a 8-membered ring, each containing a nitrogen atom, or the like. Examples of the polycyclic structure include structures formed by a combination of two, or three or more monocyclic structures.

R_{f} of -W₁NHW₂R_{f} represented by Q is preferably an alkyl group having 1 to 6 carbon atoms, which may have a fluorine atom, and more preferably a perfluoroalkyl group having 1 to 6 carbon atoms. Further, it is preferable that at least one of W₁ or W₂ is —SO₂—, with a case where both W₁ and W₂ are —SO₂— being more preferable.

Q is particularly preferably —SO₃H or —CO₂H from the viewpoint of the hydrophilicity of an acid group.

The compound represented by General Formula (PA-1) in which Q site is sulfonic acid can be synthesized by a common sulfonamidation reaction. For example, the compound can be synthesized by a method in which one sulfonyl halide moiety of a bissulfonyl halide compound is selectively reacted with an amine compound to form a sulfonamide bond, and then the another sulfonyl halide moiety thereof is hydrolyzed, or a method in which a cyclic sulfonic acid anhydride is reacted with an amine compound to cause ring opening.

The compound (PA) is preferably an ionic compound. The functional group with proton acceptor properties may be contained in any one of an anion moiety and a cation moiety, and it is preferable that the functional group is contained in an anion moiety.

Preferred examples of the compound (PA) include compounds represented by the following General Formulae (4) to (6).

R₁—W₂—N⁻—W₁-A-(X)ₙ—B—R[C]⁺ (4)

R—SO₃⁻[C]⁺ (5)

R—CO₂⁻[C]⁺ (6)

In General Formulae (4) to (6), A, X, n, B, R, R_{f}, W₁, and W₂ each have the same definitions as in General Formula (PA-1).

C⁺ represents a counter cation.

The counter cation is preferably an onium cation. More specifically, more preferred examples thereof include a sulfonium cation described as S⁺(R₂₀₁)(R₂₀₂)(R₂₀₃) in General Formula (ZI) and an iodonium cation described as I⁺(R₂₀₄)(R₂₀₅) in General Formula (ZII).

Specific examples of the compound (PA) include the compounds exemplified in <0280> of US2011/0269072A.

Furthermore, in the present invention, compounds (PA) other than a compound which generates the compound represented by General Formula (PA-1) can also be appropriately selected. For example, a compound containing a proton acceptor moiety at its cation moiety may be used as an ionic compound. More specific examples thereof include a compound represented by the following General Formula (7).

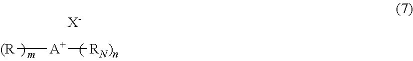

In the formula, A represents a sulfur atom or an iodine atom.

m represents 1 or 2 and n represents 1 or 2, provided that m+n=3 when A is a sulfur atom and that m+n=2 when A is an iodine atom.

R represents an aryl group.

R_{N} represents an aryl group substituted with the functional group with proton acceptor properties, and X⁻ represents a counter anion.

Specific examples of X⁻ include the same anions as those of the photoacid generators (A) as described above.

Specific preferred examples of the aryl group of R and R_{N} include a phenyl group.

Specific examples of the functional group with proton acceptor properties contained in R_{N} are the same as those of the functional group with proton acceptor properties as described above in Formula (PA-1).

Specific examples of the ionic compounds having a proton acceptor site at a cationic moiety include the compounds exemplified in <0291> of US2011/0269072A.

Furthermore, such compounds can be synthesized, for example, with reference to the methods described in JP2007-230913A, JP2009-122623A, and the like.

The compound (PA) may be used alone or in combination of two or more kinds thereof.

The content of the compound (PA) is preferably 0.1 to 10% by mass, and more preferably 1 to 8% by mass, with respect to the total solid content of the composition.

The composition of the present invention can further contain an onium salt which becomes a relatively weak acid with respect to the photoacid generator, as an acid diffusion control agent.

In the case of mixing the photoacid generator and an onium salt that generates an acid which is a relatively weak acid with respect to an acid generated from the photoacid generator, when the acid generated from the photoacid generator upon irradiation with actinic ray or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is deactivated in appearance, and thus, it is possible to carry out the control of acid diffusion.

As the onium salt which becomes a relatively weak acid with respect to the photoacid generator, compounds represented by the following General Formulae (d1-1) to (d1-3) are preferable.

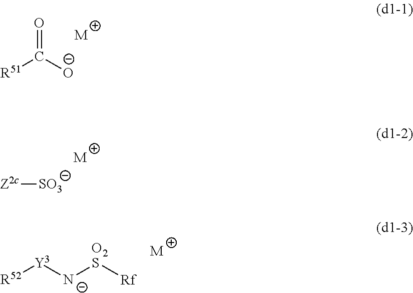

In the formulae, R⁵¹ is a hydrocarbon group which may have a substituent, Z^{2c} is a hydrocarbon group (provided that carbon adjacent to S is not substituted with a fluorine atom) having 1 to 30 carbon atoms, which may have a substituent, R⁵² is an organic group, Y³ is a linear, branched, or cyclic alkylene group or arylene group, Rf is a hydrocarbon group containing a fluorine atom, and M⁺'s are each independently a sulfonium or iodonium cation.

Preferred examples of the sulfonium cation or the iodonium cation represented by M⁺ include the aforementioned sulfonium cations in General Formula (ZI) and the aforementioned iodonium cations in General Formula (ZII).

Preferred examples of the anionic moiety of the compound represented by General Formula (d1-1) include the structures exemplified in paragraph [0198] of JP2012-242799A.

Preferred examples of the anionic moiety of the compound represented by General Formula (d1-2) include the structures exemplified in paragraph [0201] of JP2012-242799A.

Preferred examples of the anionic moiety of the compound represented by General Formula (d1-3) include the structures exemplified in paragraphs [0209] and [0210] of JP2012-242799A.

The onium salt which becomes a relatively weak acid with respect to the photoacid generator may be a compound (hereinafter also referred to as an “onium salt (C)”) having a cationic moiety (C) and an anionic moiety in the same molecule, in which the cationic moiety and the anionic moiety are linked to each other via a covalent bond.

As the onium salt (C), a compound represented by any one of the following General Formulae (C-1) to (C-3) is preferable.

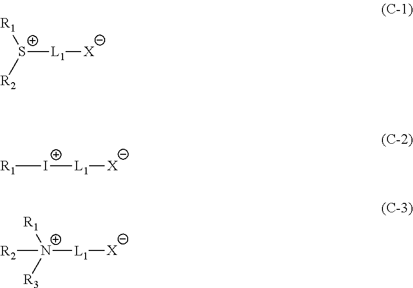

In General Formulae (C-1) to (C-3),

R₁, R₂, and R₃ represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, —SO₂⁻, and —N⁻—R₄. R₄ represents a monovalent substituent having a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to one another to form a ring structure. Further, in (C-3), two members out of R₁ to R₃ may be combined to form a double bond with an N atom.

Examples of the substituent having 1 or more carbon atoms in R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, and preferably an alkyl group, a cycloalkyl group, and an aryl group.

Examples of L₁ as a divalent linking group include a linear or branched alkylene group, a cycloalkylene group, an arylene group, a carbonyl group, an ether bond, an ester bond, an amide bond, an urethane bond, an urea bond, and a group formed by a combination of two or more kinds of these groups. L₁ is more preferably alkylene group, an arylene group, an ether bond, an ester bond, and a group formed by a combination of two or more kinds of these groups.

Preferred examples thereof the compound represented by General Formula (C-1) include the compounds exemplified in paragraphs [0037] to [0039] of JP2013-6827A and paragraphs [0027] to [0029] of JP2013-8020A.

Preferred examples thereof the compound represented by General Formula (C-2) include the compounds exemplified in paragraphs [0012] and [0013] of JP2012-189977A.

Preferred examples thereof the compound represented by General Formula (C-3) include the compounds exemplified in paragraphs [0029] to [0031] of JP2012-252124A.

The content of the onium salt which becomes a relatively weak acid with respect to the photoacid generator is preferably 0.5% to 10.0% by mass, more preferably 0.5% to 8.0% by mass, and still more preferably 1.0% to 8.0% by mass, with respect to the solid content of the composition.

<Solvent>

Examples of the solvent which can be used in the preparation of the composition by dissolving the respective components include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Preferred examples of the alkylene glycol monoalkyl ether carboxylate include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Preferred examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferred examples of the alkyl ester of lactic acid include methyl lactate, ethyl lactate, propyl lactate, and butyl lactate.

Preferred examples of the alkyl alkoxypropionate include ethyl 3-ethoxypropionate, methyl 3-methoxypropionate, methyl 3-ethoxypropionate, and ethyl 3-methoxypropionate.

Preferred examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Preferred examples of the monoketone compound which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferred examples of the alkylene carbonate include propylene carbonate, vinylene carbonate, ethylene carbonate, and butylene carbonate.

Preferred examples of the alkyl alkoxy acetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferred examples of the alkyl pyruvate include methyl pyruvate, ethyl pyruvate, and propyl pyruvate.

Examples of the solvent that can be preferably used include solvents having a boiling point of 130° C. or higher under the conditions of normal temperature and normal pressure. Specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate, and propylene carbonate.

In the present invention, the solvents may be used alone or in combination of two or more kinds thereof.

In the present invention, a mixed solvent prepared by mixing a solvent containing a hydroxyl group in its structure with a solvent not containing a hydroxyl group in its structure may be used as an organic solvent.

As the solvent containing a hydroxyl group and the solvent not containing a hydroxyl group, the exemplified compounds as described above can be appropriately selected, as the solvent containing a hydroxyl group, alkylene glycol monoalkyl ether, alkyl lactate, and the like are preferable, and propylene glycol monomethyl ether and ethyl lactate are more preferable. Further, as the solvent not containing a hydroxyl group, alkylene glycol monoalkyl ether acetate, alkylalkoxypropionate, a monoketone compound which may contain a ring, cyclic lactone, alkyl acetate, and the like preferable, and among these, propylene glycol monomethyl ether acetate, ethylethoxypropionate, 2-heptanone, γ-butyrolactone, cyclohexanone, and butyl acetate are particularly preferable, and propylene glycol monomethyl ether acetate, ethylethoxypropionate, and 2-heptanone are most preferable.

The solvent is preferably a mixed solvent is preferably a solvent of two or more kinds of propylene glycol monomethyl ether acetate. A mixed solvent including at least propylene glycol monomethyl ether acetate and cyclohexanone, or a mixed solvent including at least propylene glycol monomethyl ether acetate and γ-butyrolactone are more preferable. A mixed solvent including three kinds of at least propylene glycol monomethyl ether acetate, cyclohexanone and γ-butyrolactone is particularly preferable.

The mixing ratio (based on mass) of propylene glycol monomethyl ether acetate to other solvents is 1/99 to 99/1, and preferably 10/90 to 90/10. A mixed solvent having a proportion of propylene glycol monomethyl ether acetate of 50% by mass or more is particularly preferable from the viewpoint of coating evenness.

<Surfactant>

The composition of the present invention may further contain a surfactant. In a case where the composition of the present invention further contains the surfactant, it preferably contains any one of fluorine- and/or silicon-based surfactants (a fluorine-based surfactant, a silicon-based surfactant, and a surfactant having both a fluorine atom and a silicon atom), or two or more kinds thereof.

By incorporating the surfactant into the composition of the present invention, it becomes possible to provide a resist pattern which is improved in adhesiveness and decreased in development defects with good sensitivity and resolution when an exposure light source of 250 nm or less, and particularly 220 nm or less, is used.

Examples of the fluorine- and/or silicon-based surfactants include the surfactants described in <0276> of US2008/0248425A, and examples thereof include EFTOP EF301 and EF303 (manufactured by Shin-Akita Kasei K. K.); FLORAD FC430, 431, and 4430 (manufactured by Sumitomo 3M Inc.); MEGAFACE F171, F173, F176, F189, F113, F110, F177, F120, and R08 (manufactured by DIC Corp.); Surflon S-382, SC101, 102, 103, 104, 105, and 106 (manufactured by Asahi Glass Co., Ltd.); TROYSOL S-366 (manufactured by Troy Chemical Corp.); GF-300 and GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA); and FTX-204G, 208G, 218G 230G, 204D, 208D, 212D, 218D, and 222D (manufactured by NEOS Co., Ltd.). In addition, Polysiloxane Polymer KP-341 (manufactured by Shin-Etsu Chemical Co., Ltd.) can also be used as the silicon-based surfactant.

Furthermore, in addition to those known surfactants as described above, a surfactant using a polymer having a fluoro-aliphatic group derived from a fluoro-aliphatic compound which is produced by a telomerization method (also referred to as a telomer method) or an oligomerization method (also referred to as an oligomer method), can be used as the surfactant. The fluoro-aliphatic compound can be synthesized in accordance with the method described in JP2002-90991A.

The polymer having a fluoro-aliphatic group is preferably a copolymer of a fluoro-aliphatic group-containing monomer with a (poly(oxyalkylene))acrylate and/or a (poly(oxyalkylene))methacrylate, and the polymer may have an irregular distribution or may be a block copolymer. Examples of the poly(oxyalkylene) group include a poly(oxyethylene) group, a poly(oxypropylene) group, and a poly(oxybutylene) group. This group may also be a unit having alkylenes differing in the chain length within the same chain, such as block-linked poly(oxyethylene, oxypropylene, and oxyethylene) and block-linked poly(oxyethylene and oxypropylene). Furthermore, the copolymer of a fluoro-aliphatic group-containing monomer and a (poly(oxyalkylene))acrylate (or methacrylate) is not limited only to a binary copolymer but may also be a ternary or greater copolymer obtained by simultaneously copolymerizing two or more different fluoro-aliphatic group-containing monomers or two or more different (poly(oxyalkylene))acrylates (or methacrylates).

Examples of the commerically available surfactant corresponding to the above include MEGAFACE F178, F-470, F-473, F-475, F-476, and F-472 (manufactured by DIC Corp.); a copolymer of an acrylate (or methacrylate) having a C₆F1₃ group with a (poly(oxyalkylene)) acrylate (or methacrylate); and a copolymer of an acrylate (or methacrylate) having a C₃F₇ group with a (poly(oxyethylene)) acrylate (or methacrylate) and a (poly(oxypropylene)) acrylate (or methacrylate).

In addition, in the present invention, a surfactant other than the fluorine- and/or silicon-based surfactants described in <0280> of US2008/0248425A can also be used.

These surfactants may be used alone or in combination of a few surfactants.

The amount of the surfactant to be used is preferably 0% to 2% by mass, more preferably 0.0001% to 2% by mass, and still more preferably 0.0005% to 1% by mass, with respect to the total solid content amount (excluding the solvent) of the actinic ray-sensitive or radiation-sensitive resin composition.

<Dissolution Inhibiting Compound Having Molecular Weight of 3,000 or Less, which is Capable of Decomposing by the Action of an Acid, and Thus, has an Increased Solubility in an Alkali Developer>

As the compound having a molecular weight of 3,000 or less, which is capable of decomposing by the action of an acid, and thus, has an increased solubility in an alkali developer (which is hereinafter also referred to as a “dissolution inhibiting compound”), an alicyclic or aliphatic compound which contains an acid-decomposable group such as a cholic acid derivative which includes an acid-decomposable group described in the Proceeding of SPIE, 2724, 355 (1996) is preferable since the transparency with respect to light having a wavelength of 220 nm or less is not reduced. Examples of the acid-decomposable group and the alicyclic structure include the same as those described for the resin (A).

Furthermore, in a case where the composition of the present invention is exposed to a KrF excimer laser or irradiated with electron beams, the dissolution inhibiting compound is preferably a compound including a structure in which the phenolic hydroxyl group of a phenol compound is substituted with an acid-decomposable group. As the phenol compound, a phenol compound containing 1 to 9 phenol skeletons is preferable, and a phenol compound having 2 to 6 phenol skeletons is more preferable.

The amount of the dissolution inhibiting compound to be added is preferably 3% to 50% by mass, and more preferably 5% to 40% by mass, with respect to the solid content of the composition.

Specific examples of the dissolution inhibiting compound are shown below, but the present invention is not limited thereto.

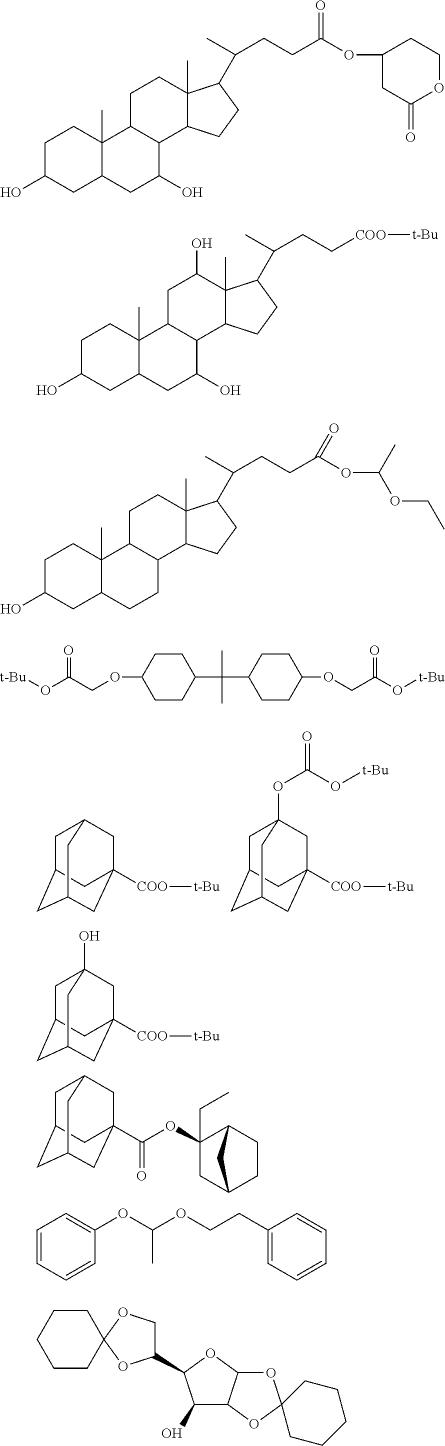

<Other Additives>

The composition of the present invention may further contain a dye, a plasticizer, a light sensitizer, a light absorbent, and a compound that promotes solubility in a developer (for example, a phenol compound having a molecular weight of 1,000 or less, an alicyclic compound having a carboxyl group, and an aliphatic compound having a carboxyl group), or the like, if desired.

Such a phenol compound having a molecular weight of 1,000 or less may be easily synthesized by those skilled in the art with reference to the method disclosed in, for example, JP1992-122938A (JP-H04-122938A), JP1990-28531A (JP-H02-28531A), U.S. Pat. No. 4,916,210A, EP219294B, and the like.

Specific examples of the alicyclic or aliphatic compound having a carboxyl group include, but are not limited to, a carboxylic acid derivative having a steroid structure such as cholic acid, deoxycholic acid, and lithocholic acid, an adamantane carboxylic acid derivative, adamantane dicarboxylic acid, cyclohexane carboxylic acid, and cyclohexane dicarboxylic acid.

The concentration of solid contents of the composition of the present invention is usually 1.0% to 10% by mass, preferably 2.0% to 5.7% by mass, and more preferably 2.0% to 5.3% by mass. By setting the concentration of solid contents to these ranges, it is possible to uniformly apply the resist solution onto a substrate and additionally, it is possible to form a resist pattern having excellent line width roughness. The reason is not clear, but it is considered that, by setting the concentration of solid contents to 10% by mass or less, and preferably 5.7% by mass or less, the aggregation of materials, particularly the photoacid generator, in the resist solution is suppressed and, as the result, it is possible to form a uniform resist film.

The concentration of solid contents is the weight percentage of the weight of other the resist components excluding the solvent with respect to the total weight of the composition.

The composition of the present invention is used by dissolving the components in a predetermined organic solvent, and preferably in the mixed solvent, filtering the solution through a filter, and then applying the filtered solution onto a predetermined substrate. The filter used for filtration is preferably a polytetrafluoroethylene-, polyethylene- or nylon-made filter having a pore size of 0.1 μm or less, more preferably 0.05 μm or less, and still more preferably 0.03 μm or less. In the filtration through a filter, as described in, for example, JP2002-62667A, circulating filtration may be carried out, or the filtration may be carried out by connecting two or more kinds of filters in series or in parallel. In addition, the composition may be filtered a plurality of times. Furthermore, the composition may be subjected to a deaeration treatment or the like before or after filtration through a filter.

Further, in terms of the applications of the composition, it is certain that a smaller content of the metal impurity elements in the composition is more preferable. Accordingly, it is preferable that the metal impurity contents of various raw materials are maintained low. In addition, it is preferable that the composition whose impurities are considered with regard to containers for storing and transporting the composition is preferably used.

<Pattern Forming Method>

As described above, the pattern forming method of the present invention includes:

a film forming step in which an actinic ray-sensitive or radiation-sensitive film including an actinic ray-sensitive or radiation-sensitive resin composition is formed,

an exposing step of irradiating the actinic ray-sensitive or radiation-sensitive film with actinic ray or radiation,

an alkali development step in which the region with a large irradiation dose of active light or radiation in the actinic ray-sensitive or radiation-sensitive film after exposure is dissolved using an alkali developer, and

an organic solvent development step in which the region with a small irradiation dose of actinic ray or radiation in the actinic ray-sensitive or radiation-sensitive film after exposure is dissolved using a developer including an organic solvent.

[Film Forming Step]

In the present step, an actinic ray-sensitive or radiation-sensitive film is formed by applying the actinic ray-sensitive or radiation-sensitive resin composition of the present invention onto a substrate. Coating the substrate with the actinic ray-sensitive or radiation-sensitive resin composition can be a commonly known method. For example, an actinic ray-sensitive or radiation-sensitive film may be formed by applying an actinic ray-sensitive or radiation-sensitive resin composition onto a substrate in the wafer center, and then spinning the substrate using a spinner, or an actinic ray-sensitive or radiation-sensitive film may be formed by coating an actinic ray-sensitive or radiation-sensitive resin composition while spinning it.

In the spinning coating, the rotation number is usually 800 rpm to 4,000 rpm. Further, the film thickness is preferably adjusted to 30 nm to 200 nm. In addition, in order to secure film formation, it is preferable to carry out a heating step (so-called prebake) after film formation.

Moreover, the substrate to be used is not particularly limited, and a substrate which is generally used in a step of manufacturing a semiconductor such as an IC including, for example, inorganic substrates such as silicon, SiN, SiO₂, and TiN, and coated inorganic substrates such as SOG, a process for manufacture of a circuit board for a liquid crystal, a thermal head, or the like, and a process used in other lithographic processes of photofabrication. Further, an antireflection film (BARC) may be formed between the actinic ray-sensitive or radiation-sensitive film and the substrate, as necessary. As the antireflection film, known organic or inorganic antireflection films may be appropriately used (see, for example, U.S. Pat. No. 8,669,042A). In addition, an antireflection film (TARC) may further be formed on the layer of the actinic ray-sensitive or radiation-sensitive film.

[Exposing Step]

The light source wavelength used in the exposure method in the present invention is not limited, and examples thereof include infrared rays, visible light, ultraviolet rays, far ultraviolet rays, extreme ultraviolet rays, X-rays, and electron beams, for example, far ultraviolet rays at a wavelength of preferably 250 nm or less, more preferably 220 nm or less, and particularly preferably 1 to 200 nm, specifically a KrF excimer laser (248 nm), an ArF excimer laser (193 nm), an F₂ excimer laser (157 nm), X-rays, EUV (13 nm), electron beams, and the like, with the KrF excimer laser, the ArF excimer laser, EUV, or the electron beams being preferable, and the ArF excimer laser being more preferable.

Furthermore, a liquid immersion exposure method can be applied to the step of carrying out exposure of the present invention. It is possible to combine the liquid immersion exposure method with super-resolution technology such as a phase shift method and a modified illumination method.

In the case of carrying out the liquid immersion exposure, a step of cleaning the surface of a film with an aqueous chemical liquid may be carried out (1) after forming a film on a substrate and before an exposing step, and/or (2) after a step of subjecting the film to exposure through an immersion liquid and before heating the film.

The immersion liquid is preferably a liquid which is transparent to exposure wavelength and has a minimum temperature coefficient of refractive index so as to minimize the distortion of an optical image projected on the resist film. In particular, in a case where the exposure light source is an ArF excimer laser (wavelength: 193 nm), water is preferably used in terms of easy availability and easy handling, in addition to the above-described viewpoints.

In the case of using water, an additive (liquid) that decreases the surface tension of water while increasing the interfacial activity may be added at a slight proportion. It is preferable that this additive does not dissolve the resist layer on the wafer, and gives a negligible effect on the optical coat at the undersurface of a lens element. Such an additive is preferably for example, an aliphatic alcohol having a refractive index substantially equal to that of water, and specific examples thereof include methyl alcohol, ethyl alcohol, and isopropyl alcohol.

On the other hand, in a case where materials opaque to light at 193 nm or impurities having a great difference in the refractive index from water are incorporated, the distortion of an optical image projected on a resist is caused. Therefore, the water to be used is preferably distilled water. Further, pure water after filtration through an ion exchange filter or the like may also be used.

In addition, the lithography performance can be enhanced by increasing the refractive index of the immersion liquid. From such a viewpoint, an additive for increasing the refractive index, for example, may be added to water, or heavy water (D₂O) may be used in place of water.

The receding contact angle of the resist film formed using the actinic ray-sensitive or radiation-sensitive resin composition in the present invention is 70° or more at 23±3° C. at a humidity of 45±5%, which is suitable in the case of the exposure through a liquid immersion medium. The receding contact angle is preferably 750 or more, and more preferably 75° to 85°.

If the receding contact angle is extremely small, the resist film cannot be suitably used in the case of the exposure through a liquid immersion medium. Further, the effect of reducing defects cannot be sufficiently exhibited due to remaining water (water marks). In order to realize a favorable receding contact angle, it is preferable to incorporate the hydrophobic resin (HR) into the actinic ray-sensitive or radiation-sensitive composition. Alternatively, a coating layer (a so-called “top coat”) formed of the hydrophobic resin composition may be formed on the resist film to improve the receding contact angle. Examples of the composition that can be applied to the top coat include the compositions described in, for example, JP2009-122325A, JP2006-053300A, and the like.

It is preferable that the top coat composition contains the above-described hydrophobic resin and at least one selected from the group consisting of the following (A1), (A2), and (A3) (which is also referred to as an “additive (A)” or a “compound (A)”).

(A1) A basic compound or base generator

(A2) A compound containing at least one bond or group selected from the group consisting of an ether bond, a thioether bond, a hydroxyl group, a thiol group, a carbonyl bond, and an ester bond

(A3) An onium salt

The content of (A1) to (A3) is preferably 1% to 25% by mass, and more preferably 2.5% to 20% by mass, with respect to the total solid contents of the top coat composition.

As the basic compound which can be contained in the top coat composition, an organic basic compound is preferable, and a nitrogen-containing basic compound is more preferable.

A compound (which is hereinafter referred to as a “compound (A2)” or an “additive (A2)”) including at least one group or bond selected from the group consisting of an ether bond, a thioether bond, a hydroxyl group, a thiol group, a carbonyl bond, and an ester bond, which can be contained in the top coat composition, will be described below.

As described above, the compound (A2) is a compound including at least one group or bond selected from the group consisting of an ether bond, a thioether bond, a hydroxyl group, a thiol group, a carbonyl bond, and an ester bond.

As described above, the compound (A2) is a compound including at least one group or bond selected from the group consisting of an ether bond, a thioether bond, a hydroxyl group, a thiol group, a carbonyl bond, and an ester bond. In one aspect of the present invention, the compound (A2) preferably has two or more groups or bonds selected from the group, more preferably has three or more groups or bonds selected from the group, and still more preferably four or more groups or bonds selected from the group. In this case, groups or bonds selected from ether bonds, thioether bonds, hydroxyl groups, thiol groups, carbonyl bonds, and ester bonds included in plural numbers in the compound (A2) may be the same as or different from each other.

In one aspect of the present invention, the compound (A2) preferably has a molecular weight of 3,000 or less, more preferably has a molecular weight of 2,500 or less, still more preferably has a molecular weight of 2,000 or less, and particularly preferably has a molecular weight of 1,500 or less.

Furthermore, in one aspect of the present invention, the number of carbon atoms included in the compound (A2) is preferably 8 or more, more preferably 9 or more, and still more preferably 10 or more.

Moreover, in one aspect of the present invention, the number of carbon atoms included in the compound (A2) is preferably 30 or less, more preferably 20 or less, and still more preferably 15 or less.

Furthermore, in one aspect of the present invention, the compound (A2) is preferably a compound having a boiling point of 200° C. or higher, more preferably a compound having a boiling point of 220° C. or higher, and still more preferably a compound having a boiling point of 240° C. or higher.

Moreover, in one aspect of the present invention, the compound (A2) is preferably a compound having an ether bond, more preferably a compound having two or more ether bonds, still more preferably a compound having three or more ether bonds, and even still more preferably a compound having four or more ether bonds.

In one aspect of the present invention, the compound (A2) is still more preferably a compound having repeating units containing an oxyalkylene structure represented by the following General Formula (1).

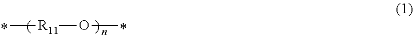

In the formula,

R₁₁ represents an alkylene group which may have a substituent,

n represents an integer of 2 or more, and

* represents a bonding arm.

The number of carbon atoms of the alkylene group represented by R₁₁ in General Formula (1) is not particularly limited, but is preferably 1 to 15, more preferably 1 to 5, still more preferably 2 or 3, and particularly preferably 2. In a case where this alkylene group has a substituent, the substituent is not particularly limited, but is preferably, for example, an alkyl group (preferably having 1 to 10 carbon atoms).

n is preferably an integer of 2 to 20, among which an integer of 10 or less is more preferable due to an increase in DOF.

The average value of n's is preferably 20 or less, more preferably 2 to 10, still more preferably 2 to 8, and particularly preferably 4 to 6 due to an increase in DOF. Here, “the average value of n's” means the value of n determined when the weight-average molecular weight of the compound (A2) is measured by GPC, and the obtained weight-average molecular weight is allowed to match the general formula. In a case where n is not an integer, it is a value rounded to the nearest integer of the specified numeric value.

R₁₁ present in plural numbers may be the same as or different from each other.

Furthermore, a compound having a partial structure represented by General Formula (1) is preferably a compound represented by the following General Formula (1-1) due to an increase in DOF.

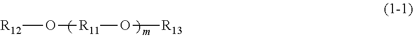

In the formula,

the definition, specific examples, and suitable aspects of R₁₁ are the same as those of R₁₁ in General Formula (1) as described above, respectively.

R₁₂ and R₁₃ each independently represent a hydrogen atom or an alkyl group. The number of carbon atoms of the alkyl group is not particularly limited, but is preferably 1 to 15. R₁₂ and R₁₃ may be bonded to each other to form a ring.

m represents an integer of 1 or more. m is preferably an integer of 1 to 20, and above all, is more preferably an integer of 10 or less due to an increase in DOF.

The average value of m's is preferably 20 or less, more preferably 1 to 10, still more preferably 1 to 8, and particularly preferably 4 to 6 due to an increase in DOF. Here, “the average value of m's” has the same definition as the “average value of n's” as described above.

In a case where m is 2 or more, R₁₁'s present in plural numbers may be the same as or different from each other.

In one aspect of the present invention, the compound having a partial structure represented by General Formula (1) is preferably alkylene glycol including at least two ether bonds.

The compound (A2) may be used as a commercially available product or may be synthesized according to a known method.

Specific examples of the compound (A2) are shown below but the present invention is not limited thereto.

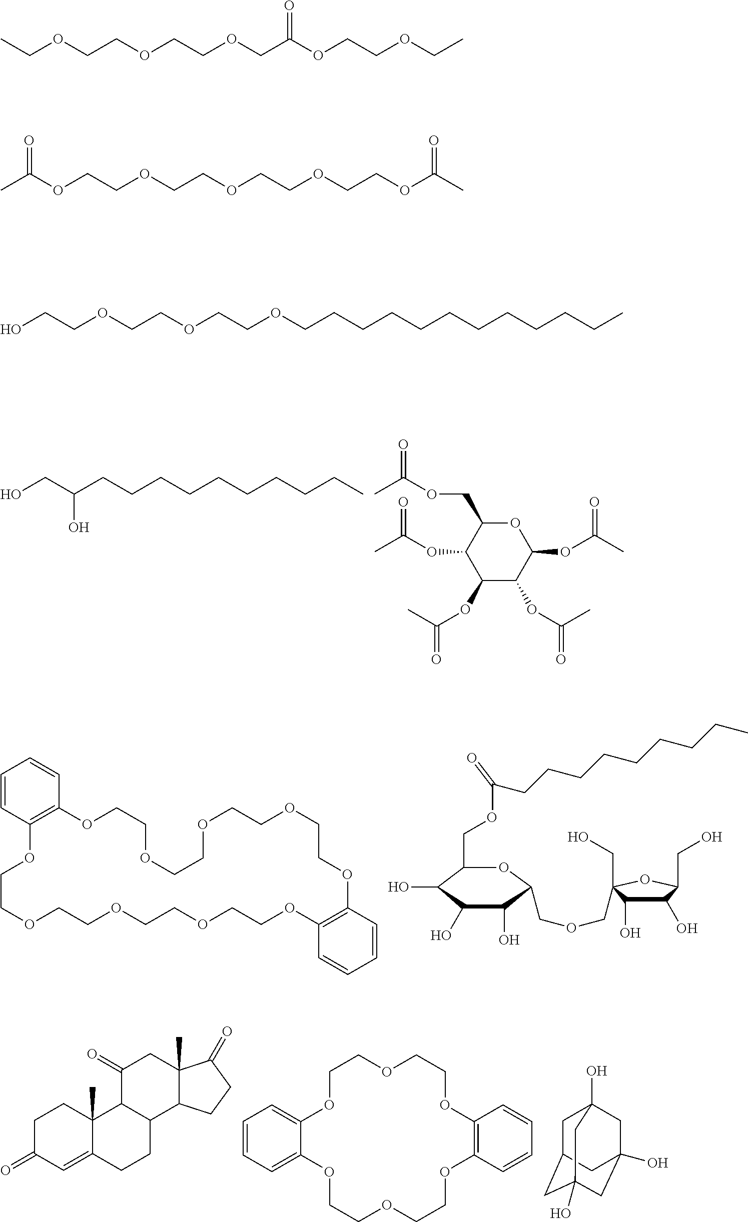

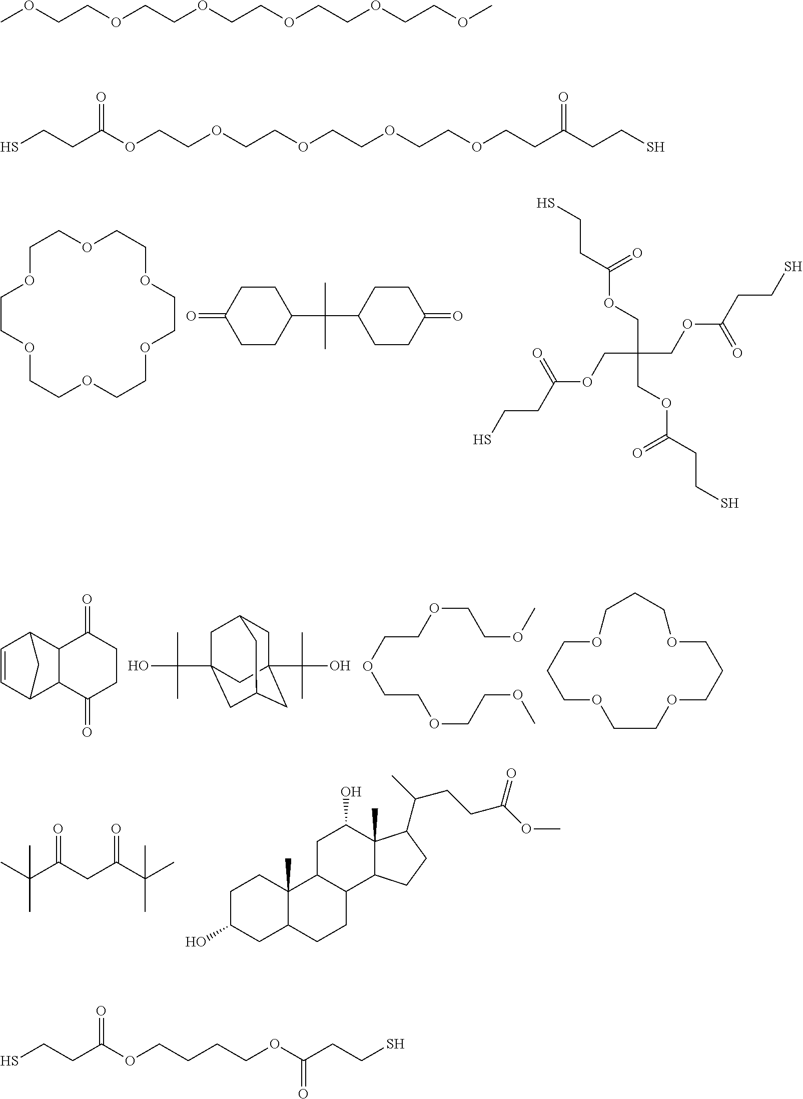

The top coat composition can contain an onium salt which becomes a relatively weak acid with respect to an acid generator. In the case where an acid generated from the acid generator upon irradiation with actinic ray or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is apparently deactivated, which makes it possible to carry out the control of acid diffusion.

As the onium salt which becomes a relatively weak acid with respect to an acid generator, compounds represented by the following General Formulae (d1-1) to (d1-3) are preferable.

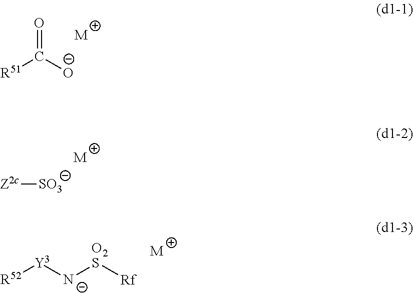

In the formulae, R⁵¹ is a hydrocarbon group which may have a substituent, Z^{2c} is a hydrocarbon group (provided that carbon adjacent to S is not substituted with a fluorine atom) having 1 to 30 carbon atoms, which may have a substituent, R⁵² is an organic group, Y³ is a linear, branched, or cyclic alkylene group or arylene group, Rf is a hydrocarbon group containing a fluorine atom, and M⁺'s are each independently a sulfonium or iodonium cation.

Preferred examples of the sulfonium cation or the iodonium cation represented by M⁺ include the sulfonium cations exemplified in General Formula (ZI) and the iodonium cations exemplified in General Formula (ZII).

In the liquid immersion exposure step, it is necessary for the immersion liquid to move on a wafer following the movement of an exposure head which scans the wafer at a high speed to form an exposure pattern. Therefore, the contact angle of the immersion liquid for the actinic ray-sensitive or radiation-sensitive film in a dynamic state is important, and the resist is required to have a performance of allowing the immersion liquid to follow the high-speed scanning of an exposure head with no remaining of a liquid droplet.

[Developing Step]

The pattern forming method of the present invention includes a double development process including an alkali development step and an organic solvent development step, as described above. In the alkali development step, the region with a large irradiation dose of actinic ray or radiation in the actinic ray-sensitive or radiation-sensitive film after exposure (that is, an exposed area) is dissolved, and in the organic solvent development step, the region with a small irradiation dose of actinic ray or radiation in the actinic ray-sensitive or radiation-sensitive film (that is, an unexposed area) after exposure is dissolved. In the present invention, the order of the alkali development step and the organic solvent development step is not particularly limited, but from the viewpoint of pattern survivability, development is preferably carried out in the order of the alkali development step and the organic solvent development step.

<Organic Solvent Developer>

As the organic solvent developer, a polar solvent and a hydrocarbon-based solvent such as a ketone-based solvent, an ester-based solvent, an alcohol-based solvent, an amide-based solvent, and an ether-based solvent can be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybuthyl acetate, 3-methyl-3-methoxybutyl acetate, methyl formate, ethyl formate, butyl formate, propyl formate, ethyl lactate, butyl lactate, propyl lactate, isoamyl acetate, butyl butanoate, methyl 2-hydroxyisobutyrate, isobutyl isobutyrate, and butyl propionate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanonol; glycol-based solvents such as ethylene glycol, diethylene glycol, and triethylene glycol; and glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent includes dioxane and tetrahydrofuran in addition to the glycol ether-based solvents.

As the amide-based solvent, for example, N-methyl-2-pirroridone, N,N-dimethylacetamide, N,N-dimethylformamide, hexamethylphosphoric triamide, 1,3-dimethyl-2-imidazolidinone, or the like can be used.

Examples of the hydrocarbon-based solvent include aromatic hydrocarbon-based solvents such as toluene and xylene, and aliphatic hydrocarbon-based solvents such as pentane, hexane, octane, and decane.

In particular, the organic solvent developer is preferably a developer containing at least one organic solvent selected from the group consisting of a ketone-based solvent and an ester-based solvent, and particularly preferably a developer including butyl acetate as an ester-based solvent as well as methyl amyl ketone (2-heptanone) as a ketone-based solvent.

The above solvents can be used by mixing two or more thereof or by mixing water or solvents other than the solvents. However, in order to sufficiently exhibit the effects of the invention, the moisture content in the developer is preferably less than 10% by mass, but a developer having substantially no water is more preferable.

That is, the amount of the organic solvent to be used with respect to the organic solvent developer is preferably from 90% by mass to 100% by mass, and more preferably from 95% by mass to 100% by mass, with respect to the organic solvent developer.

The vapor pressure of the organic solvent developer at 20° C. is preferably 5 kPa or less, more preferably 3 kPa or less, and particularly preferably 2 kPa or less. By setting the vapor pressure of the organic solvent developer to 5 kPa or less, the evaporation of the developer on the substrate or in a developing cup is inhibited, the temperature uniformity in the wafer surface is improved, and as a result, the dimensional uniformity within a wafer plane is improved.

It is possible to add an appropriate amount of a surfactant to the organic solvent developer, if necessary.

Although the surfactant is not particularly limited, for example, ionic or non-ionic fluorine-based and/or silicon-based surfactants, or the like can be used. Examples of the fluorine-based and/or the silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and non-ionic surfactants are preferable. The non-ionic surfactant is not particularly limited, but it is more preferable to use a fluorine-based surfactant or a silicon-based surfactant.

The amount of the surfactant to be used is usually 0.001% to 5% by mass, preferably 0.005% to 2% by mass, and more preferably from 0.01% to 0.5% by mass, with respect to the entire amount of the developer.

In addition, to the organic solvent developer, the nitrogen-containing compound described in JP2013-11833A, in particular, <0021> to <0063>, if necessary. By the addition, further improvement in contrast can be expected.

<Alkali Developer>

The alkali developer is not particularly limited, and for example, an aqueous alkali solution of inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, quaternary ammonium salts such as trimethylphenylammonium hydroxide, trimethylbenzylammonium hydroxide, and triethylbenzylammonium hydroxide, or cyclic amines such as pyrrole and piperidine can be used. Further, it is also possible to use a developer by adding an appropriate amount of alcohols or a surfactant to the aqueous alkali solution. In particular, a 2.38%-by-mass aqueous tetramethylammonium hydroxide solution is preferable.

The alkali concentration of the alkali developer is usually 0.1% to 20% by mass.

The pH of the alkali developer is usually 10.0 to 15.0.

As the developing method, for example, a method in which a substrate is immersed in a tank filled with a developer for a certain period of time (a dip method), a method in which a developer is heaped up to the surface of a substrate by surface tension and developed by stopping for a certain period of time (a paddle method), a method in which a developer is sprayed on the surface of a substrate (a spray method), a method in which a developer is continuously discharged on a substrate spun at a constant rate while scanning a developer discharging nozzle at a constant rate (a dynamic dispense method), or the like, can be applied.

In a case where the various developing methods include a step of discharging a developer toward a resist film from a development nozzle of a developing device, the discharge pressure of the developer discharged (the flow velocity per unit area of the developer discharged) is preferably 2 mL/sec/mm² or less, more preferably 1.5 mL/sec/mm² or less, and still more preferably 1 mL/sec/mm² or less. The flow velocity has no particular lower limit, but is preferably 0.2 mL/sec/mm² or more in consideration of a throughput. Details thereof are described in JP2010-232550A, in particular, paragraphs 0022 to 0029, and the like.

In addition, after the organic solvent developer step or the alkali development step, a step of stopping the development while replacing with another solvent may also be carried out.

[Heating Step]

In one aspect, the pattern forming method of the present invention may include a heating step.

It is also preferable that the pattern forming method of the present invention includes, for example, a pre-heating step (PB; Prebake) after the film forming step and before the exposing step.

In addition, in another aspect, it is also preferable that the pattern forming method of the present invention includes a step of heating after exposure (PEB; Post Exposure Bake) after the exposing step and before the developing step. By baking, the reaction of the exposed area is promoted, and the sensitivity or the pattern profile is improved. This PEB step is preferably carried out twice, immediately before the alkali development step and immediately before the organic solvent development step, respectively.

For both of PB and PEB, the heating is preferably carried out at a heating temperature of 70° C. to 130° C., and more preferably 80° C. to 120° C.

The heating time is preferably 30 to 300 seconds, more preferably 30 to 180 seconds, and still more preferably 30 to 90 seconds.

Heating may be carried out using a means installed in an ordinary exposure-and-development machine, or may also be carried out using a hot plate or the like.

[Rinsing Step]

It is preferable that the method includes a rinsing step of performing cleaning using a rinsing liquid after the step of carrying out development using an organic solvent developer and/or a step of carrying out development using an alkali developer.

As a rinsing liquid in the rinsing treatment to be carried out after the alkali development, pure water is used, and an appropriate amount of a surfactant may also be added and used.

The rinsing liquid used in the rinsing step after the step of carrying out development using an organic solvent development is not particularly limited as long as the rinsing liquid does not dissolve the resist pattern, and a solution including an ordinary organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same as those described for the developer including an organic solvent.

In one aspect of the present invention, after the developing step, it is more preferable to carry out a step of cleaning using a rinsing liquid containing at least one organic solvent selected from the group consisting of a ketone-based solvent, an ester-based solvent, an alcohol-based solvent, and an amide-based solvent, it is still more preferable to carry out a step of cleaning using a rinsing liquid containing a hydrocarbon-based solvent, an alcohol-based solvent, or an ester-based solvent, it is particularly preferable to carry out a step of cleaning using a rinsing liquid containing a monohydric alcohol, and it is most preferable to carry out a step of cleaning using a rinsing liquid containing a monohydric alcohol having 5 or more carbon atoms.

Here, examples of the monohydric alcohol to be used in the rinsing step include a linear, branched, or cyclic monohydric alcohol, and specifically, 1-hexanol, 2-hexanol, 4-methyl-2-pentanol, 1-pentanol, 3-methyl-1-butanol, or the like can be used can be used.

As the hydrocarbon-based solvent to be used in the rinsing step, a hydrocarbon compound having 6 to 30 carbon atoms is preferable, a hydrocarbon compound having 8 to 30 carbon atoms is more preferable, and a hydrocarbon compound having 10 to 30 carbon atoms is particularly preferable. By using a rinsing liquid including decane and/or undecane among those, pattern collapse is inhibited.

In a case where an ester-based solvent is used as the rinsing liquid, ester-based solvents (one kind or two or more kinds) may be added and glycol ether-based solvents may also be used. Specific examples in this case include use of an ester-based solvent (preferably butyl acetate) as a main component and a glycol ether-based solvent (preferably propylene glycol monomethyl ether (PGME)) as a sub-component. By such a use, a residue defect is inhibited.

A plurality of these respective solvents may be mixed, or the solvent may be used by mixing it with an organic solvent other than ones described above.

The moisture content of the rinsing liquid is preferably 10% by mass or less, more preferably 5% by mass or less, and particularly preferably 3% by mass or less. By setting the moisture content to 10% by mass or less, good development characteristics can be obtained.

The vapor pressure of the rinsing liquid to be used after the step of carrying out development using a developer including an organic solvent at 20° C. is preferably from 0.05 kPa to 5 kPa, more preferably from 0.1 kPa to 5 kPa, and most preferably from 0.12 kPa to 3 kPa. By setting the vapor pressure of the rinsing liquid to a range from 0.05 kPa to 5 kPa, the temperature uniformity within a wafer plane is improved, and further, the dimensional uniformity within a wafer plane is enhanced by inhibition of swelling due to the permeation of the rinsing liquid.

The rinsing liquid may also be used after adding an appropriate amount of a surfactant thereto.

In the rinsing step, the wafer which has been subjected to development using a developer including an organic solvent is subjected to a cleaning treatment using a rinsing liquid containing the organic solvent. A method for the cleaning treatment is not particularly limited, and for example, a method in which a rinsing liquid is continuously ejected on a substrate rotated at a constant rate (a rotation application method), a method in which a substrate is immersed in a bath filled with a rinsing liquid for a certain period of time (a dip method), a method in which a rinsing liquid is sprayed on a substrate surface (a spray method), or the like, can be applied. Among these, a method in which a cleaning treatment is carried out using the rotation application method, a substrate is rotated at a rotation speed of 2,000 rpm to 4,000 rpm after cleaning, thereby removing the rinsing liquid from the substrate, is preferable. Further, it is also preferable that a heating treatment (Post Bake) is included after the rinsing step. The developer and the rinsing liquid that remain between and inside the patterns are removed by the bake. The heating step after the rinsing step is usually carried out at 40° C. to 160° C., and preferably at 70° C. to 95° C., and usually for 10 seconds to 3 minutes, and preferably for 30 seconds to 90 seconds.

It is preferable that the organic solvent developer, the alkali developer, and/or the rinsing liquid, which are used in the present invention, have a small content of various fine particles or impurities such as metal elements. In order to obtain such a chemical solution with small amounts of impurities, it is preferable to reduce the impurities, for example, by producing the chemical solution in a clean room or performing filtration through various filters such as a Teflon (registered mark) filter, a polyolefin-based filter, and an ion exchange filter. With regard to the metal element, any of metal element concentrations Na, K, Ca, Fe, Cu, Mg, Mn, Li, A1, Cr, Ni, and Zn is preferably 1 ppm or less, more preferably 100 ppt or less, and still more preferably 10 ppt or less, and but a chemical solution having substantially no metal element (at a detection limit of a measurement device or less) is particularly preferable.

In addition, the container for storing the developer or the rinsing liquid is not particularly limited, and a container made of a polyethylene resin, a polypropylene resin, a polyethylene-polypropylene resin, or the like, which is used in the application of electronic materials, may be appropriately used, but in order to reduce the impurities eluted from the container, it is also preferable to select a container which is less likely to cause elution of a component from the inner wall of the container to the chemical solution. Examples of such a container include a container in which the inner wall of the container is formed of a perfluororesin (for example, a FluoroPure PFA composite drum (inner surface coming into contact with a liquid; a PFA resin lining) manufactured by Entegris, Inc., and a steel-made drum (inner surface coming into contact with a liquid; and a zinc phosphate coat) manufactured by JFE Steel).

The pattern formed by the method of the present invention is typically used as a mask in an etching process in the manufacture of a semiconductor, but can also be used in other applications. Examples of such other applications include applications for guide pattern formation in Directed Self-Assembly (DSA) (see, for example, ACS Nano, Vol. 4, No. 8, pp. 4815-4823), that is, a so-called core material (core) in a spacer process (see, for example, JP1991-270227A (JP-H03-270227A) and JP2013-164509A).

A method for improving the surface roughness of the pattern may also be applied to the pattern formed by the method of the present invention. Examples of the method for improving the roughness of the pattern include a method for treating a resist pattern by plasma of a hydrogen-containing gas disclosed in WO2014/002808A. In addition, known methods as described in JP2004-235468A, JP2009-19969A, Proc. of SPIE Vol. 8328 83280N-1 “EUV Resist Curing Technique for LWR Reduction and Etch Selectivity Enhancement”.

It is preferable that various materials (for example, a resist solvent, a developer, a rinsing liquid, a composition for forming an antireflection film, a composition for forming a top coat, and the like) used in the actinic ray-sensitive or radiation-sensitive resin composition of the present invention, and the pattern forming method of the present invention do not include impurities such as metals. The content of the impurities included in these materials is preferably 1 ppm or less, more preferably 100 ppt or less, and still more preferably 10 ppt or less, but the material having substantially impurities (at a detection limit of a measurement device or less) is particularly preferable.

Examples of a method for removing impurities such as metals from the various materials include filtration using a filter. As the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. As the filter, ones which have been washed with an organic solvent in advance may be used. In the step of filtration using a filter, plural kinds of filters may be connected in series or in parallel, and used. In the case of using plural kinds of filters, a combination of filters having different pore diameters and/or materials may be used. In addition, various materials may be washed plural times, and a step of washing plural times may be a circulatory filtration step.

Moreover, examples of the method for decreasing the impurities such as metals included in the various materials include a method involving, for example, performing distillation under the conditions in which contamination is inhibited as much as possible by, for example, selecting raw materials having a small content of metals as raw materials constituting various materials, subjecting raw materials constituting various materials to filtration using a filter, or lining the inside of a device with Teflon. In the preferred conditions for filtration using a filter, performed for raw materials constituting various materials are the same as described above.

In addition to filtration using a filter, removal of impurities by an adsorbing material may be carried out, or a combination of filtration using a filter and filtration using an adsorbing material may be used. As the adsorbing material, known adsorbing materials may be used, and for example, inorganic adsorbing materials such as silica gel and zeolite, and organic adsorbing materials such as activated carbon can be used.

The present invention further relates to a method for manufacturing an electronic device, including the pattern forming method of the present invention as described above, and an electronic device manufactured by the manufacturing method.

The electronic device of the present invention is suitably mounted on electric or electronic equipment (home electronics, OA/media-related equipment, optical equipment, telecommunication equipment, and the like).

### EXAMPLES

Hereinafter, the present invention will be described in detail with reference to Examples, but the contents of the present invention are not limited thereto.

<Preparation of Resist>

The components shown in Table 2 below were dissolved in a solvent to prepare a solution having a concentration of solid contents of 3% by mass, and the solution was filtered through a polyethylene filter having a pore size of 0.03 μm to prepare a resist solution.

TABLE 2

| | | | | | Acid | | | | | | concentra- |
|---|---|---|---|---|---|---|---|---|---|---|---|
| | | | | | diffusion | | Hydro- | | | | tion of solid |
| | Acid-decom- | Mass/ | Photoacid | Mass/ | control | Mass/ | phobic | Mass/ | | | contents/ |
| Resist | posable resin | g | generator | g | agent | g | resin | g | Solvent | Ratio | % by mass |
| Ar-01 | P-1 | 10 | PAG-1 | 0.8 | Q-1 | 0.1 | N-1 | 0.05 | SL-1/SL-2 | 70/30 | 3 |
| Ar-02 | P-2 | 10 | PAG-1 | 0.8 | Q-1 | 0.1 | N-2 | 0.05 | SL-1/SL-3 | 90/10 | 3 |
| Ar-03 | P-3 | 10 | PAG-1 | 0.8 | Q-1 | 0.1 | N-3 | 0.05 | SL-1/SL-2 | 70/30 | 3 |
| Ar-04 | P-4 | 10 | PAG-1 | 0.8 | Q-1 | 0.1 | N-1 | 0.05 | SL-1/SL-2 | 70/30 | 3 |
| Ar-05 | P-5 | 10 | PAG-1 | 0.8 | Q-1 | 0.1 | N-1 | 0.05 | SL-1/SL-2 | 70/30 | 3 |
| Ar-06 | P-6 | 10 | PAG-1 | 0.8 | Q-1 | 0.1 | N-1 | 0.05 | SL-1/SL-2 | 70/30 | 3 |
| Ar-07 | P-7 | 10 | PAG-1 | 0.8 | Q-1 | 0.1 | N-1 | 0.05 | SL-1/SL-2 | 70/30 | 3 |
| Ar-08 | P-8 | 10 | PAG-1 | 0.8 | Q-1 | 0.1 | N-1 | 0.05 | SL-1/SL-3 | 70/30 | 3 |
| Ar-09 | P-9 | 10 | PAG-1 | 0.8 | Q-1 | 0.1 | N-1 | 0.05 | SL-1/SL-2 | 70/30 | 3 |
| Ar-10 | P-10 | 10 | PAG-1 | 0.8 | Q-1 | 0.1 | N-1 | 0.05 | SL-1/SL-2 | 70/30 | 3 |
| Ar-11 | P-11 | 10 | PAG-1 | 0.8 | Q-1 | 0.1 | N-1 | 0.05 | SL-1/SL-2 | 70/30 | 3 |
| Ar-12 | P-12 | 10 | PAG-1 | 0.8 | Q-1 | 0.1 | N-1 | 0.05 | SL-1/SL-2 | 70/30 | 3 |
| Ar-13 | P-13 | 10 | PAG-1 | 0.8 | Q-1 | 0.1 | N-1 | 0.05 | SL-1/SL-2 | 70/30 | 3 |
| Ar-14 | P-14 | 10 | PAG-1 | 0.8 | Q-1 | 0.1 | N-1 | 0.05 | SL-1/SL-2 | 70/30 | 3 |
| Ar-15 | P-15 | 10 | PAG-2 | 0.8 | Q-2 | 0.1 | N-1 | 0.05 | SL-1/SL-2 | 70/30 | 3 |
| Ar-16 | P-16 | 10 | PAG-3 | 0.8 | Q-3 | 0.1 | N-1 | 0.05 | SL-1/SL-2 | 70/30 | 3 |
| Ar-17 | P-17 | 10 | PAG-4 | 0.8 | Q-4 | 0.1 | N-1 | 0.05 | SL-1/SL-2 | 70/30 | 3 |
| Ar-18 | P-18 | 10 | PAG-5 | 3 | Q-5 | 0.3 | N-1 | 0.05 | SL-1/SL-2 | 70/30 | 3 |
| Ar-19 | P-19 | 10 | PAG-1/PAG-5 | 0.5/1 | Q-6 | 0.3 | N-1 | 0.05 | SL-1/SL-2 | 70/30 | 3 |
| Ar-20 | P-20 | 10 | PAG-1/PAG-6 | 1/1 | Q-7 | 0.3 | N-1 | 0.05 | SL-1/SL-2 | 70/30 | 3 |
| Ar-21 | P-21 | 10 | PAG-2/PAG-7 | 1/1 | Q-8 | 0.3 | N-1 | 0.05 | SL-1/SL-2 | 70/30 | 3 |
| Ar-22 | P-22 | 10 | PAG-1/PAG-8 | 0.4/0.5 | Q-1/Q-5 | 0.05/0.1 | N-1/N-2 | 0.02/0.03 | SL-1/SL-2 | 70/30 | 3 |
| Ar-23 | P-23 | 10 | PAG-1 | 1.3 | Q-1/Q-6 | 0.05/0.1 | N-1 | 0.05 | SL-1/SL-2/SL-3 | 70/10/20 | 3 |
| Ar-24 | P-24 | 10 | PAG-6 | 3 | Q-3/Q-7 | 0.05/0.1 | N-2/N-3 | 0.01/0.04 | SL-1/SL-2 | 70/30 | 3 |
| Ar-25 | P-25 | 10 | PAG-1 | 1.3 | Q-2/Q-8 | 0.05/0.1 | N-1 | 0.05 | SL-1/SL-2 | 70/30 | 3 |
| Ar-26 | P-19/P-24 | 5/5 | PAG-4/PAG-1 | 0.6/0.2 | Q-4/Q-7 | 0.05/0.1 | N-1 | 0.05 | SL-1/SL-2 | 70/30 | 3 |
| Ar-27 | P-26 | 10 | PAG-1 | 0.8 | Q-1 | 0.1 | N-1 | 0.05 | SL-1/SL-2 | 70/30 | 3 |
| Ar-28 | P-27 | 10 | PAG-1 | 0.8 | Q-1 | 0.1 | N-1 | 0.05 | SL-1/SL-2/SL-4 | 70/20/10 | 3 |
| Ar-29 | P-28 | 10 | PAG-1 | 0.8 | Q-1 | 0.1 | N-1 | 0.05 | SL-1/SL-2 | 70/30 | 3 |
| Ar-30 | P-29 | 10 | PAG-1 | 0.8 | Q-1 | 0.1 | N-1 | 0.05 | SL-1/SL-2 | 70/30 | 3 |

<Acid-Decomposable Resin>

As the acid-decomposable resin, the resins shown below were used. It showed the weight-average molecular weight Mw, the dispersity Pd (Mw/Mn), and the compositional ratio, as described below. Here, the weight-average molecular weight Mw (in terms of polystyrene), the number-average molecular weight Mn (in terms of polystyrene), and the dispersity Pd (Mw/Mn) were calculated by GPC (solvent: THF) measurement. Further, the compositional ratio (molar ratio) of the repeating unit was calculated by ¹H-NMR measurement.

Hereinbelow, Synthesis Examples of the resin P-1 are shown. Other resins were synthesized by the same method.

### Synthesis Example 1

### Synthesis of Resin P-1

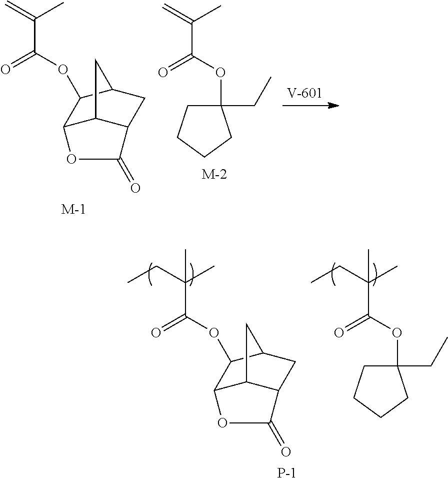

156.6 parts by mass of cyclohexanone was heated at 80° C. under a nitrogen stream. While stirring this liquid, a mixed solution of 30.6 parts by mass of a monomer M-1, 48.3 parts by mass of a monomer M-2, 290.7 parts by mass of cyclohexanone, and 2.05 parts by mass of dimethyl 2,2′-azobisisobutyrate [V-601, manufactured by Wako Pure Chemical Industries, Ltd.] was added dropwise thereto for 6 hours. After completion of the dropwise addition, the solution was additionally stirred at 80° C. for 2 hours. After leaving the reaction liquid to be cooled, the mixture was reprecipitated with a large amount of hexane/ethyl acetate (mass ratio of 7:3) and filtered, and the obtained solid was dried in vacuo to obtain 55.3 parts by mass of a resin (P-1). For the obtained resin (P-1), the weight-average molecular weight (Mw: in terms of polystyrene), the number-average molecular weight (Mn: in terms of polystyrene), and the dispersity (Mw/Mn, hereinafter referred to as “Pd”) were calculated by GPC (solvent: THF). In addition, the compositional ratio (molar ratio) was calculated by ¹H-NMR measurement.

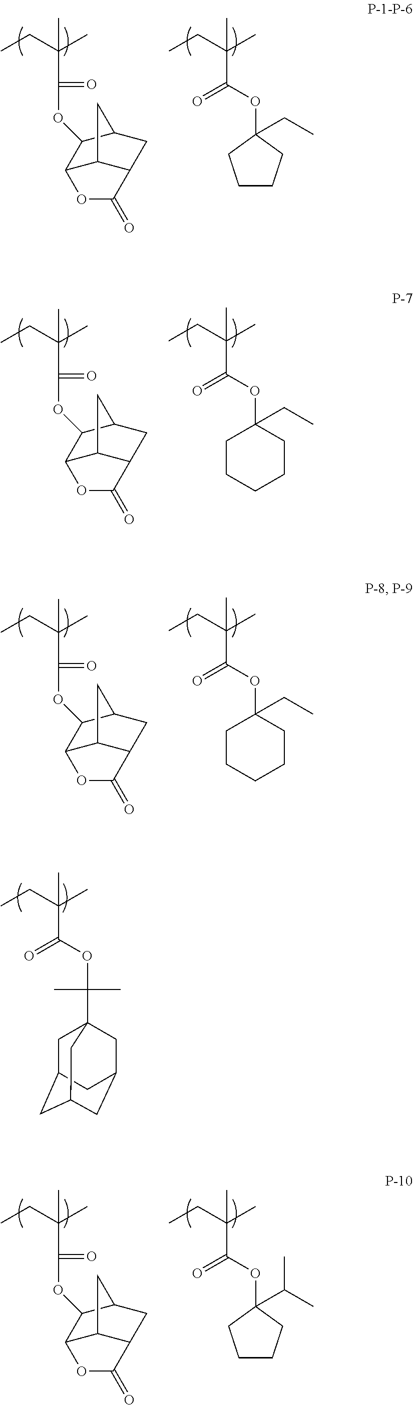

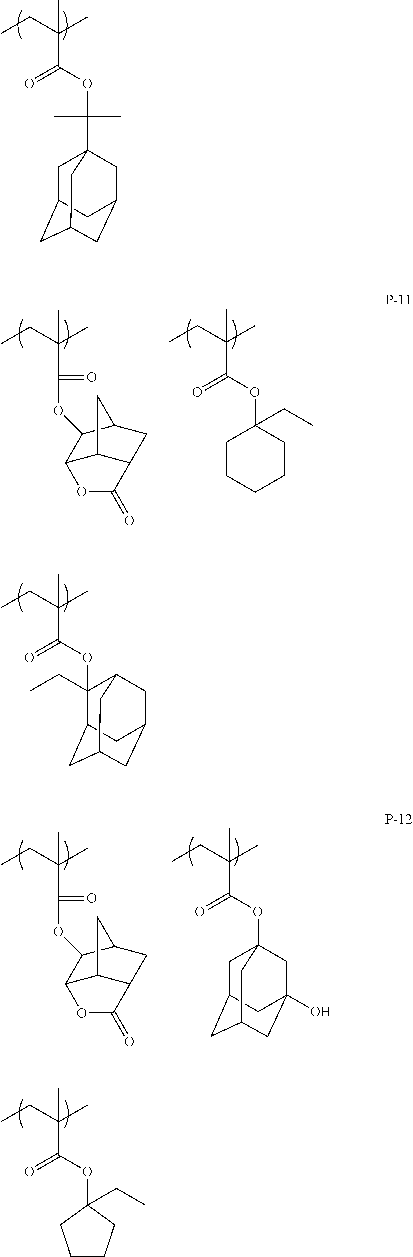

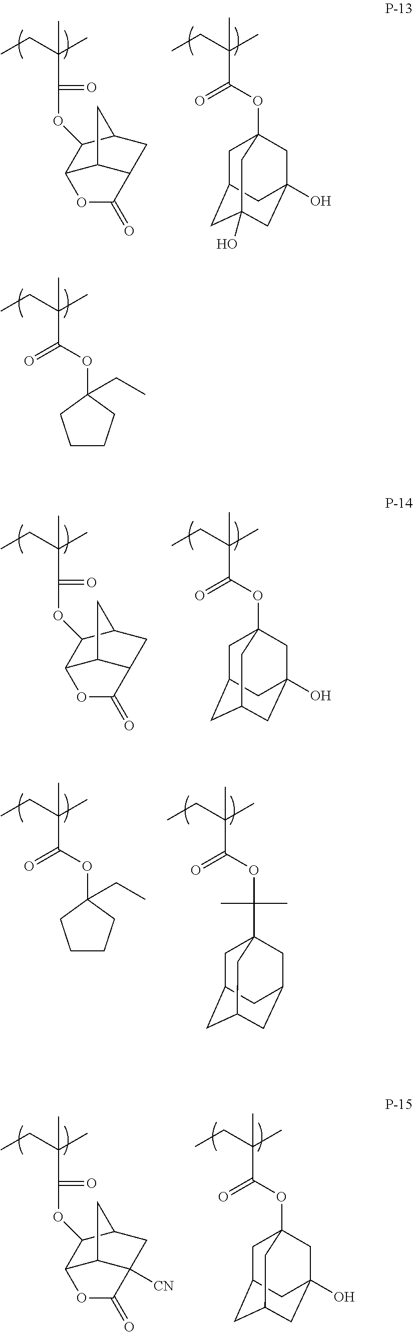

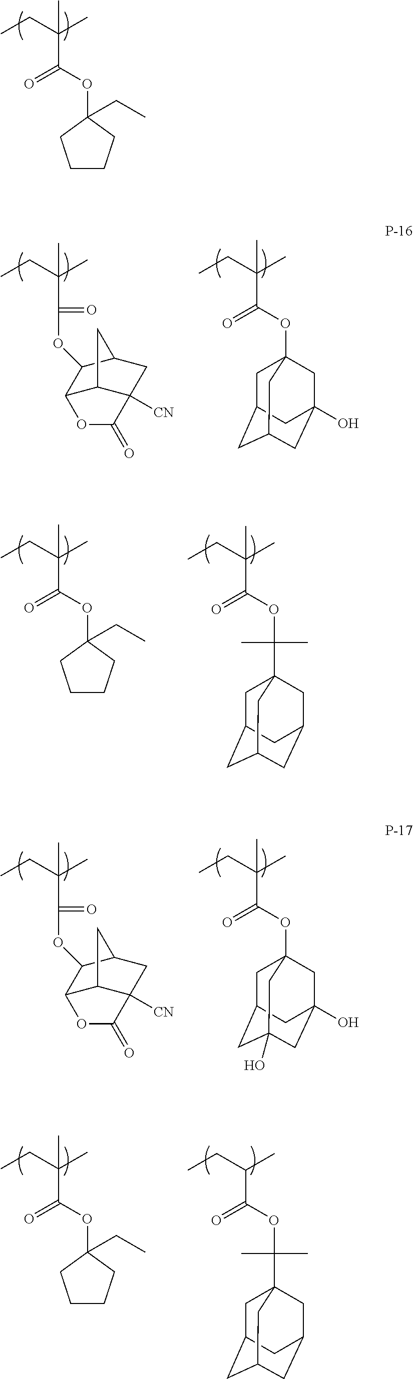

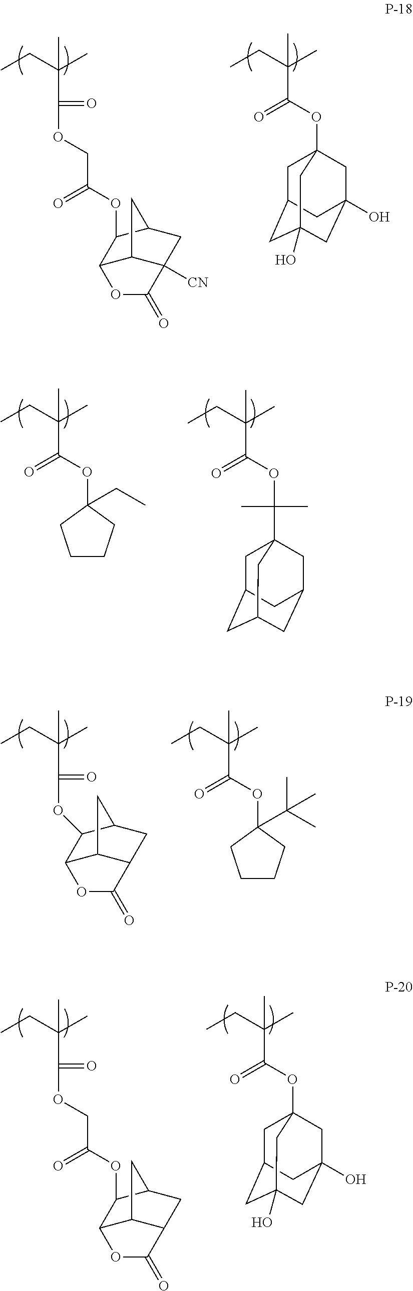

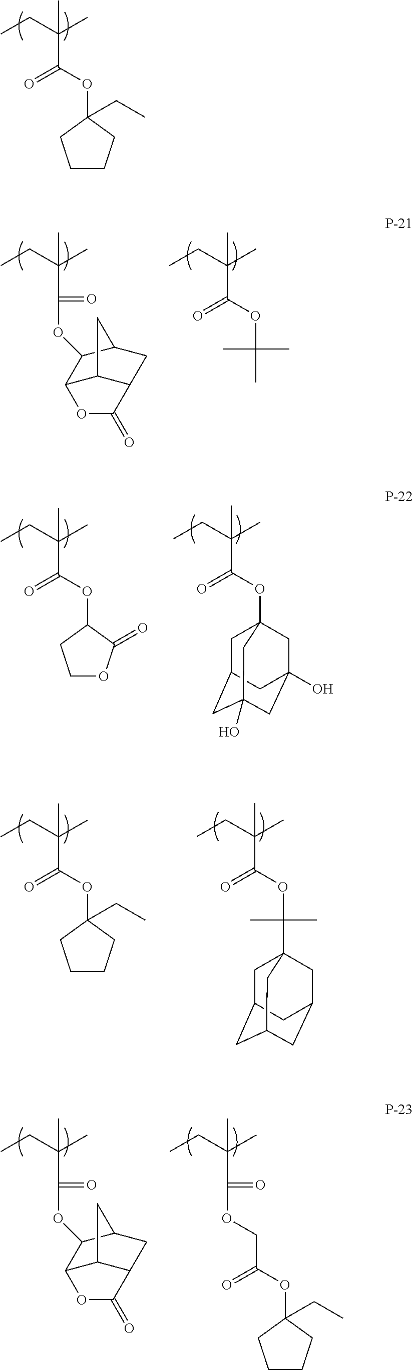

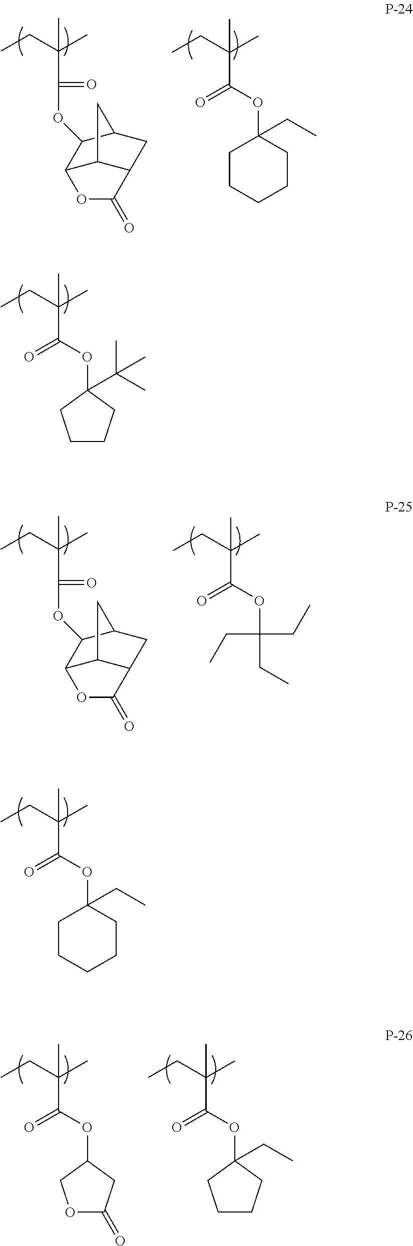

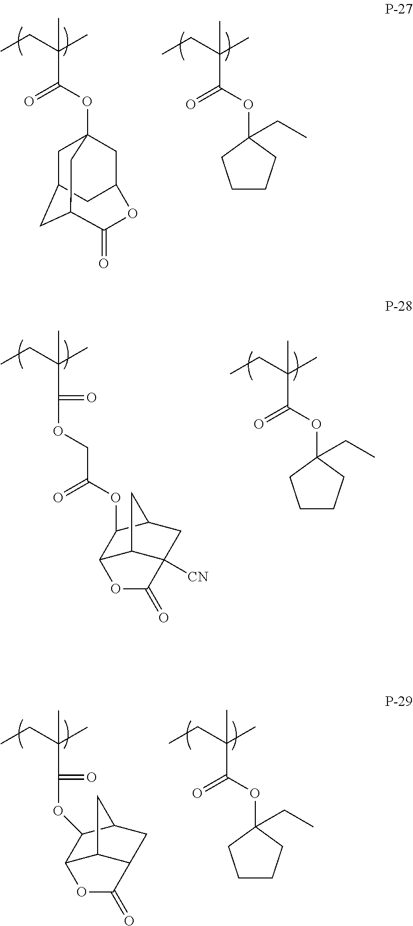

TABLE 3

| Acid-decom- | Compositional | | |
|---|---|---|---|
| posable resin | ratio | Mw | Pd |
| P-1 | 40/60 | 20,000 | 1.6 |
| P-2 | 30/70 | 20,000 | 1.5 |
| P-3 | 50/50 | 20,000 | 1.7 |
| P-4 | 40/60 | 25,000 | 2.0 |
| P-5 | 30/70 | 10,000 | 2.1 |
| P-6 | 50/50 | 15,000 | 1.5 |
| P-7 | 40/60 | 20,000 | 1.8 |
| P-8 | 40/50/10 | 20,000 | 2.2 |
| P-9 | 40/40/20 | 20,000 | 1.4 |
| P-10 | 40/40/20 | 20,000 | 1.5 |
| P-11 | 40/40/20 | 20,000 | 1.8 |
| P-12 | 30/10/60 | 20,000 | 1.6 |
| P-13 | 30/10/60 | 20,000 | 2 |
| P-14 | 30/10/50/10 | 20,000 | 1.9 |
| P-15 | 30/10/60 | 20,000 | 1.3 |
| P-16 | 30/10/50/10 | 20,000 | 2.2 |
| P-17 | 30/10/50/10 | 20,000 | 1.8 |
| P-18 | 30/10/50/10 | 20,000 | 1.7 |
| P-19 | 40/60 | 20,000 | 1.8 |
| P-20 | 30/10/60 | 20,000 | 1.7 |
| P-21 | 30/70 | 10,000 | 1.5 |
| P-22 | 30/10/50/10 | 20,000 | 1.8 |
| P-23 | 40/60 | 20,000 | 1.6 |
| P-24 | 40/50/10 | 18,000 | 1.7 |
| P-25 | 40/40/20 | 18,000 | 1.5 |
| P-26 | 40/60 | 20,000 | 1.6 |
| P-27 | 40/60 | 20,000 | 1.6 |
| P-28 | 30/70 | 10,000 | 1.7 |
| P-29 | 30/70 | 8,000 | 1.5 |

<Photoacid Generator>

As the photoacid generator, the compounds shown below were used.

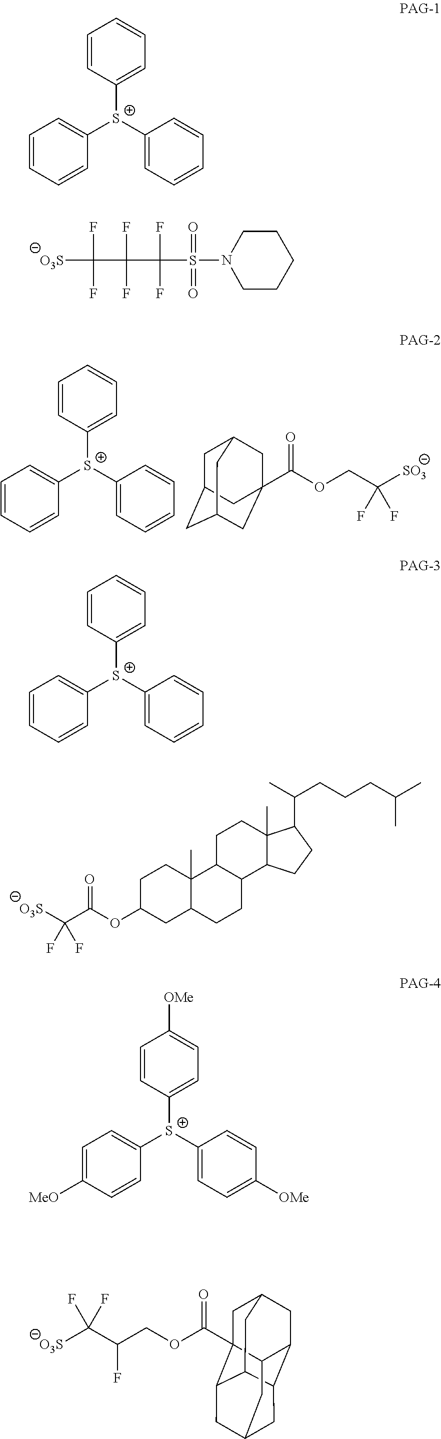

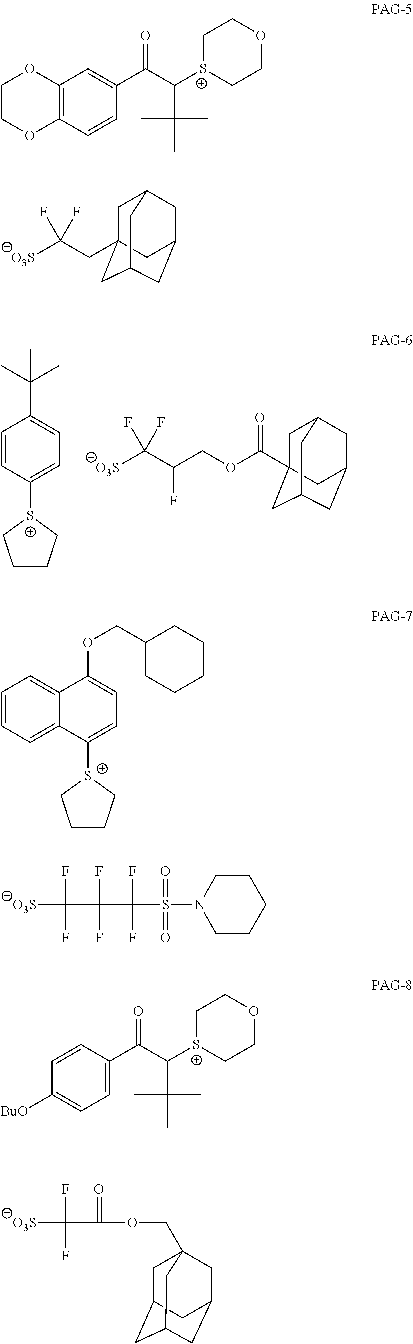

<Acid Diffusion Control Agent>

As the basic compound, the compounds shown below were used.

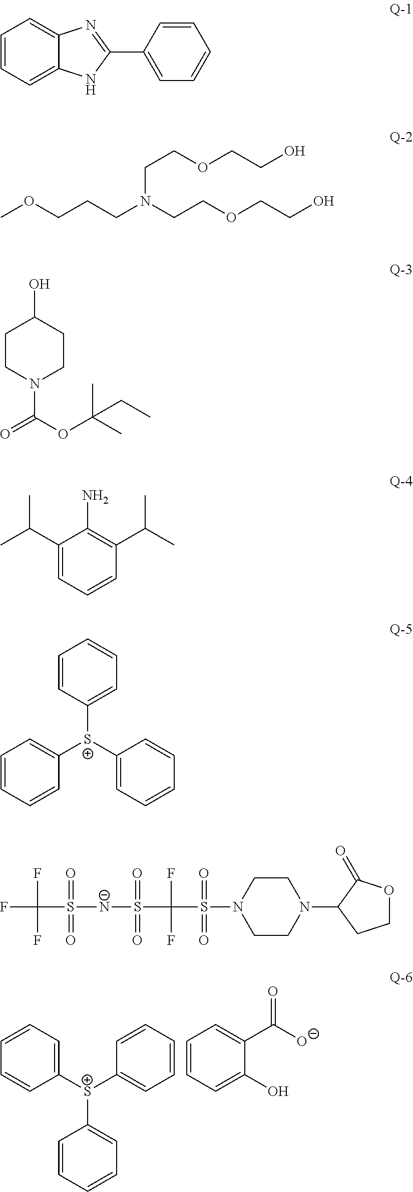

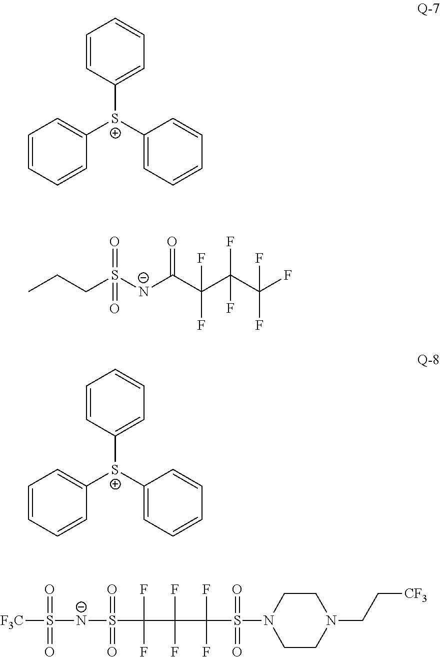 [SMILES: c1ccc([S+](c2ccccc2)c2ccccc2)cc1 ; CCCS(=O)(=O)[N-]C(=O)C(F)(F)C(F)(F)C(F)(F)F ; c1ccc([S+](c2ccccc2)c2ccccc2)cc1 ; O=S(=O)([N-]S(=O)(=O)C(F)(F)C(F)(F)C(F)(F)S(=O)(=O)N1CCN(CCC(F)(F)F)CC1)C(F)(F)F]

<Hydrophobic Resin>

As the hydrophobic resin, the resins shown below were used. Here, the weight-average molecular weight Mw (in terms of polystyrene), the number-average molecular weight Mn (in terms of polystyrene), and the dispersity Pd (Mw/Mn) were calculated by GPC (solvent: THF) measurement. Further, the compositional ratio (molar ratio) of the repeating unit was calculated by ¹H-NMR measurement.

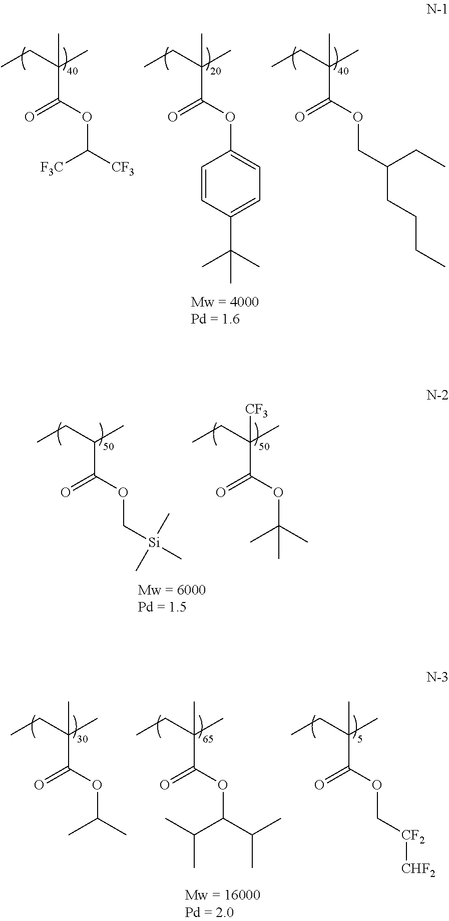

<Solvent>

As the solvent, the following ones were used.

SL-1: Propylene glycol monomethyl ether acetate (PGMEA)

SL-2: Propylene glycol monomethyl ether (PGME)

SL-3: Cyclohexanone

SL-4: γ-Butyrolactone

<ΔDth>

The ΔDth in each of the resist compositions was determined by applying Dth(PTI) and Dth(NTI) determined by the following methods to Formula (1).

[Threshold Deprotection Rate in Alkali Development: Dth(PTI)]

The prepared resist composition was applied onto a silicon wafer substrate which had been subjected to a hexamethyldisilazane treatment, using a spin coater, and baked at 90° C. for 60 seconds to form a resist film having a film thickness of 100 nm (FTₘₐₓ). The obtained resist film was fragmentated and exposed at an exposure dose which was changed as below per section. That is, the resist film was subjected to surface exposure at an exposure dose which was changed by 0.5 mJ/cm² within a range from 0 to 50 mJ/cm² per section, using an ArF excimer laser scanner (manufactured by ASML; PAS5500, NA0.75, Conventional, outer sigma 0.89). Further, the resist film was heated (Post Exposure Bake: PEB) at 100° C. for 60 seconds. At this time, the film thickness was measured at each exposure dose per section. From these measurement results, a film shrinkage curve illustrating the relationship between the film thickness after exposure and the exposure dose was obtained (see FIG. 1).

Subsequently, the samples were developed using a 2.38%-by-mass aqueous tetramethylammonium solution for 30 seconds, and then the film thickness was measured again at each exposure dose per section. From these measurement results, a sensitivity curve illustrating the relationship between the film thickness after alkali development and the exposure dose was obtained (see FIG. 2).

In the film shrinkage curve shown in FIG. 1, the film thickness at an exposure dose of 0 (unexposure) was defined as FTₘₐₓ (100 nm), the film thickness after exposure at an exposure dose of 50 mJ/cm² (Over Dose) was defined as FT₀, and the film thickness after exposure at a predetermined exposure dose was defined as S. By calculating the film shrinkage amount at each exposure dose (FTₘₐₓ−S) per section, a graph illustrating the relationship between the film shrinkage amount after exposure (deprotection amount) and the exposure dose was obtained (see FIG. 3).

Furthermore, by dividing the film shrinkage amount at each exposure dose: FTₘₐₓ−S by FTₘₐₓ−FT₀ to calculate a film shrinkage rate: {FTₘₐₓ−S/FTₘₐₓ−FT₀}×100(%), a graph illustrating the film shrinkage rate (deprotection rate (D)) after exposure and the exposure dose was obtained (see FIG. 4). Here, the film shrinkage rate at an exposure dose of 50 mJ/cm² (Over Dose) became 100%.

In addition, by changing the exposure dose in the sensitivity curve illustrating the relationship between the film thickness after alkali development and the exposure dose in FIG. 2 to the deprotection rate (D) in the graph illustrating the relationship between the deprotection rate and the exposure dose in FIG. 4, a deprotection rate curve illustrating the relationship between the film thickness after alkali development and the deprotection rate (D) was obtained (see FIG. 5). In the deprotection rate curve shown in FIG. 5, the ratio of the deprotection rate (D) when the film thickness after alkali development becomes a half (FTₘₐₓ/2) film thickness of 50 nm, with respect to the film thickness 100 nm (FTₘₐₓ) at deprotection rate of 0%, was defined as a threshold deprotection rate Dth(PTI) in alkali development.

[Threshold Deprotection Rate in Organic Solvent Development: Dth(NTI)]

The prepared resist composition was applied onto a silicon wafer substrate which had been subjected to a hexamethyldisilazane treatment, using a spin coater, and baked at 90° C. for 60 seconds to form a resist film having a film thickness of 100 nm (FTₘₐₓ). The obtained resist film was fragmentated and exposed at an exposure dose which is changed as below per section. That is, the resist film was subjected to surface exposure at an exposure dose by 0.5 mJ/cm² within a range from 0 to 50 mJ/cm² per section, using an ArF excimer laser scanner (manufactured by ASML; PAS5500, NA0.75, Conventional, outer sigma 0.89). Further, the resist film was heated (Post Exposure Bake: PEB) at 100° C. for 60 seconds. At this time, the film thickness was measured at each exposure dose per section. From these measurement results, a film shrinkage curve illustrating the relationship between the film thickness after exposure and the exposure dose was obtained (see FIG. 1).

Subsequently, the samples were developed using butyl acetate for 30 seconds, and then the film thickness was measured again at each exposure dose per section. From these measurement results, a sensitivity curve illustrating the relationship between the film thickness after organic solvent development and the exposure dose was obtained (see FIG. 6).

In the film shrinkage curve shown in FIG. 1, the film thickness at an exposure dose of 0 (unexposure) was defined as FTₘₐₓ (100 nm), the film thickness after exposure at an exposure dose of 50 mJ/cm² (Over Dose) was defined as FT₀, and the film thickness after exposure at a predetermined exposure dose was defined as S. By calculating the film shrinkage amount at each exposure dose (FTₘₐₓ−S) per section, a graph illustrating the relationship between the film shrinkage amount after exposure (deprotection amount) and the exposure dose was obtained (see FIG. 3).

Furthermore, by calculating a film shrinkage rate: {FTₘₐₓ−S/FTₘₐₓ−FT₀}×100(%) by dividing the film shrinkage amount at each exposure dose: FTₘₐₓ−S by FTₘₐₓ−FT₀, a graph illustrating the film shrinkage rate (deprotection rate (D)) after exposure and the exposure dose was obtained (see FIG. 4). Here, the film shrinkage rate at an exposure dose of 50 mJ/cm² (Over Dose) became 100%.

In addition, by changing the exposure dose in the sensitivity curve illustrating the relationship between the film thickness after organic solvent development and the exposure dose in FIG. 6 to the deprotection rate (D) in the graph illustrating the relationship between the deprotection rate and the exposure dose in FIG. 4, a deprotection rate curve illustrating the relationship between the film thickness after organic solvent (butyl acetate) development and the deprotection rate (D) was obtained (see FIG. 7). In the deprotection rate curve shown in FIG. 7, the ratio of the deprotection rate (D) when the film thickness after butyl acetate development becomes a half film thickness (Aₘₐₓ/2), with respect to the film thickness Aₘₐₓ at deprotection rate of 100%, was defined as a threshold deprotection rate Dth(NTI) in organic solvent development.

### Examples 1 to 28, and Comparative Examples 1 and 2

### Alkali Development→Organic Solvent Development/Line-and-Space Pattern

ARC29SR (manufactured by Nissan Chemical Industries, Ltd.) for forming an organic antireflection film was applied onto a silicon wafer and baked at 205° C. for 60 seconds. The resist composition described in Table 2 was applied thereonto thereon and baked at 90° C. for 60 seconds to form a resist film having a film thickness of 85 nm.

The obtained resist film was subjected to pattern exposure, using an ArF excimer laser liquid immersion scanner (manufactured by ASML, XT1700i, NA1.20, C-Quad, outer sigma 0.960, inner sigma 0.709, XY deflection). Further, as a reticle, a 6% halftone mask having a half pitch of 60 nm with line:space=1:1 was used. In addition, ultrapure water was used as an immersion liquid.

Thereafter, the resist film was baked (Post Exposure Bake; PEB) at 90° C. for 60 seconds, and then cooled to room temperature. Next, the resist film was developed using a 2.38%-by-mass TMAH (tetramethylammonium hydroxide) aqueous solution for 10 seconds, and rinsed with pure water for 30 seconds.

Thereafter, the resist film was developed using n-butyl acetate for 30 seconds. Then, the wafer was rotated at a rotation speed of 4,000 rpm for 30 seconds to obtain a resist pattern with line-and-space (L/S) having a half pitch of 30 nm.

For the obtained patterns, the disconnection suppressing performance was evaluated according to the following evaluation criteria. The evaluation results are shown in Table 4.

[Disconnection Inhibition Performance]

The line-and-space pattern with a half pitch of 30 nm obtained by the pattern forming method was observed using a length-measuring dimension scanning electron microscope (SEM, manufactured by Hitachi, Ltd., S-9380II), and the shape of the pattern was evaluated according to the following evaluation criteria.

A: Line-and-space patterns without disconnection were observed.

B: Line-and-space patterns with disconnection were observed.

C: Line-and-space patterns were not observed.

<Alkali Development→Organic Solvent Development/Contact Hole Pattern>

ARC29SR (manufactured by Nissan Chemical Industries, Ltd.) for forming an organic antireflection film was applied onto a silicon wafer and baked at 205° C. for 60 seconds. The resist composition described in Table 2 was applied thereonto and baked at 90° C. for 60 seconds to form a resist film having a film thickness of 85 nm.

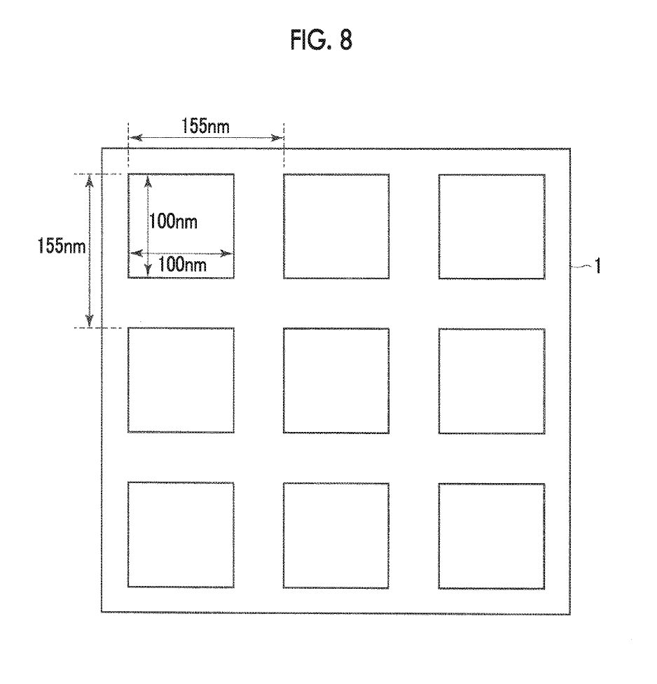

The obtained resist film was subjected to pattern exposure, using an ArF excimer laser liquid immersion scanner (manufactured by ASML, XT1700i, NA1.20, C-Quad, outer sigma 0.9, inner sigma 0.8, XY deflection). Further, as a reticle, the pattern shown in FIG. 8 was used (1 denotes a light-shielding section, and the dimensions described in drawings are described on the basis of the optical image upon projection). In addition, ultrapure water was used as an immersion liquid.

Thereafter, the resist film was baked (Post Exposure Bake; PEB) at 90° C. for 60 seconds, and then cooled to room temperature. Next, the resist film was developed using a 2.38%-by-mass aqueous TMAH (tetramethylammonium hydroxide) solution for 10 seconds, and rinsed with pure water for 30 seconds.

Thereafter, the resist film was developed using n-butyl acetate for 30 seconds. Then, the wafer was rotated at a rotation speed of 4,000 rpm for 30 seconds to obtain a contact hole pattern with a pitch of 110 nm.

For the obtained patterns, the number of bridges was evaluated according to the following evaluation criteria.

[Number of Bridges]

For the hole patterns with a pitch of 110 nm obtained in the pattern forming method, 200 holes were observed using a length-measuring dimension scanning electron microscope (SEM, manufactured by Hitachi, Ltd., S-9380II), and the number of holes found to be linked to adjacent holes was counted. A smaller number of the value indicates better performance with less linkage.

TABLE 4

| | | | | | Line-and- | |
|---|---|---|---|---|---|---|
| | | | | | space dis- | Contact |
| | | | | | connection | hole |
| | | Dth | Dth | | control | number of |
| Example | Resist | (PTI) | (NTI) | ΔDth | performance | bridges |
| 1 | Ar-01 | 0.5 | 0.31 | 1.6 | A | 2 |
| 2 | Ar-02 | 0.43 | 0.31 | 1.4 | A | 3 |
| 3 | Ar-03 | 0.58 | 0.31 | 1.9 | A | 0 |
| 4 | Ar-04 | 0.51 | 0.27 | 1.9 | A | 0 |
| 5 | Ar-05 | 0.41 | 0.41 | 1 | A | 10 |
| 6 | Ar-06 | 0.5 | 0.28 | 1.8 | A | 0 |
| 7 | Ar-07 | 0.51 | 0.30 | 1.7 | A | 0 |
| 8 | Ar-08 | 0.52 | 0.29 | 1.8 | A | 0 |
| 9 | Ar-09 | 0.53 | 0.28 | 1.9 | A | 0 |
| 10 | Ar-10 | 0.53 | 0.29 | 1.8 | A | 0 |
| 11 | Ar-11 | 0.53 | 0.28 | 1.9 | A | 0 |
| 12 | Ar-12 | 0.52 | 0.31 | 1.7 | A | 0 |
| 13 | Ar-13 | 0.55 | 0.29 | 1.9 | A | 0 |
| 14 | Ar-14 | 0.54 | 0.27 | 2 | A | 0 |
| 15 | Ar-15 | 0.29 | 0.29 | 1 | A | 6 |
| 16 | Ar-16 | 0.31 | 0.22 | 1.4 | A | 3 |
| 17 | Ar-17 | 0.32 | 0.20 | 1.6 | A | 2 |
| 18 | Ar-18 | 0.31 | 0.22 | 1.4 | A | 3 |
| 19 | Ar-19 | 0.52 | 0.31 | 1.7 | A | 0 |
| 20 | Ar-20 | 0.54 | 0.30 | 1.8 | A | 0 |
| 21 | Ar-21 | 0.29 | 0.22 | 1.3 | A | 7 |
| 22 | Ar-22 | 0.29 | 0.21 | 1.4 | A | 4 |
| 23 | Ar-23 | 0.47 | 0.31 | 1.5 | A | 3 |
| 24 | Ar-24 | 0.45 | 0.28 | 1.6 | A | 2 |
| 25 | Ar-25 | 0.44 | 0.29 | 1.5 | A | 3 |
| 26 | Ar-26 | 0.48 | 0.30 | 1.6 | A | 2 |
| 27 | Ar-27 | 0.37 | 0.31 | 1.2 | A | 3 |
| 28 | Ar-28 | 0.47 | 0.31 | 1.5 | A | 2 |
| Comparative | Ar-29 | 0.21 | 0.42 | 0.5 | C | 120 |
| Example 1 | | | | | | |
| Comparative | Ar-30 | 0.29 | 0.41 | 0.7 | B | 83 |
| Example 2 | | | | | | |

### Example 29

### Organic Solvent Development→Alkali Development/Contact Hole Pattern

ARC29SR (manufactured by Nissan Chemical Industries, Ltd.) for forming an organic antireflection film was applied onto a silicon wafer and baked at 205° C. for 60 seconds. The resist composition Ar-03 described in Table 2 was applied thereonto and baked at 90° C. for 60 seconds to form a resist film having a film thickness of 85 nm.

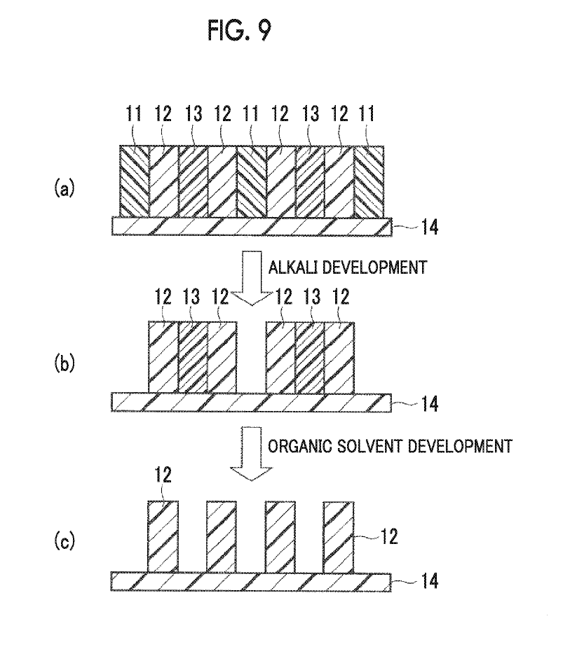

The obtained resist film was subjected to pattern exposure, using an ArF excimer laser liquid immersion scanner (manufactured by ASML, XT1700i, NA1.20, C-Quad, outer sigma 0.9, inner sigma 0.8, XY deflection). Further, as a reticle, the pattern shown in FIG. 9 was used (the black section denotes a light-shielding section, and the dimensions described in drawings are described on the basis of the optical image upon projection). In addition, ultrapure water was used as an immersion liquid.

Thereafter, the resist film was baked (Post Exposure Bake; PEB) at 90° C. for 60 seconds, and then cooled to room temperature. Next, the resist film was developed using butyl acetate for 30 seconds. Then, the wafer was rotated at a rotation speed of 4,000 rpm for 30 seconds. Thereafter, the wafer was developed using a 2.38%-by-mass aqueous TMAH (tetramethylammonium hydroxide) solution for 10 seconds, and rinsed with pure water for 30 seconds to obtain contact hole patterns with a pitch of 110 nm without linkage of adjacent holes.

### Example 30

The resist pattern having line-and-space with a half pitch of 30 nm obtained in Example 1 was subjected to the same treatment as the methods in the steps S3 and S4 described in Test Example 1 of WO2014/002808A. By this treatment, the Line Width Roughness (LWR) of the resist pattern increased from 5.8 nm to 2.9 nm.

[Method for Evaluating LWR]

The line-and-space pattern with a half pitch of 30 nm was observed using a length-measuring dimension scanning electron microscope (SEM; manufactured by Hitachi Ltd., S-9380II). The line width was measured at 50 points in the range of 2 μm in the longitudinal direction of the space pattern, and 3σ was calculated from the standard deviation. A smaller value thereof indicates better performance.

### Example 31

Line-and-space with a half pitch of 30 nm was formed by changing only the following 2 points in the line-and-pattern forming method in Example 1, and thus, good disconnection suppressing performance was observed as in Example 1.

### Modification 1

Providing a top coat film having a thickness of 100 nm on a resist film, using a top coat composition including 2.5% by mass of the resin shown below, 0.05% by mass of an additive Z-1, 0.45% by mass of an additive Z-2, and 97% by mass of 4-methyl-2-pentanol as a solvent, before carrying out exposure.

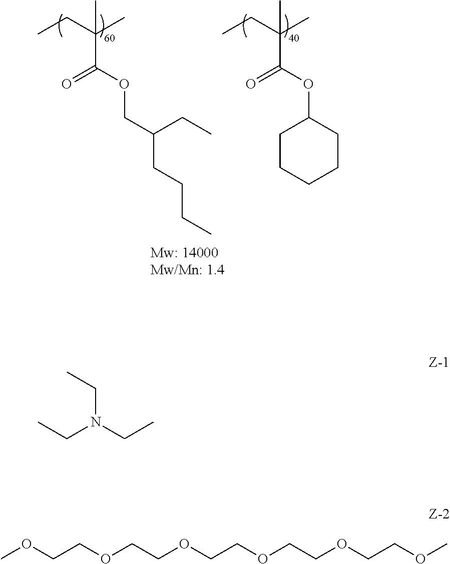

### Modification 2

Rinsing the resist film having the top coat film applied thereonto with 4-methyl-2-pentanol for 30 seconds before developing the resist film using a 2.38%-by-mass TMAH aqueous solution.

### Example 32

A contact hole pattern with a pitch of 110 nm was formed by changing only the following one point from the contact hole pattern forming method in Example 27, and thus, good patterns without linkages of adjacent holes was obtained as in Example 27.

### Modification 1

Providing a top coat film having a thickness of 100 nm on a resist film, using a top coat composition including 2.5% by mass of the resin shown below, 0.05% by mass of an additive Z-1, 0.45% by mass of an additive Z-2, and 97% by mass of 4-methyl-2-pentanol as a solvent, before carrying out exposure.

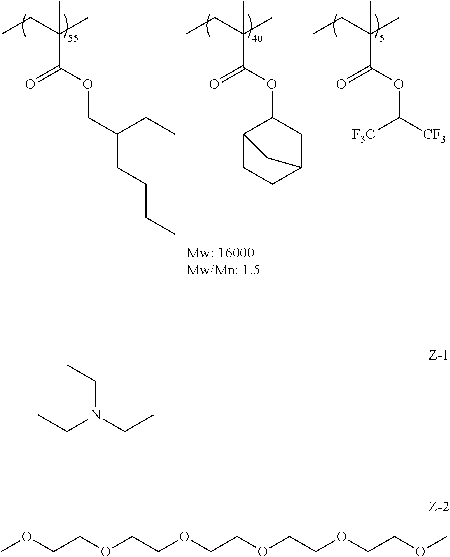

In Examples above, ArF excimer laser is used as an exposure light source, but even in a case where other exposure light sources, for example, KrF light and EUV light, are used, the same effects can be expected.

### EXPLANATION OF REFERENCES

1: light-shielding section
11: region with high exposure dose (exposed area)
12: region with intermediate exposure dose (intermediate-exposed area)
13: region with low exposure dose (unexposed area)

What is claimed is:

1. A pattern forming method comprising:
forming an actinic ray-sensitive or radiation-sensitive film, using an actinic ray-sensitive or radiation-sensitive resin composition containing a resin (A) whose polarity increases by the action of an acid by having repeating units (a-1) including acid-decomposable groups capable of decomposing by the action of an acid to generate polar groups;
irradiating the actinic ray-sensitive or radiation-sensitive film with actinic ray or radiation;
dissolving a region with a large irradiation dose of active light or radiation in the actinic ray-sensitive or radiation-sensitive film, using an alkali developer; and
dissolving a region with a small irradiation dose of actinic ray or radiation in the actinic ray-sensitive or radiation-sensitive film, using a developer including an organic solvent,
wherein ΔDth represented by the following Formula (1) of the actinic ray-sensitive or radiation-sensitive resin composition is 0.8 or more,
ΔDth=Dth(PTI)/Dth(NTI) (1)
in the formula,
Dth(PTI) represents the threshold deprotection rate of the acid-decomposable group in the repeating unit (a-1) included in the resin (A) with respect to the film thickness of the actinic ray-sensitive or radiation-sensitive film after development using the alkali developer, and
Dth(NTI) represents the threshold deprotection rate of the acid-decomposable group in the repeating unit (a-1) included in the resin (A) with respect to the film thickness of the actinic ray-sensitive or radiation-sensitive film after development using the developer including an organic solvent.

2. The pattern forming method according to claim 1, wherein Dth(PTI) in Formula (1) is 0.3 or more.

3. The pattern forming method according to claim 1, wherein Dth(NTI) in Formula (1) is 0.4 or less.

4. The pattern forming method according to claim 1, wherein the weight-average molecular weight of the resin (A) is 10,000 or more.

5. The pattern forming method according to claim 1, wherein the content of the repeating units (a-1) including acid-decomposable groups that occupy the resin (A) is 65% by mole or less with respect to all the repeating units in the resin (A).

6. The pattern forming method according to claim 1, wherein the resin (A) contains an adamantane structure.

7. The pattern forming method according to claim 1, wherein the resin (A) further contains repeating units represented by the following General Formula (2), 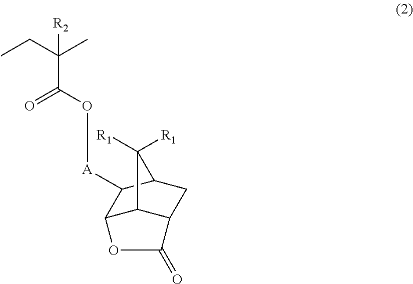
in the formula, A represents a single bond or a linking group, R₁'s each independently represent a hydrogen atom or an alkyl group, and R₂ represents a hydrogen atom or an alkyl group.

8. An actinic ray-sensitive or radiation-sensitive resin composition used in a pattern forming method including carrying out development using an alkali developer, and carrying out development using a developer including an organic solvent, the actinic ray-sensitive or radiation-sensitive resin composition comprising:
a resin (A) whose polarity increases by the action of an acid by having repeating units (a-1) including acid-decomposable groups capable of decomposing by the action of an acid to generate polar groups,
wherein ΔDth represented by the following Formula (1) is 0.8 or more,
ΔDth=Dth(PTI)/Dth(NTI) (1)
in the formula,
Dth(PTI) represents the threshold deprotection rate of the acid-decomposable group in the repeating unit (a-1) included in the resin (A) with respect to the film thickness of the actinic ray-sensitive or radiation-sensitive film after development using the alkali developer, and
Dth(NTI) represents the threshold deprotection rate of the acid-decomposable group in the repeating unit (a-1) included in the resin (A) with respect to the film thickness of the actinic ray-sensitive or radiation-sensitive film after development using the developer including an organic solvent.

9. The actinic ray-sensitive or radiation-sensitive resin composition according to claim 8, wherein Dth(PTI) in Formula (1) is 0.3 or more.

10. The actinic ray-sensitive or radiation-sensitive resin composition according to claim 8, wherein Dth(NTI) in Formula (1) is 0.4 or less.

11. The actinic ray-sensitive or radiation-sensitive resin composition according to claim 8, wherein the weight-average molecular weight of the resin (A) is 10,000 or more.

12. The actinic ray-sensitive or radiation-sensitive resin composition according to claim 8, wherein the content of the repeating units (a-1) including acid-decomposable groups that occupy the resin (A) is 65% by mole or less with respect to all the repeating units in the resin (A).

13. The actinic ray-sensitive or radiation-sensitive resin composition according to claim 8, wherein the resin (A) contains an adamantane structure.

14. The actinic ray-sensitive or radiation-sensitive resin composition according to claim 8, wherein the resin (A) contains repeating units represented by the following General Formula (2), 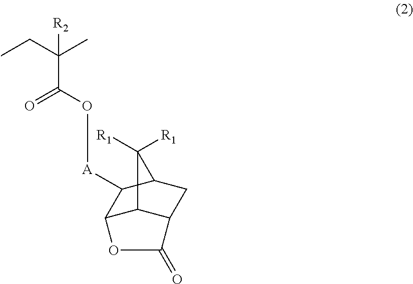
in the formula, A represents a single bond or a linking group, R₁'s each independently represent a hydrogen atom or an alkyl group, and R₂ represents a hydrogen atom or an alkyl group.

15. An actinic ray-sensitive or radiation-sensitive film formed from the actinic ray-sensitive or radiation-sensitive resin composition according to claim 8.

16. A method for manufacturing an electronic device, comprising the pattern forming method according to claim 1.
